(19) United States
(12) Patent Application Publication
(10) Pub. No.: US 2025/0188346 A1
(43) Pub. Date: Jun. 12, 2025

(54) QUANTUM DOT, AND INK COMPOSITION, OPTICAL MEMBER, ELECTRONIC APPARATUS, AND ELECTRONIC DEVICE INCLUDING THE QUANTUM DOT

(71) Applicant: Samsung Display Co., Ltd., Yongin-si (KR)

(72) Inventors: Sooho Lee, Yongin-si (KR); Byounghun Sung, Yongin-si (KR); Doohyun Lee, Yongin-si (KR)

(21) Appl. No.: 18/971,557

(22) Filed: Dec. 6, 2024

(30) Foreign Application Priority Data
Dec. 7, 2023 (KR) 10-2023-0176769
Nov. 28, 2024 (KR) 10-20240173946

(51) Int. Cl. C09K 11/54; C09D 11/322; C09K 11/56; C09K 11/88; G02F 1/1335; H10H 20/851; H10K 50/115; H10K 102/00

(52) U.S. Cl. CPC C09K 11/54; C09D 11/322; C09K 11/565; C09K 11/883; G02F 1/133514; H10H 20/8513; H10K 50/115; H10K 2102/331

(57) ABSTRACT

A quantum dot, and an ink composition, an optical member, an electronic apparatus, and an electronic device that include the quantum dot are provided. The quantum dot includes a core including a first semiconductor compound represented by Formula 1 and a first shell covering the core and including A¹, wherein a radius of the core of the quantum dot is 5 nm or more and Formula 1 is:

CdₓA₁₋ₓ¹B¹ Formula 1

wherein, in Formula 1, A¹ may be a Group II element other than cadmium (Cd), B¹ may be a Group VI element, and x may be greater than 0 but not more than 0.12.

### CROSS-REFERENCE TO RELATED APPLICATION

This application claims priority to and the benefit of Korean Patent Application No. 10-2023-0176769, filed on Dec. 7, 2023, and Korean Patent Application No. 10-2024-0173946, filed on Nov. 28, 2024, in the Korean Intellectual Property Office, the entire content of which is incorporated by reference herein.

### BACKGROUND

### 1. Field

Embodiments of the present disclosure relate to a quantum dot, and relate to an ink composition, an optical member, an electronic apparatus, and an electronic device that include the quantum dot.

### 2. Description of the Related Art

Quantum dots can be utilized as materials that perform one or more suitable optical functions (for example, a light conversion function, a light emission function, and/or the like) in optical members and suitable electronic apparatuses. Quantum dots, which are semiconductor nanocrystals with a quantum confinement effect, may have different energy bandgaps by controlling the size and composition of the nanocrystals, and accordingly may be to emit light of one or more suitable emission wavelengths.

An optical member including such quantum dots may be in the form of a thin film, for example, a thin film patterned for each subpixel. Such an optical member may be used as a color conversion member of a device such as a light source.

Quantum dots may be used for a variety of purposes in one or more suitable electronic apparatuses. For example, quantum dots may be used as emitters. For example, quantum dots may be included in an emission layer of a light-emitting device including a pair of electrodes and the emission layer, and in this regard, the quantum dots may serve as emitters.

Currently, to implement high-quality optical members and electronic apparatuses, the development of quantum dots having excellent or suitable photoluminescence quantum yield (PLQY) and a long lifespan is desired or required.

The above information disclosed in this Background section is only for enhancement of understanding of the background of the disclosure and therefore it may contain information that does not constitute prior art.

### SUMMARY

Aspects of one or more embodiments of the present disclosure relate to a novel quantum dot, and an ink composition, an optical member, an electronic apparatus, and an electronic device that include the novel quantum dot.

Additional aspects will be set forth in part in the description which follows and, in part, will be apparent from the description, or may be learned by practice of the presented embodiments of the disclosure.

According to one or more embodiments, a quantum dot includes a core including a first semiconductor compound represented by Formula 1, and a first shell covering the core and including A¹, wherein a radius of the core of the quantum dot is 5 nm or more and Formula 1 is:

CdₓA₁₋ₓ¹B¹. Formula 1

Wherein, in Formula 1, A¹ is a Group II element other than Cd, B¹ is a Group VI element, and x is greater than 0 but not more than 0.12.

According to one or more embodiments, an ink composition includes the quantum dot and a solvent.

According to one or more embodiments, an optical member includes the quantum dot.

According to one or more embodiments, an electronic apparatus includes the quantum dot.

According to one or more embodiments, an electronic device includes the quantum dot.

### BRIEF DESCRIPTION OF THE DRAWINGS

The above and other aspects, features, and/or principles of certain embodiments of the present disclosure will be more apparent from the following description taken in conjunction with the accompanying drawings, in which:

FIG. 1 is a schematic cross-sectional view of a quantum dot according to one or more embodiments of the present disclosure;

FIG. 2 is a schematic cross-sectional view of a structure of an electronic apparatus according to one or more embodiments of the present disclosure;

FIG. 3 is a schematic cross-sectional view of a structure of a light-emitting device according to one or more embodiments of the present disclosure;

FIG. 4 is a schematic perspective view of an electronic device including quantum dots according to one or more embodiments of the present disclosure;

FIG. 5 is a diagram schematically illustrating the exterior of a vehicle as an electronic device including quantum dots according to one or more embodiments of the present disclosure; and

FIGS. 6A-6C are each a diagram schematically illustrating the interior of a vehicle according to one or more embodiments of the present disclosure.

### DETAILED DESCRIPTION

The present disclosure may be modified in many alternate forms, and thus specific embodiments will be illustrated in the drawings and described in more detail. It should be understood, however, that this is not intended to limit the present disclosure to the particular forms disclosed, but rather, is intended to cover all modifications, equivalents, and alternatives falling within the spirit and scope of the present disclosure.

Reference will now be made in more detail to one or more embodiments, examples of which are illustrated in the accompanying drawings, wherein like reference numerals refer to like elements throughout, and duplicative descriptions thereof may not be provided. In this regard, the present embodiments may have different forms and should not be construed as being limited to the descriptions set forth herein. Further, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described.

As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof. Unless otherwise apparent from the disclosure, expressions such as “at least one of,” “a plurality of,” “one of,” and other prepositional phrases, when preceding a list of elements, should be understood as including the disjunctive if written as a conjunctive list and vice versa. For example, the expressions “at least one of a, b, or c,” “at least one of a, b, and/or c,” “one selected from the group consisting of a, b, and c,” “at least one selected from a, b, and c,” “at least one from among a, b, and c,” “one from among a, b, and c”, “at least one of a to c” indicates only a, only b, only c, both a and b, both a and c, both b and c, all of a, b, and c, or variations thereof.

Because the disclosure may have diverse modified embodiments, embodiments are illustrated in the drawings and are described in the detailed description. An aspect and a characteristic of the disclosure, and a method of accomplishing these will be apparent when referring to one or more embodiments described with reference to the drawings. The disclosure may, however, be embodied in many different forms and should not be construed as limited to one or more embodiments set forth herein. In the drawings, the relative sizes of elements, layers, and regions may be exaggerated for clarity.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

As used herein, the singular forms “a”, “an” and “the” are intended to include the plural forms as well, unless the context clearly indicates otherwise.

It will be further understood that the terms “comprises,” “comprising,” “includes”, “including”, “have,” and “having,” when used in this specification, specify the presence of the stated features, integers, steps, operations, elements, and/or components, but do not preclude the presence or addition of one or more other features, integers, steps, operations, elements, components, and/or groups thereof.

It will be understood that when an element, such as an area, layer, film, region or portion, is referred to as being “on,” “connected to,” or “coupled to” another element, it can be directly on, connected to, or coupled to the other element, or one or more intervening elements may be present. In addition, it will also be understood that when an element is referred to as being “between” two elements, it can be the only element between the two elements, or one or more intervening elements may also be present. As used herein, the terms “use,” “using,” and “used” may be considered synonymous with the terms “utilize,” “utilizing,” and “utilized,” respectively. Also, the term “exemplary” is intended to refer to an example or illustration.

In the present disclosure, when particles are spherical, “diameter” indicates a particle diameter or an average particle diameter, and when the particles are non-spherical, the “diameter” indicates a major axis length or an average major axis length. The diameter (or size) of the particles may be measured utilizing a scanning electron microscope or a particle size analyzer. As the particle size analyzer, for example, HORIBA, LA-950 laser particle size analyzer, may be utilized. When the size of the particles is measured utilizing a particle size analyzer, the average particle diameter (or size) is referred to as D50. D50 refers to the average diameter (or size) of particles whose cumulative volume corresponds to 50 vol % in the particle size distribution (e.g., cumulative distribution), and refers to the value of the particle size corresponding to 50% from the smallest particle when the total number of particles is 100% in the distribution curve accumulated in the order of the smallest particle size to the largest particle size.

In the present disclosure, when particles are spherical, “radius” indicates a particle radius or an average particle radius, and when the particles are non-spherical, the “radius” indicates half a major axis length or half an average major axis length. The radius of the particles may be measured utilizing a scanning electron microscope or a particle size analyzer. As the particle size analyzer, for example, HORIBA, LA-950 laser particle size analyzer, may be utilized.

The term “Group I” as used herein may include a Group IA element and a Group IB element on the IUPAC Periodic Table, and the Group I element may include, for example, silver (Ag), copper (Cu), and/or the like.

The term “Group II” as used herein may include a Group IIA element and a Group IIB element on the IUPAC Periodic Table, and the Group II element includes, for example, magnesium (Mg), calcium (Ca), zinc (Zn), cadmium (Cd), mercury (Hg), and/or the like.

The term “Group III” as used herein may include a Group IIIA element and a Group IIIB element on the IUPAC Periodic Table, and the Group Ill element may include, for example, aluminum (Al), gallium (Ga), indium (In), thallium (TI), and/or the like.

The term “Group VI” as used herein may include a Group VIA element and a Group VIB element on the IUPAC Periodic Table, and the Group VI element may include, for example, oxygen (O), sulfur (S), selenium (Se), tellurium (Te), and/or the like.

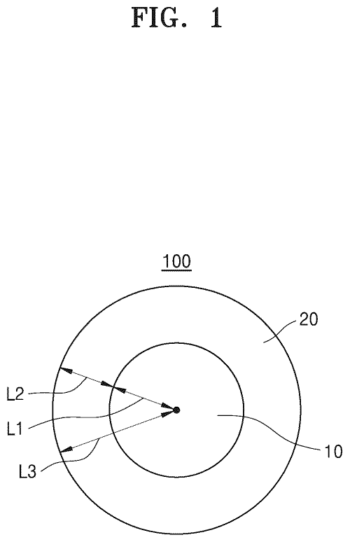

Hereinafter, a preparation method of a quantum dot 100 according to one or more embodiments will be described with reference to FIG. 1.

### Description of FIG. 1

FIG. 1 is a schematic cross-sectional view of a quantum dot 100 according to one or more embodiments of the present disclosure. The quantum dot 100 includes a core 10 and a first shell 20.

### Quantum Dot 100

The quantum dot 100 of FIG. 1 includes: a core 10 including a first semiconductor compound represented by Formula 1; and a first shell 20 covering the core and including A¹, wherein a radius of the core 10 of the quantum dot 100 is 5 nm or more:

CdₓA₁₋ₓ¹B¹ Formula 1

In Formula 1, A¹ may be a Group II element other than cadmium (Cd), B¹ may be a Group VI element, and x may be greater than 0 but not more than 0.12.

In one or more embodiments, x in Formula 1 may be greater than 0 but not more than about (e.g., less than or equal to about) 0.12, and for example, may be greater than 0 but not more than about 0.12, about 0.01 to about 0.12, about 0.02 to about 0.12, about 0.03 to about 0.12, about 0.04 to about 0.12, about 0.05 to about 0.12, about 0.06 to about 0.12, about 0.07 to about 0.12, about 0.08 to about 0.12, about 0.09 to about 0.12, about 0.1 to about 0.12, about 0.11 to about 0.12, about 0.01 to about 0.11, about 0.02 to about 0.11, about 0.03 to about 0.11, about 0.04 to about 0.11, about 0.05 to about 0.11, about 0.06 to about 0.11, about 0.07 to about 0.11, about 0.08 to about 0.11, about 0.09 to about 0.11, about 0.1 to about 0.11, about 0.01 to about 0.1, about 0.02 to about 0.1, about 0.03 to about 0.1, about 0.04 to about 0.1, about 0.05 to about 0.1, about 0.06 to about 0.1, about 0.07 to about 0.1, about 0.08 to about 0.1, about 0.09 to about 0.1, about 0.01 to about 0.09, about 0.02 to about 0.09, about 0.03 to about 0.09, about 0.04 to about 0.09, about 0.05 to about 0.09, about 0.06 to about 0.09, about 0.07 to about 0.09, about 0.08 to about 0.09, about 0.01 to about 0.08, about 0.02 to about 0.08, about 0.03 to about 0.08, about 0.04 to about 0.08, about 0.05 to about 0.08, about 0.06 to about 0.08, about 0.07 to about 0.08, about 0.01 to about 0.07, about 0.02 to about 0.07, about 0.03 to about 0.07, about 0.04 to about 0.07, about 0.05 to about 0.07, about 0.06 to about 0.07, about 0.01 to about 0.06, about 0.02 to about 0.06, about 0.03 to about 0.06, about 0.04 to about 0.06, about 0.05 to about 0.06, about 0.01 to about 0.05, about 0.02 to about 0.05, about 0.03 to about 0.05, about 0.04 to about 0.05, about 0.01 to about 0.04, about 0.02 to about 0.04, about 0.03 to about 0.04, about 0.01 to about 0.03, about 0.02 to about 0.03, or about 0.01 to about 0.02.

In one or more embodiments, the first shell 20 may further include B² and B³, wherein B² and B³ may each independently be a Group VI element.

In one or more embodiments, A¹ may be Zn, Mg, Ca, Hg, and/or a (e.g., any suitable) combination thereof.

In one or more embodiments, B¹, B², and B³ may each independently be O, S, Se, Te, and/or a (e.g., any suitable) combination thereof.

In one or more embodiments, A¹ may be Zn or Mg, B¹ may be S or Se, B² may be S or Se, and B³ may be S or Se. In one or more embodiments, A¹ may be Zn, B¹ may be Se, B² may be Se, and B³ may be S.

In one or more embodiments, the core 10 and the first shell 20 may each include a Group II-VI semiconductor compound.

The Group II-VI semiconductor compound may include CdS, CdSe, CdTe, ZnS, ZnSe, ZnTe, ZnO, HgS, HgSe, HgTe, MgSe, MgS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, CdZnSeS, CdZnSeTe, CdZnSTe, CdHgSeS, CdHgSeTe, CdHgSTe, HgZnSeS, HgZnSeTe, HgZnSTe, and/or a (e.g., any suitable) combination thereof.

In one or more embodiments, the core 10 may include a first semiconductor compound, and the first semiconductor compound may be a Group II-VI semiconductor compound. For example, the first semiconductor compound may include CdZnSe.

In one or more embodiments, the first shell 20 may include a second semiconductor compound represented by Formula 2:

A¹B_{y}²B_{1-y}³ Formula 2

In Formula 2, A¹ may be a Group II element, B² and B³ may each independently be a Group VI element, and y may be greater than 0 but less than 1.

In one or more embodiments, the first shell 20 may include a second semiconductor compound, and the second semiconductor compound may be a Group II-VI semiconductor compound. For example, the second semiconductor compound may include ZnSeS.

In one or more embodiments, A¹ included in the core 10 and A¹ included in the first shell 20 may be substantially identical to or substantially different from each other.

In one or more embodiments, B¹ and B² may be substantially identical to each other.

In one or more embodiments, Cd included in the core 10 may be present in a substantially uniform concentration or a non-uniform (substantially non-uniform) concentration.

In one or more embodiments, A¹ included in the core 10 may be present in a substantially uniform concentration or a non-uniform (substantially non-uniform) concentration.

In one or more embodiments, B¹ included in the core 10 may be present in a substantially uniform concentration or a non-uniform (substantially non-uniform) concentration.

In one or more embodiments, A¹ included in the first shell 20 may be present in a substantially uniform concentration or a non-uniform (substantially non-uniform) concentration.

In one or more embodiments, B² included in the first shell 20 may be present in a substantially uniform concentration or a non-uniform (substantially non-uniform) concentration.

In one or more embodiments, B³ included in the first shell 20 may be present in a substantially uniform concentration or a non-uniform (substantially non-uniform) concentration.

In one or more embodiments, a radius (L1) of the core 10 in the quantum dot may be about 5 nm or more, and for example, may be about 5 nm or more, about nm to about 8 nm, about 5.5 nm to about 7.5 nm, about 6 nm to about 7 nm, or about 6.5 nm to about 7 nm.

In one or more embodiments, a thickness (L2) of the first shell 20 in the quantum dot 100 may be in a range of about 1 nm to 5 nm or about 2 nm to about 5 nm.

In one or more embodiments, a ratio of the radius L1 of the core 10 to the thickness L2 of the first shell 20 may be in a range of about 1 to about 8.

For example, the ratio of the radius L1 of the core 10 to the thickness L2 of the first shell 20 may be in a range of about 1 to about 8, about 1.1 to about 3.9, about 1.2 to about 3.8, about 1.3 to about 3.7, about 1.4 to about 3.6, about 1.5 to about 3.5, about 1.6 to about 3.4, about 1.7 to about 3.3, about 1.8 to about 3.2, about 1.9 to about 3.1, about 2.0 to about 3.0, about 2.1 to about 2.9, about 2.2 to about 2.8, about 2.3 to about 2.7, or about 2.4 to about 2.6.

The expression “radius L1 of the core” as used herein refers to a distance from the center of the quantum dot 100 to the interface between the core 10 and the first shell 20.

The expression “thickness L2 of the first shell” as used herein refers to a distance from the interface between the core 10 and the first shell 20 to the surface of the first shell 20. For example, the thickness L2 of the first shell 20 corresponds to a value obtained by subtracting the radius L1 of the core 10 from a distance (L3) from the center of the quantum dot 100 to the surface of the first shell 20.

When the thickness L2 of the first shell 20 or the ratio of the radius L1 of the core 10 to the thickness L2 of the first shell 20 is within the ranges above, the quantum dot 100 according to one or more embodiments may achieve excellent or suitable luminescence efficiency and a long lifespan.

In one or more embodiments, the quantum dot 100 may further include a second shell covering the first shell 20.

In one or more embodiments, the quantum dot 100 may be a nanoparticle, a nanotube, a nanowire, a nanofiber, a nanoplate, and/or the like, specifically in the form of a spherical particle, a pyramidal particle, a multi-arm particle, or a cubic particle.

In one or more embodiments, the quantum dot 100 may be spherical.

In one or more embodiments, a maximum emission wavelength of a photoluminescence (PL) spectrum of the quantum dot 100 may be in a range of about nm to about 480 nm, about 420 nm to about 470 nm, about 430 nm to about 465 nm, or about 440 nm to about 460 nm.

In one or more embodiments, the quantum dot 100 may be to emit blue light.

In one or more embodiments, a photoluminescence (PL) efficiency of the quantum dot 100 may be in a range of about 50% to about 98%, about 55% to about 97%, or about 60% to about 95%.

In one or more embodiments, a full width of half maximum (FWHM) of an emission wavelength spectrum of the quantum dot 100 may be in a range of about 20 nm to about 30 nm or about 20 nm to about 23 nm. When the FWHM of the quantum dot 100 is within this range, the color purity or color reproducibility may be improved. In one or more embodiments, because light emitted through the quantum dot 100 is emitted in all directions, the wide viewing angle may be improved.

In one or more embodiments, the quantum dot 100 may be prepared by a method of preparing a quantum dot described in more detail below.

The quantum dot 100 may be synthesized by a wet chemical process, a metal organic chemical vapor deposition process, a molecular beam epitaxy process, and/or a (e.g., any suitable) process similar thereto.

The wet chemical process is a method including mixing a precursor material with an organic solvent and then growing quantum dot particle crystals. When the crystals grow, the organic solvent naturally acts as a dispersant coordinated on the surface of the quantum dot crystals and controls the growth of the crystals so that the growth of quantum dot particles may be controlled or selected through a process which costs less and may be easier than vapor deposition methods, such as metal organic chemical vapor deposition (MOCVD) or molecular beam epitaxy (MBE).

The quantum dot 100 may further include, in addition to the aforementioned Group II-VI semiconductor compound, a Group II-VI semiconductor compound, a Group III-V semiconductor compound, a Group III-VI semiconductor compound, a Group I-III-VI semiconductor compound, a Group IV-VI semiconductor compound, a Group IV element or compound, and/or a (e.g., any suitable) combination thereof.

Examples of the Group II-VI semiconductor compound may include: a binary compound, such as CdS, CdSe, CdTe, ZnS, ZnSe, ZnTe, ZnO, HgS, HgSe, HgTe, MgSe, MgS, and/or the like; a ternary compound, such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and/or the like; a quaternary compound, such as CdZnSeS, CdZnSeTe, CdZnSTe, CdHgSeS, CdHgSeTe, CdHgSTe, HgZnSeS, HgZnSeTe, HgZnSTe, and/or the like; and/or a (e.g., any suitable) combination thereof.

Examples of the Group III-V semiconductor compound may include: a binary compound, such as GaN, GaP, GaAs, GaSb, AlN, AlP, AlAs, AlSb, InN, InP, InAs, InSb, and/or the like; a ternary compound, such as GaNP, GaNAs, GaNSb, GaPAs, GaPSb, AlNP, AlNAs, AlNSb, AlPAs, AlPSb, InGaP, InNP, InAlP, InNAs, InNSb, InPAs, InPSb, GaAlNP, and/or the like; a quaternary compound, such as GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and/or the like; and/or a (e.g., any suitable) combination thereof. In one or more embodiments, the Group III-V semiconductor compound may further include a Group II element. Examples of the Group III-V semiconductor compound further including a Group II element may include InZnP, InGaZnP, InAIZnP, and/or the like.

Examples of the Group III-VI semiconductor compound may include: a binary compound, such as GaS, GaSe, Ga₂Se₃, GaTe, InS, InSe, In₂S₃, In₂Sea, InTe, and/or the like; a ternary compound, such as InGaS₃, InGaSes, and/or the like; and/or a (e.g., any suitable) combination thereof.

Examples of the Group I-III-VI semiconductor compound may include: a ternary compound, such as AgInS, AgInS₂, AgInSe₂, AgGaS, AgGaS₂, AgGaSe₂, CuInS, CulnS₂, CulnSe₂, CuGaS₂, CuGaSe₂, CuGaO₂, AgGaO₂, AgAIO₂, and/or the like; a quaternary compound, such as AgInGaS₂, AgInGaSe₂, and/or the like; and/or a (e.g., any suitable) combination thereof.

Examples of the Group IV-VI semiconductor compound may include: a binary compound, such as SnS, SnSe, SnTe, PbS, PbSe, PbTe and/or the like; a ternary compound, such as SnSeS, SnSeTe, SnSTe, PbSeS, PbSeTe, PbSTe, SnPbS, SnPbSe, SnPbTe, and/or the like; a quaternary compound, such as SnPbSSe, SnPbSeTe, SnPbSTe, and/or the like; and/or a (e.g., any suitable) combination thereof.

The Group IV element or compound may include: a single element compound, such as Si, Ge, and/or the like; a binary compound, such as SiC, SiGe, and/or the like; and/or a (e.g., any suitable) combination thereof.

Each element included in a multi-element compound, such as the binary compound, the ternary compound, and the quaternary compound, may be present at a substantially uniform concentration or non-uniform (substantially non-uniform) concentration in a particle. For example, the formulae above refer to types (kinds) of elements included in the compound, and the element ratios within the compound may vary. For example, AgInGaS₂ refers to AgInₓGa₁₋ₓS₂ (where x is a real number between and 1).

The shell (i.e., the first shell and/or the second shell) of the quantum dot 100 may act as a protective layer that prevents chemical degeneration of the core 10 to maintain semiconductor characteristics, and/or as a charging layer that imparts electrophoretic characteristics to the quantum dot 100. The shell may be single-layered or multi-layered. The interface between the core 10 and the first shell 20 may have a concentration gradient in which the concentration of an element existing in the first shell 20 decreases toward the center of the core 10.

The shell of the quantum dot 100 may further include: an oxide of metal, metalloid, or non-metal; a semiconductor compound; and/or a (e.g., any suitable) combination thereof. Examples of the oxide of metal, metalloid, or non-metal may include: a binary compound, such as SiO₂, Al₂O₃, TiO₂, ZnO, MnO, Mn₂O₃, Mn₃O₄, CuO, FeO, Fe₂O₃, Fe₃O₄, CoO, CO₃O₄, NiO, and/or the like; a ternary compound, such as MgAl₂O₄, CoFe₂O₄, NiFe₂O₄, CoMn₂O₄, and/or the like; and/or a (e.g., any suitable) combination thereof. Examples of the semiconductor compound may include: as described above, a Group II-VI semiconductor compound; a Group III-V semiconductor compound; a Group III-VI semiconductor compound; a Group I-III-VI semiconductor compound; a Group IV-VI semiconductor compound; and/or a (e.g., any suitable) combination thereof. For example, the semiconductor compound may include CdS, CdSe, CdTe, ZnS, ZnSe, ZnTe, ZnSeS, ZnTeS, GaAs, GaP, GaS, GaSe, AgGaS, AgGaS₂, GaSb, HgS, HgSe, HgTe, InAs, InP, InGaP, InSb, AlAs, AlP, AlSb, and/or a (e.g., any suitable) combination thereof.

By controlling the size (e.g., diameter and/or radius) of the quantum dots 100, the energy band gap may be adjustable so that light having one or more suitable wavelength bands may be obtained from an emission layer including the quantum dots 100. Accordingly, by using the quantum dots 100 of different sizes, a light-emitting device that emits light of one or more suitable wavelengths may be implemented. In one or more embodiments, the size of quantum dots 100 may be selected to emit red light, green light, and/or blue light. In one or more embodiments, the size of quantum dots 100 may be configured to emit white light by combining light of one or more suitable colors.

The quantum dot 100 according to one or more embodiments may satisfy the radius L1 of the core 10, the range of x, or both (e.g., simultaneously) the radius L1 of the core 10 and the range of x, thereby having excellent or suitable luminescence efficiency and long lifespan characteristics. Thus, use of the quantum dot 100 may provide a high-quality optical member, electronic apparatus, and/or electronic device.

In one or more embodiments, the first shell 20 of the quantum dot 100 according to one or more embodiments satisfies the characteristics described above, thereby having excellent or suitable luminescence efficiency and long lifespan characteristics. Thus, use of the quantum dot 100 may provide a high-quality optical member, electronic apparatus, and/or electronic device.

In one or more embodiments, if (e.g., when) the core 10 and the shell in the quantum dot 100 according to one or more embodiments both include a Group II-VI semiconductor compound, ion-binding components may be included in a high concentration so that the bandgap characteristics may be improved, resulting in long lifespan characteristics. Thus, use of the quantum dot 100 may provide a high-quality optical member, electronic apparatus, and/or electronic device.

In one or more embodiments, if (e.g., when) the quantum dot 100 according to one or more embodiments is mixed with a solvent having a high boiling point for use in the formation of an ink composition, the exchange of cations caused by Cu impurities may be suppressed or reduced, and thus excellent or suitable luminescence efficiency and long lifespan characteristics may be maintained and improved. Thus, use of the quantum dot 100 may provide a high-quality optical member, electronic apparatus, and/or electronic device.

### Ink Composition

One or more embodiments of the disclosure includes an ink composition including the quantum dots and a solvent.

In one or more embodiments, based on a total of 100 parts by weight of the ink composition, an amount of the quantum dots may be in a range of about 1.0 parts by weight to about 10 parts by weight, or about 2 parts by weight to about 5 parts by weight.

In one or more embodiments, based on a total of 100 parts by weight of the ink composition, the amount of the quantum dots may be in a range of about 80 parts by weight to about 99.9 parts by weight, or about 90 parts by weight to about 99.8 parts by weight.

In one or more embodiments, a viscosity of the ink composition may be in a range of about 2 cP to about 10 cP.

In one or more embodiments, a surface tension of the ink composition may be in a range of about 20 dyne/cm to about 40 dyne/cm.

In one or more embodiments, a vapor pressure of the ink composition may be about 10⁻² mmHg or less.

When the viscosity, surface tension, and vapor pressure of the ink composition including the quantum dots are within the ranges above, an inkjet process of ejecting the ink composition may be more easily performed.

In one or more embodiments, the solvent may be a hydrophilic solvent or a hydrophobic solvent.

In one or more embodiments, the hydrophobic solvent may include at least one of an aliphatic hydrocarbon system and an aromatic hydrocarbon system.

For example, the hydrophobic solvent may include at least one of: alkanes including n-pentane, n-hexane, n-heptane, n-octane, n-nonane, n-decane, dodecane, hexadecane, octadecane, and/or the like; haloalkanes including dichloromethane, 1,2-dichloroethane, 1,1,2-trichloroethane, and/or the like; cycloalkanes including cyclohexane, methylcyclohexane, and/or the like; aryls including toluene, xylene, mesitylene, ethylbenzene, n-hexylbenzene, octylbenzene, cyclohexylbenzene, trimethylbenzene, tetrahydronaphthalene, and/or the like; and haloaryls including chlorobenzene, o-dichlorobenzene, and/or the like.

In one or more embodiments, the hydrophilic solvent may include at least one of an alcohol group, an ether group, a ketone group, and/or an ester group.

For example, the hydrophilic solvent may include at least one of: alkylene glycol alkyl ethers, such as ethylene glycol monomethyl ether, ethylene glycol monoethyl ether, ethylene glycol monopropyl ether, ethylene glycol monobutyl ether, propylene glycol monomethyl ether, propylene glycol methylethyl ether, and/or the like; diethylene glycol dialkyl ethers, such as diethylene glycol dimethyl ether, diethylene glycol diethyl ether, diethylene glycol dipropyl ether, diethylene glycol dibutyl ether, and/or the like; methyl cellosolve acetate, ethyl cellosolve acetate, propylene glycol monomethyl ether acetate, propylene glycol monoethyl ether acetate, propylene glycol monopropyl ether acetate, and/or the like; alkoxy alkyl acetates, such as methoxybutyl acetate, methoxypentyl acetate, and/or the like; aromatic hydrocarbons, such as benzene, toluene, xylene, mesitylene, and/or the like; ketones, such as methyl ethyl ketone, acetone, methyl amyl ketone, methyl isobutyl ketone, cyclohexanone, and/or the like; alcohols, such as ethanol, propanol, butanol, hexanol, cyclohexanol, ethylene glycol, glycerin, and/or the like; esters, such as 3-ethoxypropionate ethyl ester, 3-methoxypropionate methyl ester, 3-phenyl-propionate ethyl ester, and/or the like; cyclic esters, such as γ-butyrolactone, and/or the like; and/or methoxybenzene (anisole).

In one or more embodiments, a boiling point of the solvent may be about 120° C. or higher. For example, the boiling point of the solvent may be about 120° C. to about 400° C., about 120° C. to about 350° C., about 120° C. to about 300° C., about 120° C. to about 250° C., or about 120° C. to about 240° C.

In one or more embodiments, the boiling point of the solvent may be about 200° C. or higher. For example, the boiling point of the solvent may be about 200° C. to about 400° C., about 200° C. to about 350° C., about 200° C. to about 300° C., about 200° C. to about 250° C., or about 200° C. to about 240° C.

In one or more embodiments, the solvent may be a single solvent or a mixed solvent of at least two types (kinds) of the solvent.

In one or more embodiments, the solvent may be a mixed solvent of at least two types (kinds) of the hydrophobic solvent. For example, the solvent may include three types (kinds) of the hydrophobic solvent, wherein the three types (kinds) of the hydrophobic solvent may be mixed at a volume ratio of 1:1:1, 3:2:1, 4:3:1, 4:3:2, 5:3:1, or 6:3:1.

The ink composition including the quantum dots and the solvent according to one or more embodiments has excellent or suitable efficiency and long lifespan characteristics, and thus use of the ink composition in the formation of ink may provide high-quality electronic apparatuses and electronic devices.

### Apparatus

The quantum dots may be used in one or more suitable electronic apparatuses. Accordingly, one or more embodiments include an electronic apparatus including the quantum dots.

In one or more embodiments, an electronic apparatus includes a light source and a color conversion member arranged in an optical path of light emitted from the light source, wherein the color conversion member includes the quantum dots.

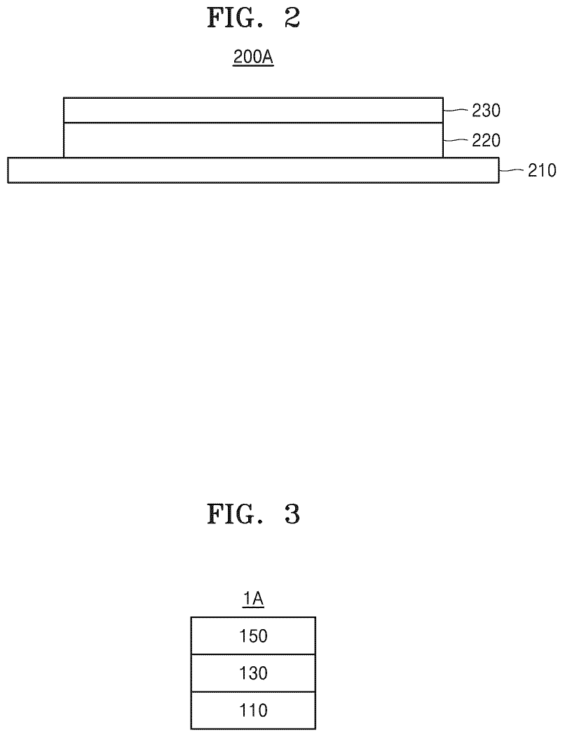

### Description of FIG. 2

FIG. 2 is a schematic view of a structure of an electronic apparatus 200A according to one or more embodiments of the present disclosure. The electronic apparatus 200A of FIG. 2 includes: a substrate 210; a light source 220 arranged on the substrate 210; and a color conversion member 230 arranged on the light source 220.

For example, the light source 220 may be a backlight unit (BLU) for use in a liquid crystal display (LCD), a fluorescent lamp, a light-emitting device, an organic light-emitting device, a quantum-dot light-emitting device (QLED), and/or a (e.g., any suitable) combination thereof. The color conversion member 230 may be arranged in at least one direction of travel of light (e.g., arranged in the path of light) emitted from the light source 220.

At least one region of the color conversion member 230 in the electronic apparatus 200A may include the quantum dots, and the at least one region may be to absorb light emitted from the light source 220 to emit blue light having a maximum emission wavelength in a range of about 410 nm to about 480 nm.

Here, the fact that the color conversion member 230 is arranged in at least one direction of travel of light (e.g., arranged in the path of light) emitted from the light source 220 does not exclude a case where other elements may be additionally included between the color conversion member 230 and the light source 220.

In one or more embodiments, a polarizing plate, a liquid crystal layer, alight guide plate, a diffusion plate, a prism sheet, a microlens sheet, a luminance-enhancing sheet, a reflective film, a color filter, and/or a (e.g., any suitable) combination thereof may be additionally arranged between the light source 220 and the color conversion member 230.

In one or more embodiments, a polarizing plate, a liquid crystal layer, a light guide plate, a diffusion plate, a prism sheet, a microlens sheet, a luminance-enhancing sheet, a reflective film, a color filter, and/or a (e.g., any suitable) combination thereof may be additionally arranged on the color conversion member 230.

The electronic apparatus 200A of FIG. 2 is an example of apparatuses according to one or more embodiments above, and may have one or more suitable shapes suitable in the art, and accordingly, may further include one or more suitable configurations suitable in the art.

In one or more embodiments, the electronic apparatus may have a structure in which a light source, a light guide plate, a color conversion member, a first polarizing plate, a liquid crystal layer, a color filter, and a second polarizing plate are sequentially arranged.

In one or more embodiments, the electronic apparatus may have a structure in which a light source, a light guide plate, a first polarizing plate, a liquid crystal layer, a second polarizing plate, and a color conversion member are sequentially arranged.

In one or more embodiments described above, the color filter may include a pigment and/or a dye. In one or more embodiments above, one of the first polarizing plate and/or the second polarizing plate may be a vertical polarizing plate, and the other one may be a horizontal polarizing plate.

### Light-Emitting Device

In one or more embodiments, the quantum dots described herein may be used as emitters. Thus, one or more embodiments of the disclosure includes an electronic apparatus including a light-emitting device including: a first electrode; a second electrode facing the first electrode; and an interlayer arranged between the first electrode and the second electrode, wherein the light-emitting device (e.g., an emission layer included in the light-emitting device) includes the quantum dots. The light-emitting device may further include: a hole transport region between the first electrode and the emission layer; an electron transport region between the emission layer and the second electrode; and/or a (e.g., any suitable) combination thereof.

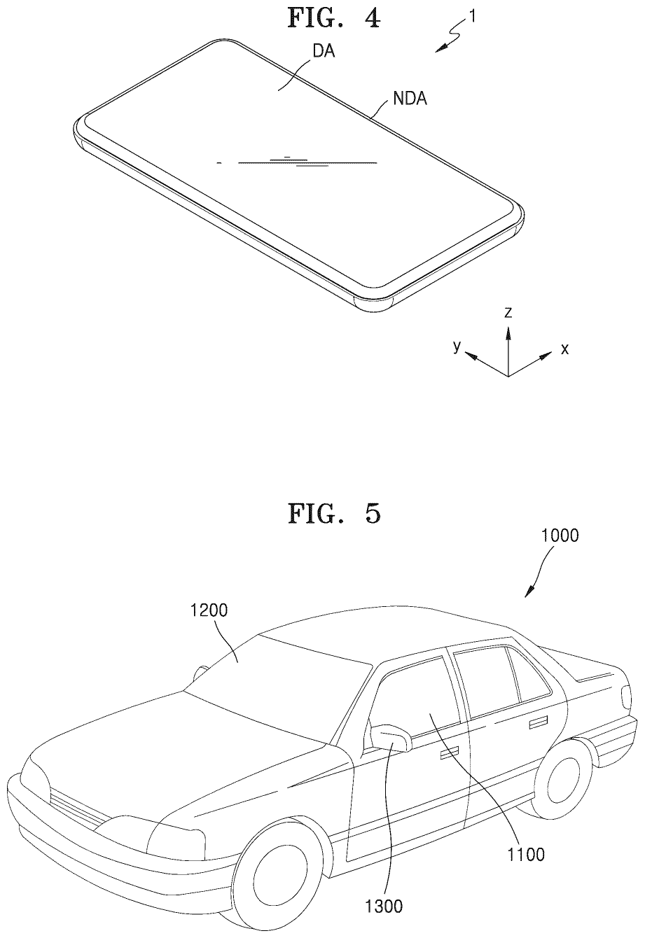

### Description of FIG. 3

FIG. 3 is a schematic view of a structure of a light-emitting device 1A according to one or more embodiments of the present disclosure.

The light-emitting device 1A includes: a first electrode 110; a second electrode 150 facing the first electrode 110; and an interlayer 130 arranged between the first electrode 110 and the second electrode 150 and including quantum dots. Hereinafter, each layer of the light-emitting device 1A will be described.

At least one of the quantum dots may be used in a light-emitting device (e.g., an organic light-emitting device). In this regard, one or more embodiments of the disclosure includes a light-emitting device including: a first electrode; a second electrode facing the first electrode; and an interlayer arranged between the first electrode and the second electrode and including an emission layer; wherein the light-emitting device includes the quantum dots.

In one or more embodiments, the first electrode of the light-emitting device may be an anode, the second electrode of the light-emitting device may be a cathode, and the interlayer may further include a hole transport region arranged between the first electrode and the emission layer and an electron transport region arranged between the emission layer and the second electrode, wherein the hole transport region may include a hole injection layer, a hole transport layer, an emission auxiliary layer, an electron blocking layer, and/or a (e.g., any suitable) combination thereof, and the electron transport region may include a buffer layer, a hole blocking layer, an electron control layer, an electron transport layer, an electron injection layer, and/or a (e.g., any suitable) combination thereof.

In one or more embodiments, the quantum dots may be included between the first electrode and the second electrode of the light-emitting device. Therefore, the quantum dots may be included in the interlayer of the light-emitting device, e.g., the emission layer of the light-emitting device.

In one or more embodiments, the emission layer in the interlayer of the light-emitting device may include a dopant and a host, and the dopant may include the quantum dots. For example, the quantum dots may serve as hosts. The emission layer may be to emit red light, green light, blue light, and/or white light. For example, the emission layer may be to emit blue light. The blue light may have, for example, a maximum emission wavelength in a range of about 400 nm to about 490 nm.

In one or more embodiments, the emission layer in the interlayer of the light-emitting device may include a dopant and a host, the host may include the quantum dots, and the dopant may be to emit blue light. For example, the dopant may include a transition metal and ligand(s) in the number of m, and m may be an integer from 1 to 6. The ligand(s) in the number of m may be substantially identical to or substantially different from each other, at least one of the ligand(s) in the number of m may be linked to the transition metal via a carbon-transition metal bond, and the carbon-transition metal bond may be a coordinate bond. For example, at least one of the ligand(s) in the number of m may be a carbene ligand (e.g., Ir(pmp)₃, and/or the like). The transition metal may be, for example, iridium, platinum, osmium, palladium, rhodium, gold, and/or the like. More details on the emission layer and the dopant are the same as described herein.

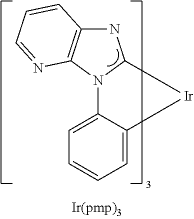

In one or more embodiments, the light-emitting device may further include a capping layer arranged outside the first electrode or outside the second electrode.

In one or more embodiments, the light-emitting device may further include at least one of a first capping layer arranged outside the first electrode and/or a second capping layer arranged outside the second electrode, and at least one of the first capping layer and/or the second capping layer may include the quantum dots. More details on the first capping layer and/or the second capping layer are the same as described herein.

In one or more embodiments, the light-emitting device may include: a first capping layer arranged outside the first electrode and including the quantum dots; a second capping layer arranged outside the second electrode and including the quantum dots; or both the first capping layer and the second capping layer.

The expression “(interlayer and/or capping layer) includes quantum dots” as used herein may be interpreted as “(interlayer and/or capping layer) includes the quantum dots disclosed herein or two or more different types (kinds) of quantum dots.

The term “interlayer” as used herein refers to a single layer and/or multiple layers arranged between the first electrode and the second electrode of the light-emitting device.

One or more embodiments of the disclosure includes: an apparatus including the quantum dots and/or the light-emitting device; and an electronic apparatus. The electronic apparatus may further include a thin-film transistor. For example, the electronic apparatus may further include a thin-film transistor including a source electrode and a drain electrode, wherein the first electrode of the light-emitting device may be electrically connected to the source electrode or the drain electrode. In one or more embodiments, the electronic apparatus may further include a color filter, a color conversion layer, a touch screen layer, a polarizing layer, and/or a (e.g., any suitable) combination thereof. More details on the electronic apparatus are the same as described herein.

Hereinafter, a structure of the light-emitting device 1A according to one or more embodiments and a method of manufacturing the light-emitting device 1A will be described with reference to FIG. 3.

FIG. 3 is a schematic cross-sectional view of the light-emitting device 1A according to one or more embodiments of the present disclosure. The light-emitting device 1A includes the first electrode 110, the interlayer 130, and the second electrode 150.

### First Electrode 110

In FIG. 3, a substrate may be additionally arranged under the first electrode or on the second electrode 150. In one or more embodiments, as the substrate, a glass substrate or a plastic substrate may be used. In one or more embodiments, the substrate may be a flexible substrate, and may include plastics with excellent or suitable heat resistance and durability, such as polyimide, polyethylene terephthalate (PET), polycarbonate, polyethylene napthalate, polyarylate (PAR), polyetherimide, and/or a (e.g., any suitable) combination thereof.

The first electrode 110 may be formed by, for example, depositing or sputtering, onto the substrate, a material for forming the first electrode 11. When the first electrode 110 is an anode, a material for forming the first electrode 110 may be a high-work function material that facilitates injection of holes.

The first electrode 110 may be a reflective electrode, a transflective electrode, or a transmissive electrode. In one or more embodiments, if (e.g., when) the first electrode 110 is a transmissive electrode, a material for forming the first electrode may include indium tin oxide (ITO), indium zinc oxide (IZO), tin oxide (SnO₂), zinc oxide (ZnO), and/or a (e.g., any suitable) combination thereof. In one or more embodiments, if (e.g., when) the first electrode 110 is a transflective electrode or a reflective electrode, a material for forming the first electrode 110 may include magnesium (Mg), silver (Ag), aluminum (Al), aluminum-lithium (Al—U), calcium (Ca), magnesium-indium (Mg—In), magnesium-silver (Mg—Ag), and/or a (e.g., any suitable) combination thereof.

The first electrode 110 may have a single-layer structure including (e.g., consisting of) a single layer, or a multi-layer structure including multiple layers. For example, the first electrode 110 may have a three-layer structure of ITO/Ag/ITO.

### Interlayer 130

The interlayer 130 is arranged on the first electrode 110. The interlayer 130 may include an emission layer.

The interlayer 130 may further include: a hole transport region between the first electrode 110 and the emission layer; and an electron transport region between the emission layer and the second electrode 150.

The interlayer 130 may further include, in addition to one or more suitable organic materials, a metal-containing compound, such as an organometallic compound, an inorganic material, such as quantum dots, and/or the like.

In one or more embodiments, the interlayer 130 may include i) two or more emitting units sequentially stacked between the first electrode 110 and the second electrode 150, and ii) a charge generation layer between neighboring two emitting units. When the interlayer 130 includes the two or more light-emitting units and the charge generation layer, the light-emitting device 1A may be a tandem light-emitting device.

### Hole Transport Region in Interlayer 130

The hole transport region may have i) a single-layer structure including (e.g., consisting of) a single layer including (e.g., consisting of) a single material, ii) a single-layer structure including (e.g., consisting of) a single layer including (e.g., consisting of) multiple materials that are different from each other, or iii) a multi-layer structure including multiple layers including multiple materials that are different from each other.

The hole transport region may include a hole injection layer, a hole transport layer, an emission auxiliary layer, an electron blocking layer, and/or a (e.g., any suitable) combination thereof.

For example, the hole transport region may have a multi-layer structure including a hole injection layer/hole transport layer structure, a hole injection layer/hole transport layer/emission auxiliary layer structure, a hole injection layer/emission auxiliary layer structure, a hole transport layer/emission auxiliary layer structure, or a hole injection layer/hole transport layer/electron-blocking layer structure, wherein layers in each structure are sequentially stacked on (from) the first electrode 110.

The hole transport region may include a compound represented by Formula 201, a compound represented by Formula 202, and/or a (e.g., any suitable) combination thereof:

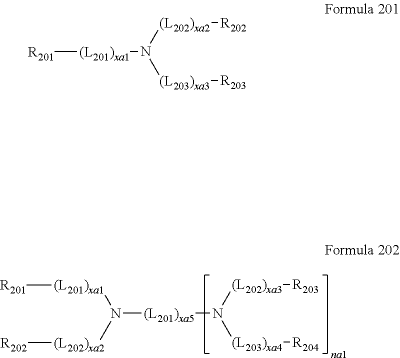

In Formulae 201 and 202, L₂₀₁ to L₂₀₄ may each independently be a C₃-C₆₀ carbocyclic group unsubstituted or substituted with at least one R₁₀ₐ or a C₁-C₆₀ heterocyclic group unsubstituted or substituted with at least one R₁₀ₐ, L₂₀₅ may be *—O—*′, *—S—*′, *—N(Q₂₀₁)—*′, a C₁-C₂₀ alkylene group unsubstituted or substituted with at least one R₁₀ₐ, a C₂-C₂₀ alkenylene group unsubstituted or substituted with at least one R₁₀ₐ, a C₃-C₆₀ carbocyclic group unsubstituted or substituted with at least one R₁₀ₐ, or a C₁-C₆₀ heterocyclic group unsubstituted or substituted with at least one R₁₀ₐ, xa1 to xa4 may each independently be an integer from 0 to 5, xa5 may be an integer from 1 to 10, R₂₀₁ to R₂₀₄ and Q₂₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ, R₂₀₁ and R₂₀₂ may optionally be linked to each other via a single bond, a C₁-C₅alkylene group unsubstituted or substituted with at least one R₁₀ₐ, or a C₂-C₅ alkenylene group unsubstituted or substituted with at least one R₁₀ₐ, to form a C₈-C₆₀ polycyclic group (e.g., a carbazole group, and/or the like) unsubstituted or substituted with at least one R₁₀ₐ (e.g., Compound HT16, and/or the like), R₂₀₃ and R₂₀₄ may optionally be linked to each other via a single bond, a C₁-C₅ alkylene group unsubstituted or substituted with at least one R₁₀ₐ, or a C₂-C₅ alkenylene group unsubstituted or substituted with at least one R₁₀ₐ, to form a C₈-C₆₀ polycyclic group unsubstituted or substituted with at least one R₁₀ₐ, and na1 may be an integer from 1 to 4.

For example, each of Formulae 201 and 202 may include at least one selected from among (e.g., may be any one selected from among) groups represented by Formulae CY201 to CY217:

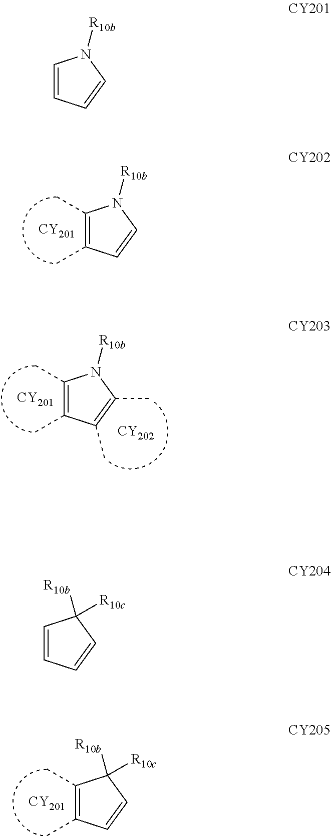

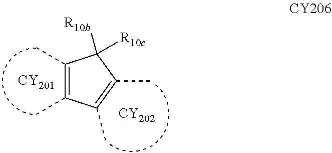

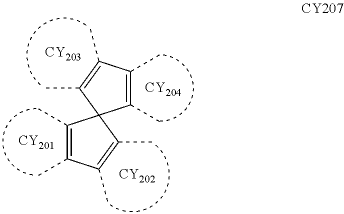

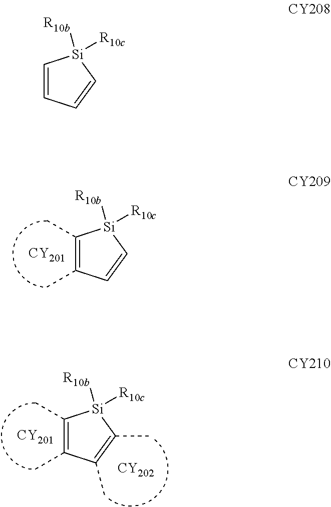

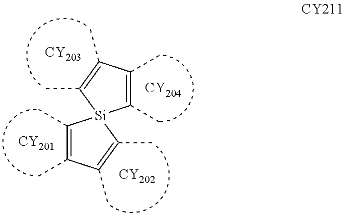

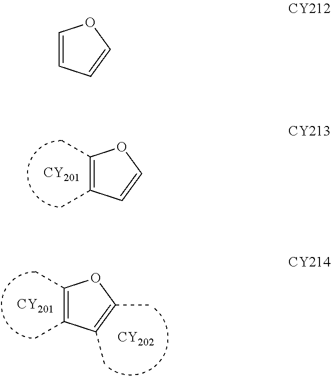

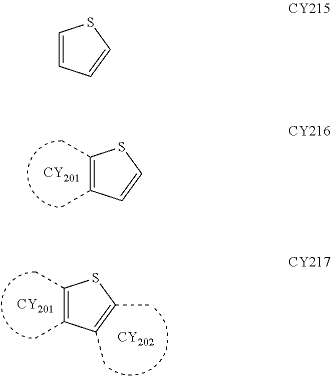

In Formulae CY201 to CY217, R_{10b} and R_{10c} may each be the same as described in connection with R₁₀ₐ, ring CY201 to ring CY204 may each independently be a C₃-C₂₀ carbocyclic group or a C₁-C₂₀ heterocyclic group, and at least one hydrogen in Formulae CY201 to CY217 may be unsubstituted or substituted with R₁₀ₐ.

In one or more embodiments, in Formulae CY201 to CY217, ring CY201 to ring CY204 may each independently be a benzene group, a naphthalene group, a phenanthrene group, or an anthracene group.

In one or more embodiments, each of Formulae 201 and 202 may include at least one of groups represented by Formulae CY201 to CY203.

In one or more embodiments, Formula 201 may include at least one of groups represented by Formulae CY201 to CY203 and/or at least one of groups represented by Formulae CY204 to CY217.

In one or more embodiments, in Formula 201, xa1 may be 1, R₂₀₁ may be one of groups represented by Formulae CY201 to CY203, xa2 may be 0, and R₂₀₂ may be one of groups represented by one of Formulae CY204 to CY207.

In one or more embodiments, each of Formulae 201 and 202 may not include (e.g., may exclude) groups represented by Formulae CY201 to CY203.

In one or more embodiments, each of Formulae 201 and 202 may not include (e.g., may exclude) groups represented by Formulae CY201 to CY203, and may include at least one of groups represented by Formulae CY204 to CY217.

In one or more embodiments, each of Formulae 201 and 202 may not include (e.g., may exclude) groups represented by Formulae CY201 to CY217.

For example, the hole transport region may include: at least one of (e.g., selected from among) Compounds HT1 to HT46; m-MTDATA; TDATA; 2-TNATA; NPB(NPD); β-NPB; TPD; spiro-TPD; spiro-NPB; methylated NPB; TAPC; HMTPD; 4, 4′, 4″-tris(N-carbazolyl)triphenylamine (TCTA); polyaniline/dodecylbenzenesulfonic acid (PANI/DBSA); poly(3,4-ethylenedioxythiophene)/poly(4-styrenesulfonate) (PEDOT/PSS); polyaniline/camphor sulfonic acid (PANI/CSA); polyaniline/poly(4-styrenesulfonate) (PANI/PSS); and/or a (e.g., any suitable) combination thereof:

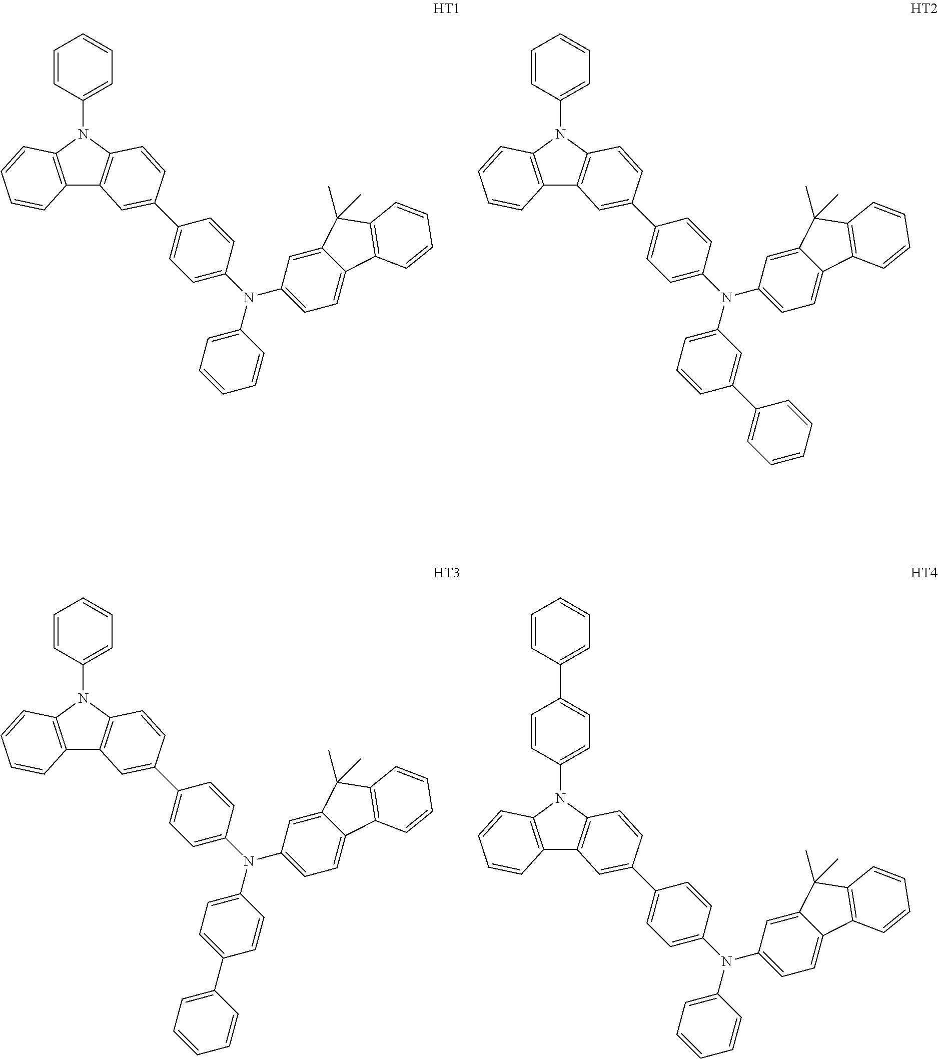 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21 ; CC1(C)c2ccccc2-c2ccc(N(c3ccccc3)c3ccc(-c4ccc5c(c4)c4ccccc4n5-c4ccc(-c5ccccc5)cc4)cc3)cc21]

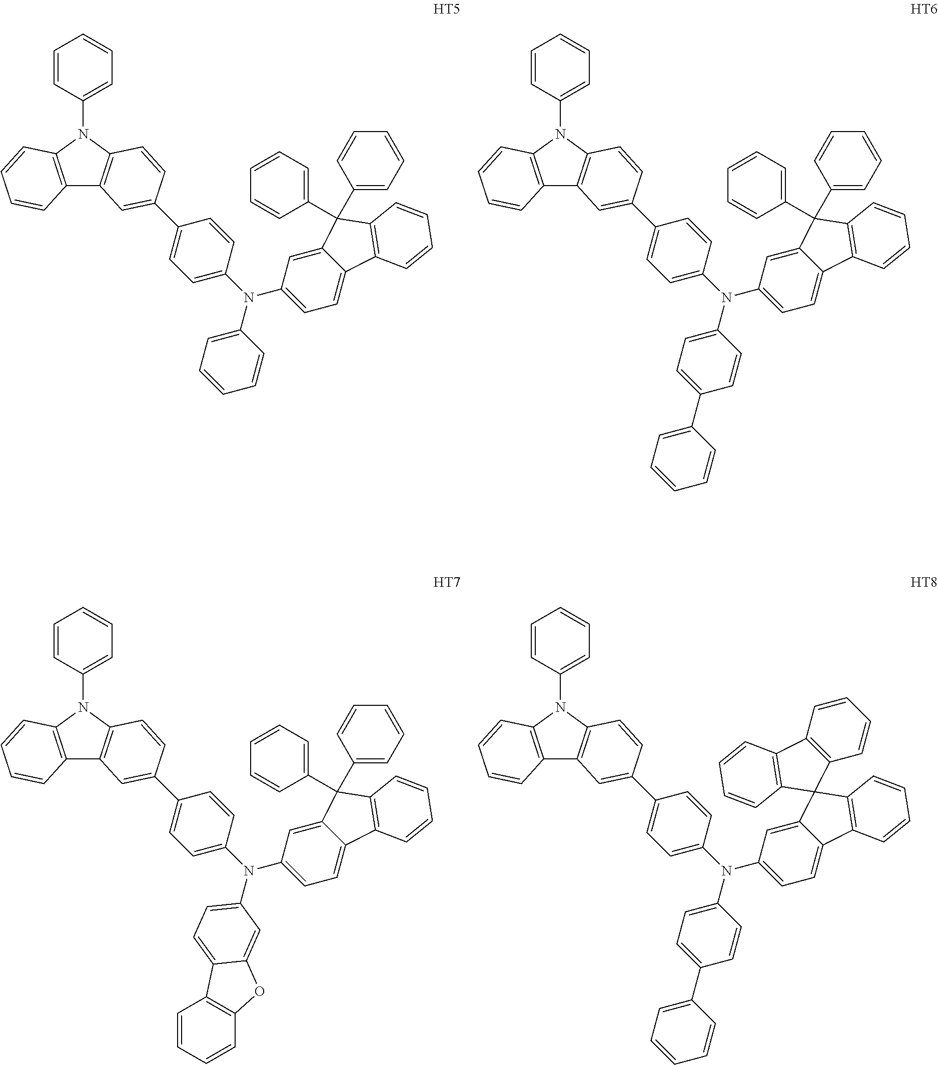 [SMILES: c1ccc(N(c2ccc(-c3ccc4c(c3)c3ccccc3n4-c3ccccc3)cc2)c2ccc3c(c2)C(c2ccccc2)(c2ccccc2)c2ccccc2-3)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1 ; c1ccc(-n2c3ccccc3c3cc(-c4ccc(N(c5ccc6c(c5)C(c5ccccc5)(c5ccccc5)c5ccccc5-6)c5ccc6c(c5)oc5ccccc56)cc4)ccc32)cc1 ; c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1]

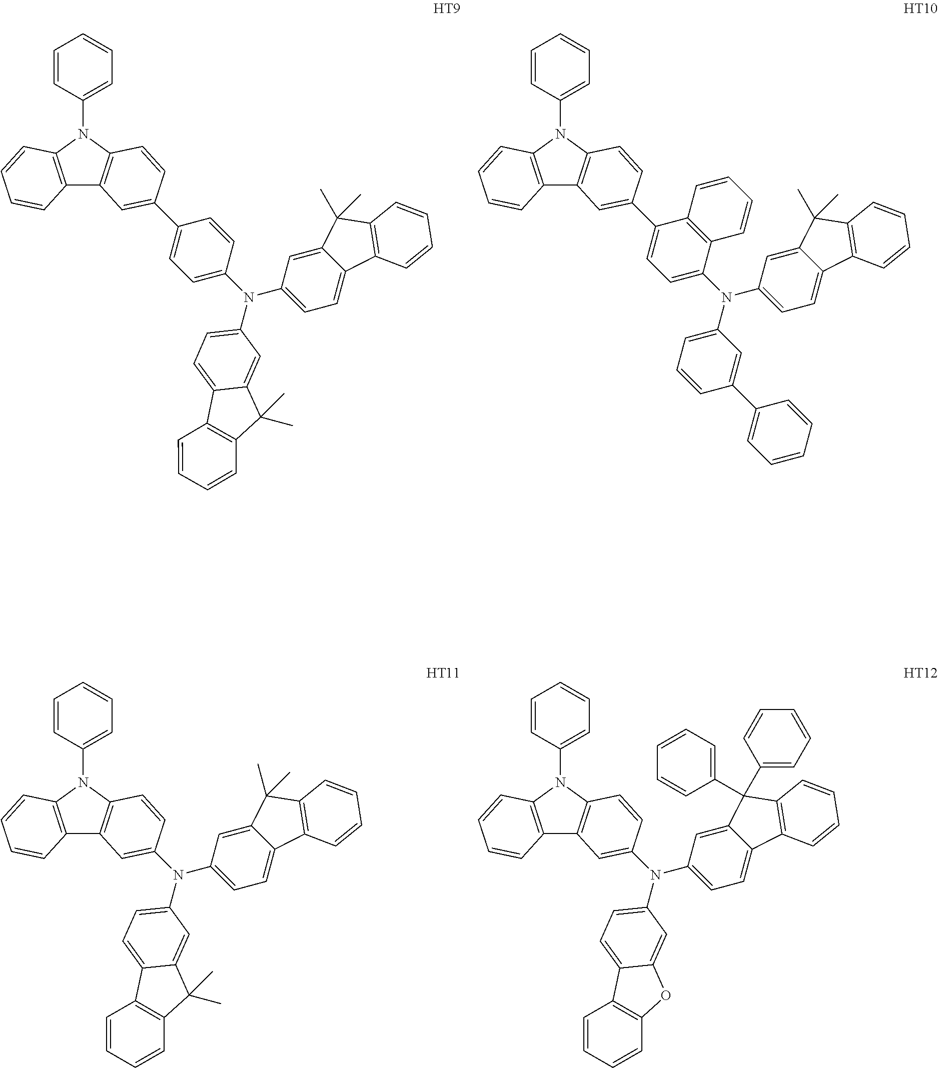 [SMILES: CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC1(C)c2ccccc2-c2ccc(N(c3cccc(-c4ccccc4)c3)c3ccc(-c4ccc5c(c4)c4ccccc4n5-c4ccccc4)c4ccccc34)cc21 ; CC1(C)c2ccccc2-c2ccc(N(c3ccc4c(c3)C(C)(C)c3ccccc3-4)c3ccc4c(c3)c3ccccc3n4-c3ccccc3)cc21 ; c1ccc(-n2c3ccccc3c3cc(N(c4ccc5c(c4)C(c4ccccc4)(c4ccccc4)c4ccccc4-5)c4ccc5c(c4)oc4ccccc45)ccc32)cc1]

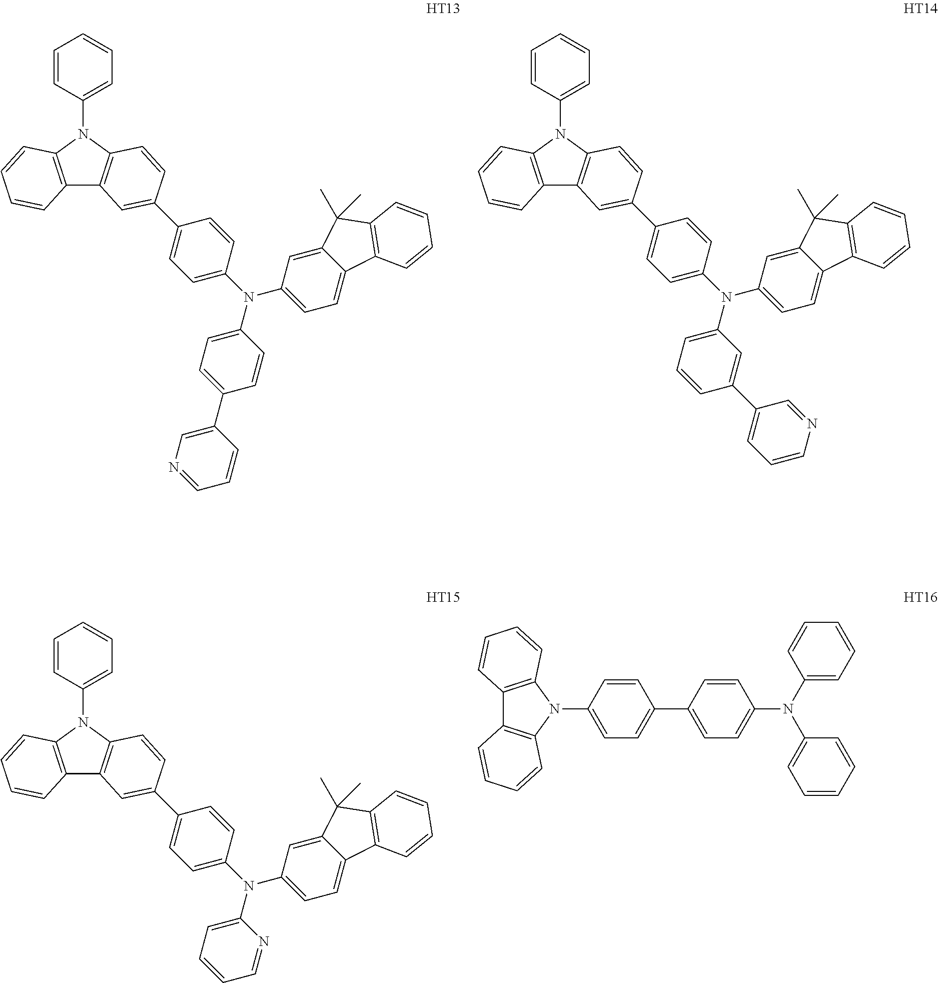 [SMILES: CC1(C)c2ccccc2-c2ccc(N(c3ccc(-c4cccnc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4cccnc4)c3)cc21 ; CC1(C)c2ccccc2-c2ccc(N(c3ccc(-c4ccc5c(c4)c4ccccc4n5-c4ccccc4)cc3)c3ccccn3)cc21 ; c1ccc(N(c2ccccc2)c2ccc(-c3ccc(-n4c5ccccc5c5ccccc54)cc3)cc2)cc1]

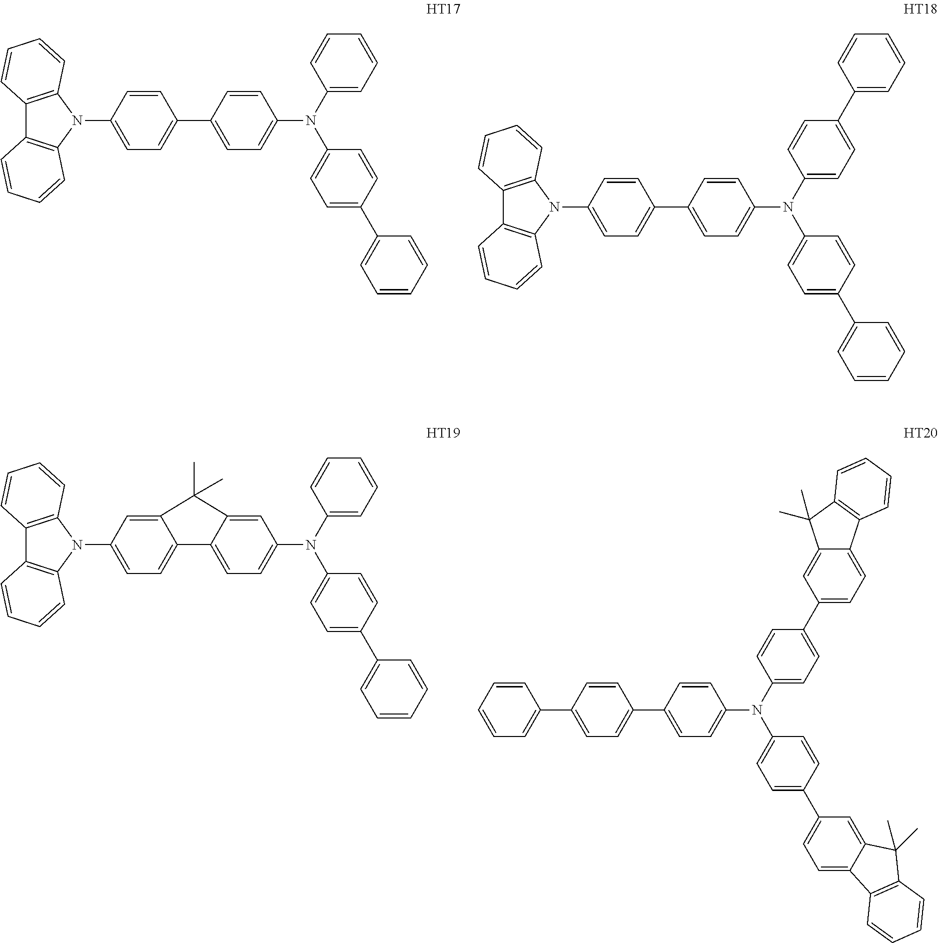 [SMILES: c1ccc(-c2ccc(N(c3ccccc3)c3ccc(-c4ccc(-n5c6ccccc6c6ccccc65)cc4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1 ; CC1(C)c2cc(N(c3ccccc3)c3ccc(-c4ccccc4)cc3)ccc2-c2ccc(-n3c4ccccc4c4ccccc43)cc21 ; CC1(C)c2ccccc2-c2ccc(-c3ccc(N(c4ccc(-c5ccc(-c6ccccc6)cc5)cc4)c4ccc(-c5ccc6c(c5)C(C)(C)c5ccccc5-6)cc4)cc3)cc21]

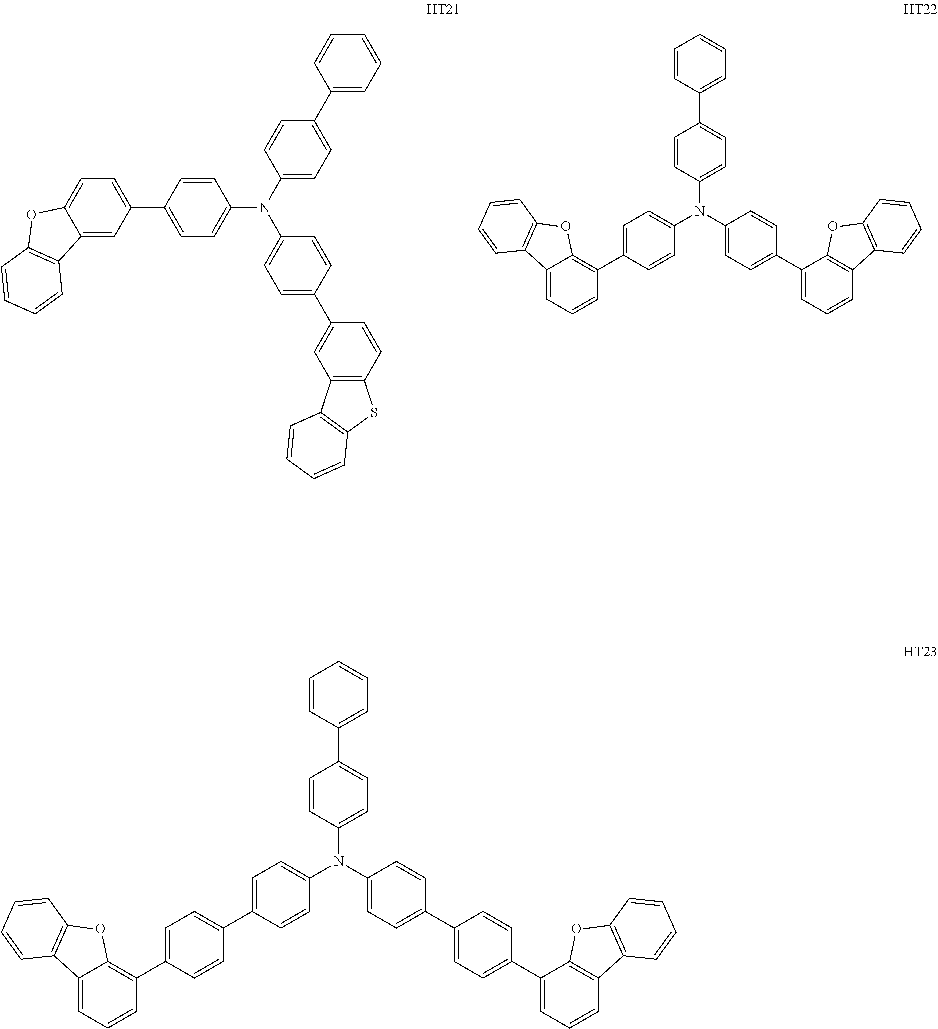 [SMILES: c1ccc(-c2ccc(N(c3ccc(-c4ccc5oc6ccccc6c5c4)cc3)c3ccc(-c4ccc5sc6ccccc6c5c4)cc3)cc2)cc1 ; c1ccc(-c2ccc(N(c3ccc(-c4cccc5c4oc4ccccc45)cc3)c3ccc(-c4cccc5c4oc4ccccc45)cc3)cc2)cc1 ; c1ccc(-c2ccc(N(c3ccc(-c4ccc(-c5cccc6c5oc5ccccc56)cc4)cc3)c3ccc(-c4ccc(-c5cccc6c5oc5ccccc56)cc4)cc3)cc2)cc1]

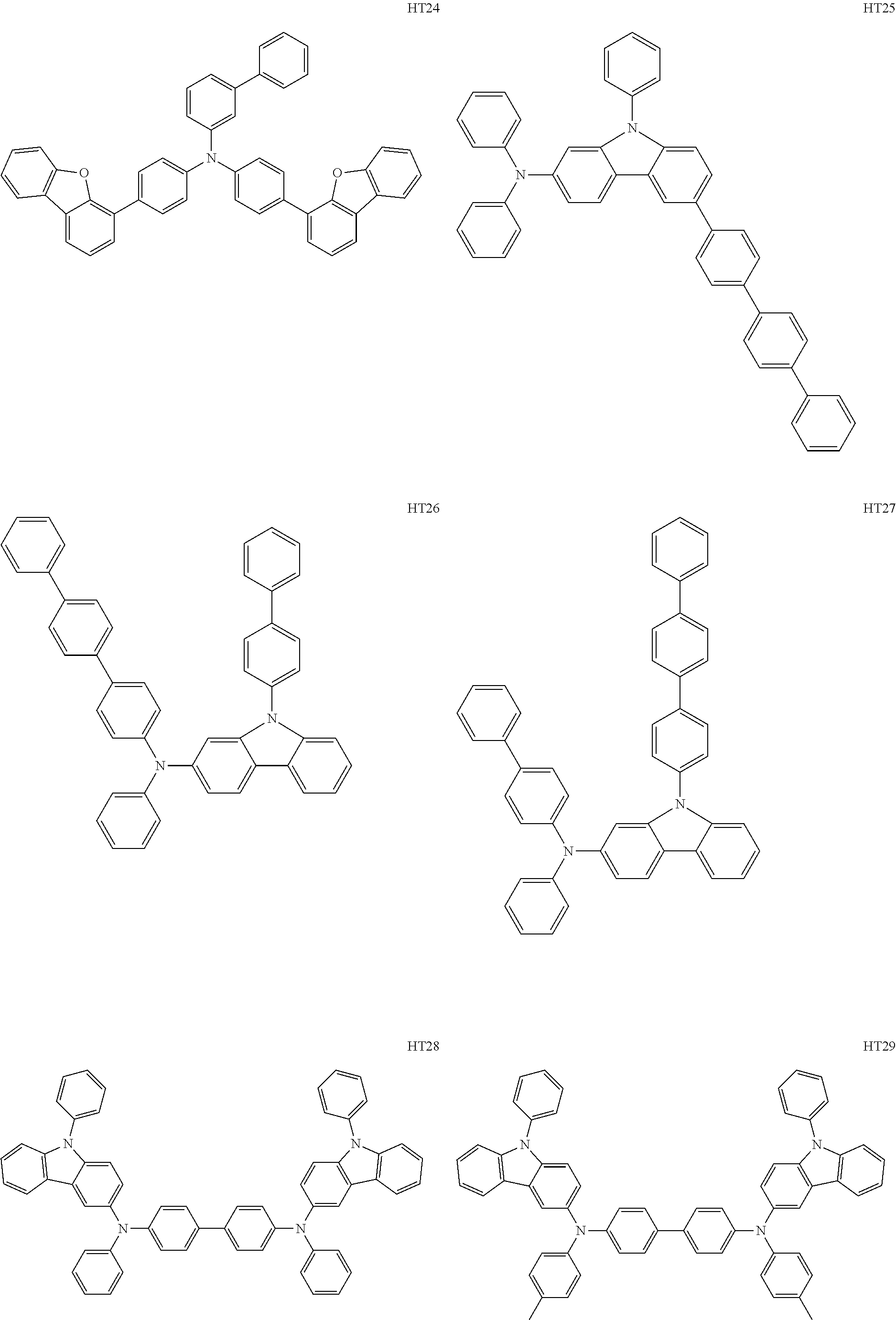

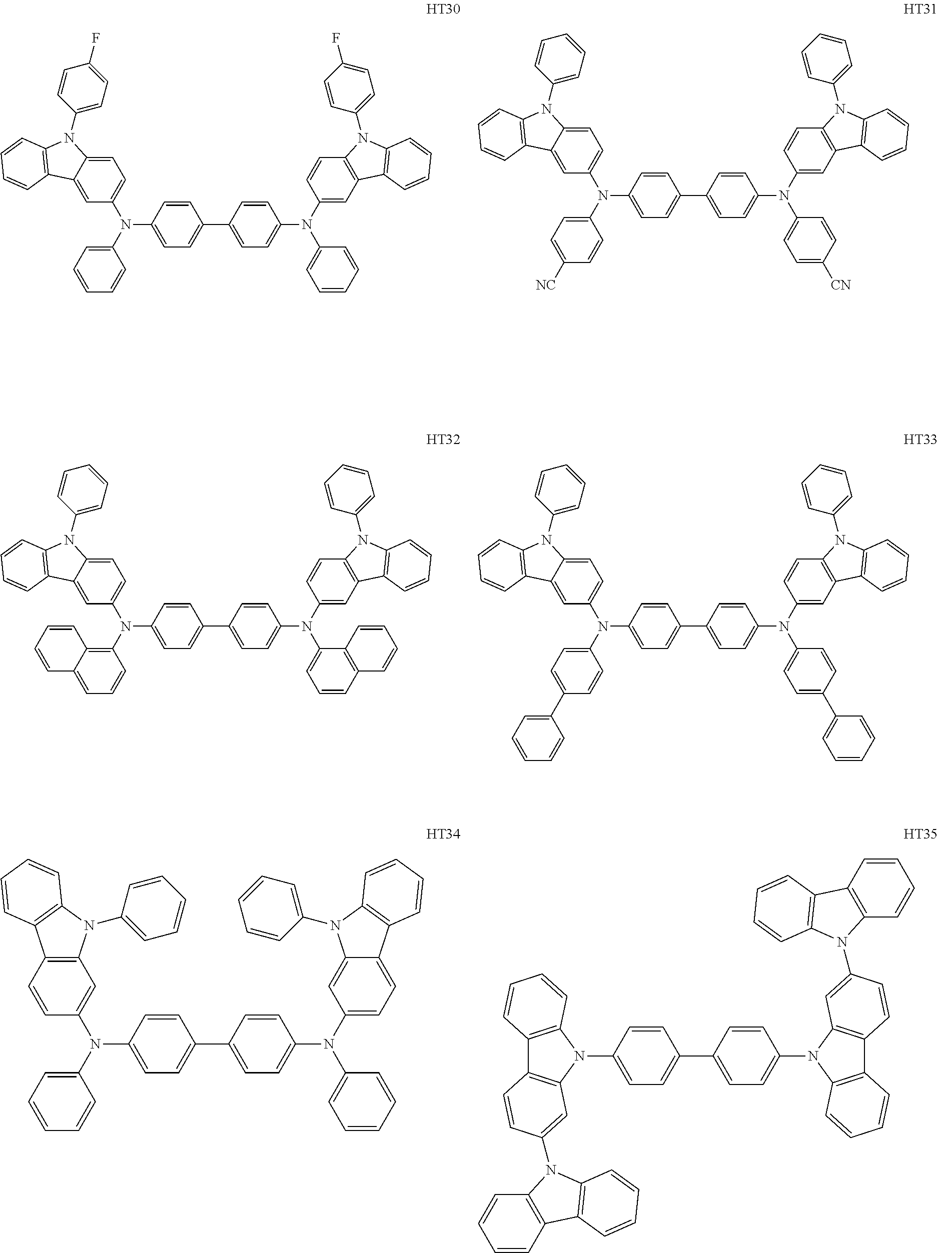

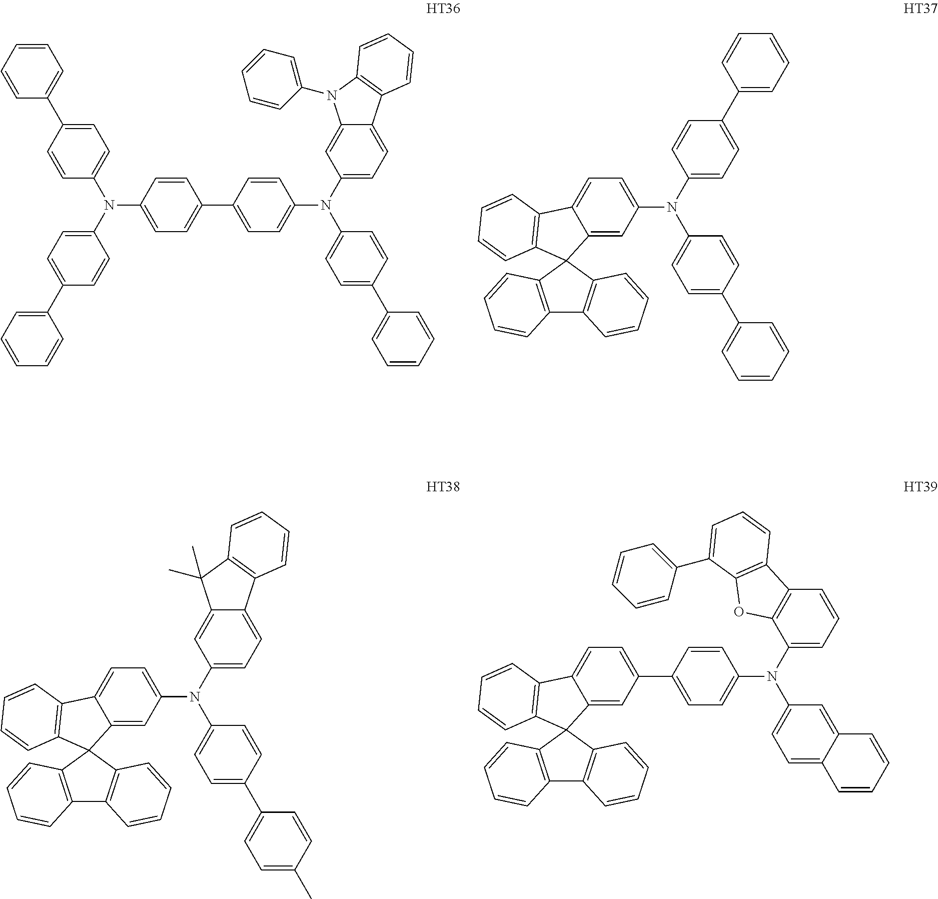 [SMILES: c1ccc(-c2ccc(N(c3ccc(-c4ccccc4)cc3)c3ccc(-c4ccc(N(c5ccc(-c6ccccc6)cc5)c5ccc6c7ccccc7n(-c7ccccc7)c6c5)cc4)cc3)cc2)cc1 ; c1ccc(-c2ccc(N(c3ccc(-c4ccccc4)cc3)c3ccc4c(c3)C3(c5ccccc5-c5ccccc53)c3ccccc3-4)cc2)cc1 ; Cc1ccc(-c2ccc(N(c3ccc4c(c3)C(C)(C)c3ccccc3-4)c3ccc4c(c3)C3(c5ccccc5-c5ccccc53)c3ccccc3-4)cc2)cc1 ; c1ccc(-c2cccc3c2oc2c(N(c4ccc(-c5ccc6c(c5)C5(c7ccccc7-c7ccccc75)c5ccccc5-6)cc4)c4ccc5ccccc5c4)cccc23)cc1]

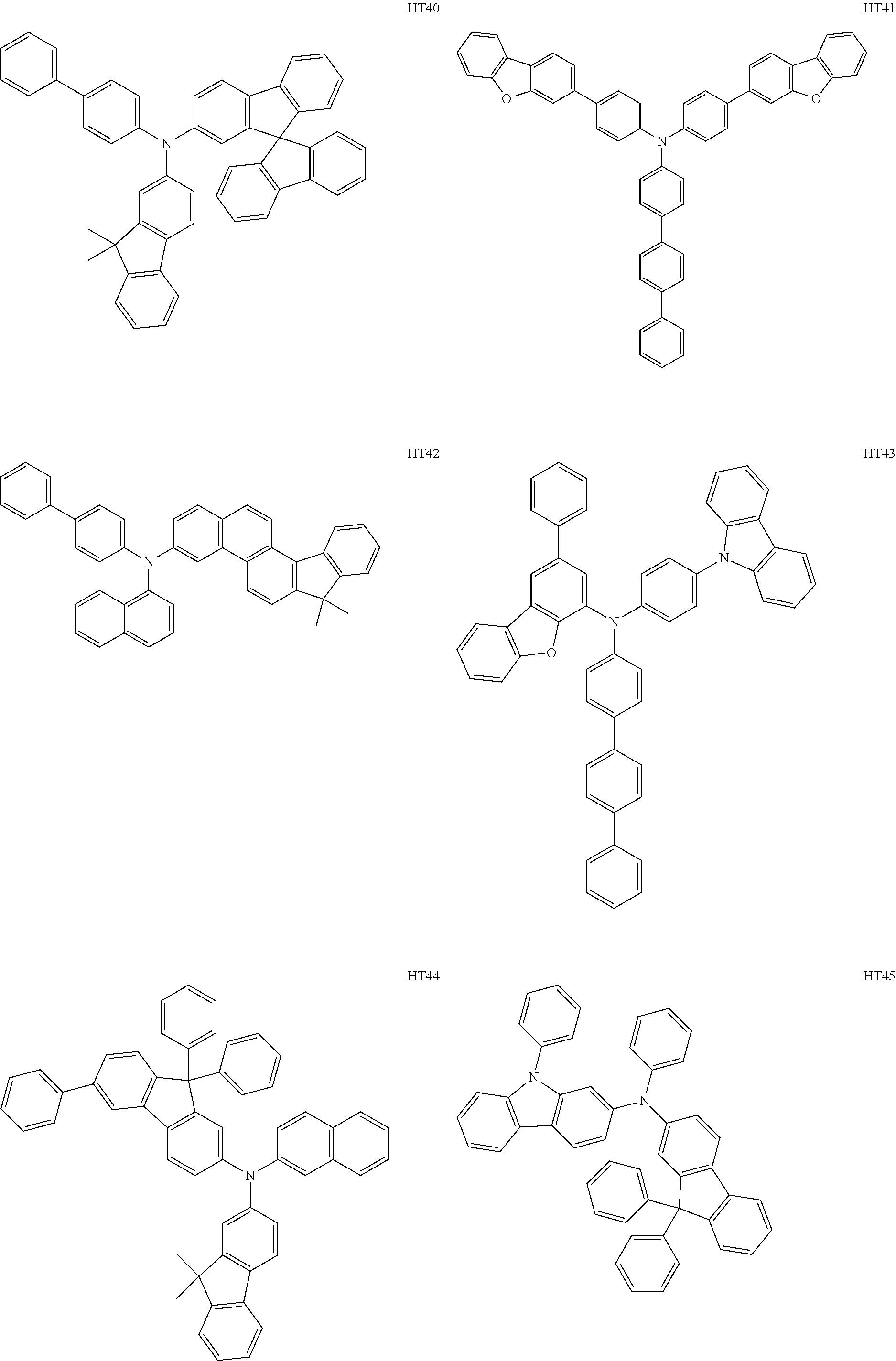

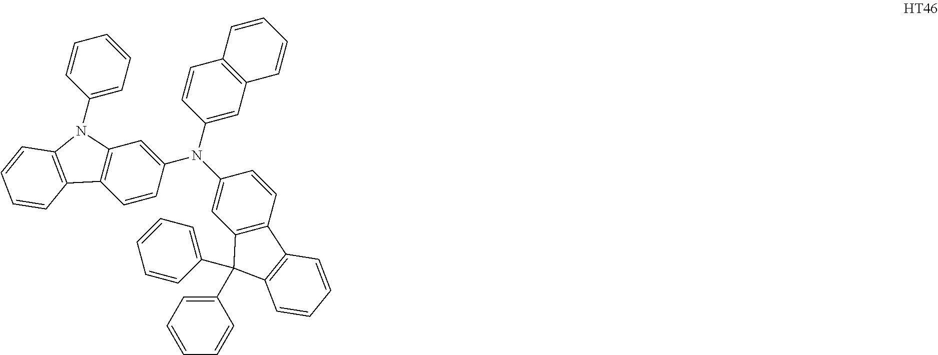 [SMILES: c1ccc(-n2c3ccccc3c3ccc(N(c4ccc5c(c4)C(c4ccccc4)(c4ccccc4)c4ccccc4-5)c4ccc5ccccc5c4)cc32)cc1]

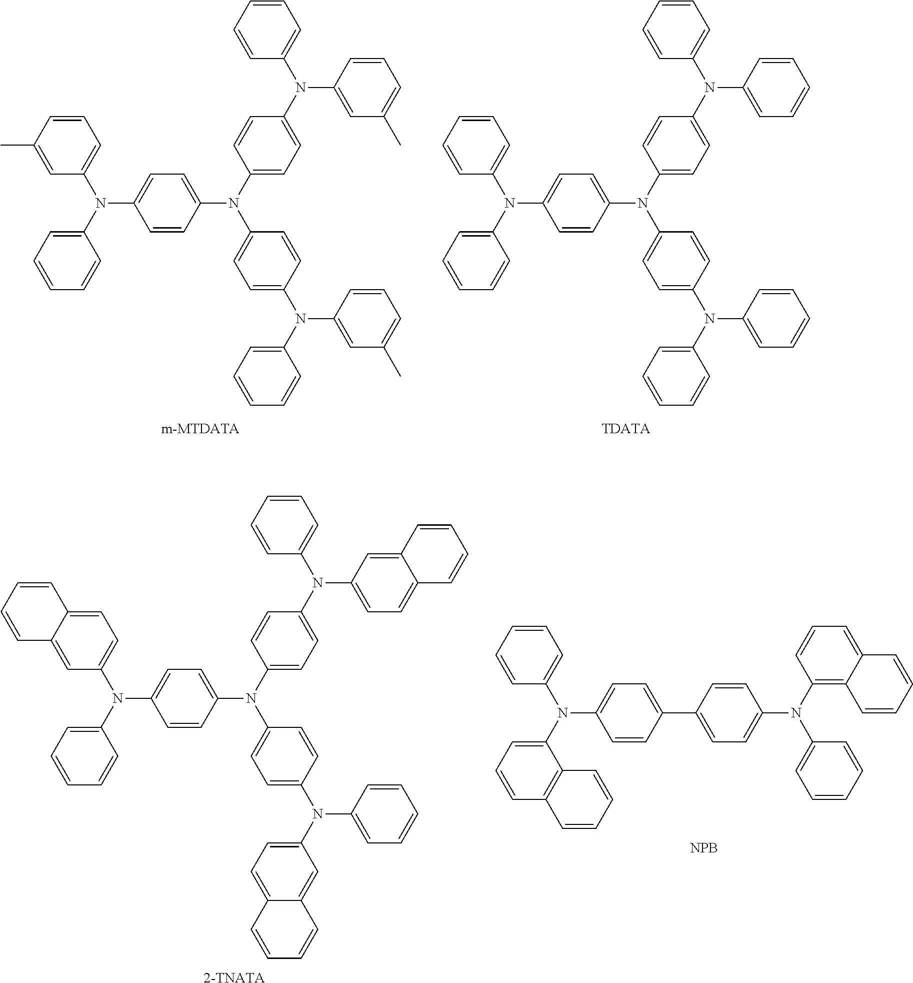

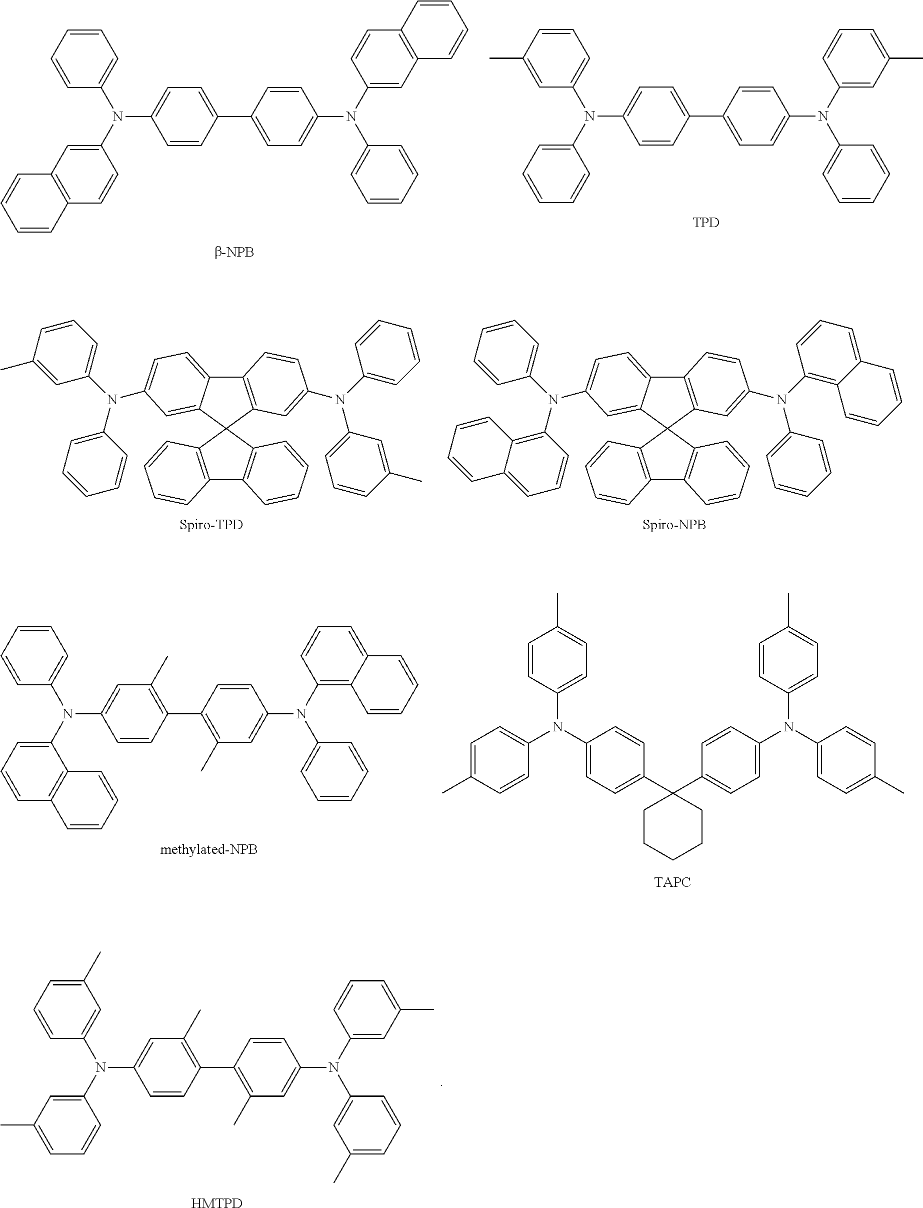

A thickness of the hole transport region may be in a range of about 50 Å to about 10,000 Å, for example, about 100 Å to about 4,000 Å. When the hole transport region includes a hole injection layer, a hole transport layer, and/or a (e.g., any suitable) combination thereof, a thickness of the hole injection layer may be in a range of about 100 Å to about 9,000 Å, for example, about 100 Å to about 1,000 Å, and a thickness of the hole transport layer may be in a range of about 50 Å to about 2,000 Å, for example, about 100 Å to about 1,500 Å. When the thicknesses of the hole transport region, the hole injection layer, and the hole transport layer are within these ranges, satisfactory hole transporting characteristics may be obtained without a substantial increase in driving voltage.

The emission auxiliary layer may increase light emission efficiency by compensating for an optical resonance distance according to the wavelength of light emitted by the emission layer, and the electron blocking layer may block or reduce the leakage of electrons from the emission layer to the hole transport region. Materials that may be included in the hole transport region may be included in the emission auxiliary layer and the electron blocking layer.

p-Dopant

The hole transport region may further include, in addition to the aforementioned materials, a charge-generation material for the improvement of conductive properties. The charge-generation material may be uniformly (e.g., substantially uniformly) or non-uniformly (e.g., substantially non-uniformly) dispersed in the hole transport region (e.g., in the form of a single layer including (e.g., consisting of) the charge-generation material).

The charge-generation material may be, for example, a p-dopant.

For example, the p-dopant may have a lowest unoccupied molecular orbital (LUMO) energy level of −3.5 eV or less.

In one or more embodiments, the p-dopant may include a quinone derivative, a cyano group-containing compound, a compound including element EL1 and element EL2, and/or a (e.g., any suitable) combination thereof.

Examples of the quinone derivative may include TCNQ, F4-TCNQ, and/or the like.

Examples of the cyano group-containing compound may include TCNQ, F4-TCNQ, HAT-CN, a compound represented by Formula 221, and/or the like:

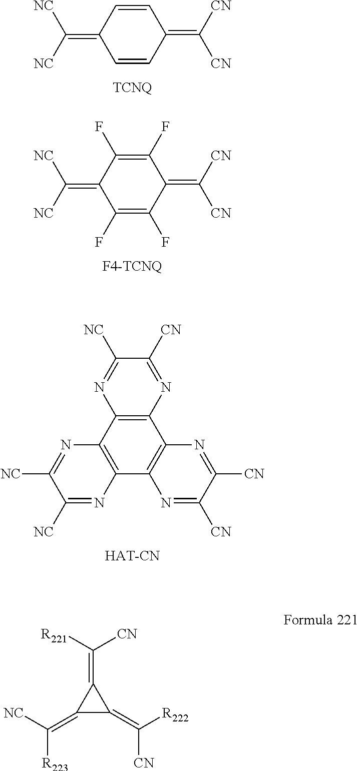

In Formula 221, R₂₂₁ to R₂₂₃ may each independently be a C₃-C₆₀ carbocyclic group unsubstituted or substituted with at least one R₁₀ₐ or a C₁-C₆₀ heterocyclic group unsubstituted or substituted with at least one R₁₀ₐ, and at least one of R₂₂₁ to R₂₂₃ may each independently be a C₃-C₆₀ carbocyclic group or a C₁-C₆₀ heterocyclic group, each substituted with: a cyano group; —F; —Cl; —Br; —I; a C₁-C₂₀ alkyl group substituted with a cyano group, —F, —Cl, —Br, —I, and/or a (e.g., any suitable) combination thereof; and/or a (e.g., any suitable) combination thereof.

In the compound including element EL1 and element EL2, element EL1 may be metal, metalloid, and/or a (e.g., any suitable) combination thereof, and element EL2 may be non-metal, metalloid, and/or a (e.g., any suitable) combination thereof.

Examples of the metal may include: an alkali metal (e.g., lithium (Li), sodium (Na), potassium (K), rubidium (Rb), cesium (Cs), and/or the like); an alkaline earth metal (e.g., beryllium (Be), magnesium (Mg), calcium (Ca), strontium (Sr), barium (Ba), and/or the like); a transition metal (e.g., titanium (Ti), zirconium (Zr), hafnium (Hf), vanadium (V), niobium (Nb), tantalum (Ta), chromium (Cr), molybdenum (Mo), tungsten (W), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), and/or the like); a post-transition metal (e.g., zinc (Zn), indium (In), tin (Sn), and/or the like); a lanthanide metal (e.g., lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), and/or the like); and/or the like.

Examples of the metalloid may include silicon (Si), antimony (Sb), tellurium (Te), and/or the like.

Examples of the non-metal may include oxygen (O), a halogen (e.g., F, Cl, Br, I, and/or the like), and/or the like.

For example, the compound including element EL1 and element EL2 may include a metal oxide, a metal halide (e.g., metal fluoride, metal chloride, metal bromide, metal iodide, and/or the like), a metalloid halide (e.g., metalloid fluoride, metalloid chloride, metalloid bromide, metalloid iodide, and/or the like), a metal telluride, and/or a (e.g., any suitable) combination thereof.

Examples of the metal oxide may include tungsten oxide (e.g., WO, W₂O₃, WO₂, WO₃, W₂O₅, and/or the like), vanadium oxide (e.g., VO, V₂O₃, VO₂, V₂O₅, and/or the like), molybdenum oxide (e.g., MoO, MO₂O₃, MoO₂, MoO₃, Mo₂O₅, and/or the like), rhenium oxide (e.g., ReO₃, and/or the like), and/or the like.

Examples of the metal halide may include alkali metal halide, alkaline earth metal halide, transition metal halide, post-transition metal halide, lanthanide metal halide, and/or the like.

Examples of the alkali metal halide may include LiF, NaF, KF, RbF, CsF, LiCl, NaCl, KCl, RbCI, CsCl, UlBr, NaBr, KBr, RbBr, CsBr, Lil, Nal, KI, Rbl, Csl, and/or the like.

Examples of the alkaline earth metal halide may include BeF₂, MgF₂, CaF₂, SrF₂, BaF₂, BeCl₂, MgCl₂, CaCl₂, SrCl₂, BaCl₂, BeBr₂, MgBr₂, CaBr₂, SrBr₂, BaBr₂, BeI₂, MgI₂, CaI₂, SrI₂, BaI₂, and/or the like.

Examples of the transition metal halide may include titanium halide (e.g., TiF₄, TiC₄, TiBr₄, Til₄, and/or the like), zirconium halide (e.g., ZrF₄, ZrCl₄, ZrBr₄, Zrl₄, and/or the like), hafnium halide (e.g., HfF₄, HfCl₄, HfBr₄, HfI₄, and/or the like), vanadium halide (e.g., VF₃, VCl₃, VBr₃, Vis, and/or the like), niobium halide (e.g., NbF₃, NbCl₃, NbBr₃, NbI₃, and/or the like), tantalum halide (e.g., TaF₃, TaCl₃, TaBr₃, TaI₃, and/or the like), chromium halide (e.g., CrF₃, CrCl₃, CrBr₃, CrI₃, and/or the like), molybdenum halide (e.g., MoF₃, MoCl₃, MoBr₃, MoI₃, and/or the like), tungsten halide (e.g., WF₃, WCl₃, WBr₃, WI₃, and/or the like), manganese halide (e.g., MnF₂, MnCl₂, MnBr₂, MnI₂, and/or the like), technetium halide (e.g., TcF₂, TcCl₂, TcBr₂, Tcl₂, and/or the like), rhenium halide (e.g., ReF₂, ReCl₂, ReBr₂, ReI₂, and/or the like), iron halide (e.g., FeF₂, FeCl₂, FeBr₂, FeI₂, and/or the like), ruthenium halide (e.g., RuF₂, RuCl₂, RuBr₂, RuI₂, and/or the like), osmium halide (e.g., OsF₂, OsCl₂, OsBr₂, OsI₂, and/or the like), cobalt halide (e.g., CoF₂, CoCl₂, CoBr₂, CoI₂, and/or the like), rhodium halide (e.g., RhF₂, RhCl₂, RhBr₂, RhI₂, and/or the like), iridium halide (e.g., IrF₂, IrCl₂, IrBr₂, IrI₂, and/or the like), nickel halide (e.g., NiF₂, NiCl₂, NiBr₂, NiI₂, and/or the like), palladium halide (e.g., PdF₂, PdCl₂, PdBr₂, PdI₂, and/or the like), platinum halide (e.g., PtF₂, PtCl₂, PtBr₂, PtI₂, and/or the like), copper halide (e.g., CuF, CuCl, CuBr, Cul, and/or the like), silver halide (e.g., AgF, AgCl, AgBr, Agl, and/or the like), gold halide (e.g., AuF, AuCl, AuBr, AuI, and/or the like), and/or the like.

Examples of the post-transition metal halide may include zinc halide (e.g., ZnF₂, ZnCl₂, ZnBr₂, ZnI₂, and/or the like), indium halide (e.g., InI₃, and/or the like), tin halide (e.g., SnI₂, and/or the like), and/or the like.

Examples of the lanthanide metal halide may include YbF, YbF₂, YbF₃, SmF₃, YbCl, YbCl₂, YbCl₃ SmCl₃, YbBr, YbBr₂, YbBr₃ SmBr₃, YbI, YbI₂, YbI₃, Sml₃, and/or the like.

Examples of the metalloid halide may include antimony halide (e.g., SbCl₅, etc.) and/or the like.

Examples of the metal telluride may include alkali metal telluride (e.g., Li₂Te, Na₂Te, K₂Te, Rb₂Te, Cs₂Te, and/or the like), alkaline earth metal telluride (e.g., BeTe, MgTe, CaTe, SrTe, BaTe, and/or the like), transition metal telluride (e.g., TiTe₂, ZrTe₂, HfTe₂, V₂Te₃, Nb₂Te₃, Ta₂Te₃, Cr₂Te₃, Mo₂Te₃, W₂Te₃, MnTe, TcTe, ReTe, FeTe, RuTe, OsTe, CoTe, RhTe, IrTe, NiTe, PdTe, PtTe, Cu₂Te, CuTe, Ag₂Te, AgTe, Au₂Te, and/or the like), post-transition metal telluride (e.g., ZnTe, and/or the like), lanthanide metal telluride (e.g., LaTe, CeTe, PrTe, NdTe, PmTe, EuTe, GdTe, TbTe, DyTe, HoTe, ErTe, TmTe, YbTe, LuTe, and/or the like), and/or the like.

### Emission Layer in Interlayer 130

When the light-emitting device 1A is a full-color light-emitting device, the emission layer may be patterned into a red emission layer, a green emission layer, and/or a blue emission layer, according to a sub-pixel. In one or more embodiments, the emission layer may have a stacked structure of two or more layers among a red emission layer, a green emission layer, and a blue emission layer, in which the two or more layers contact each other or are separated from each other, to emit white light. In one or more embodiments, the emission layer may include two or more materials among a red light-emitting material, a green light-emitting material, and a blue light-emitting material, in which the two or more materials are mixed with each other in a single layer, to emit white light.

The emission layer may include the quantum dots.

The term “quantum dots” as used herein refers to crystals of a semiconductor compound, and may include any material capable of emitting light of one or more suitable emission wavelengths according to the size of the crystals. The quantum dots may be to emit light of one or more suitable emission wavelengths by adjusting the element ratio in the quantum dot compound.

A diameter of the quantum dots may be, for example, in a range of about 1 nm to about 10 nm.

The quantum dots may be synthesized by a wet chemical process, a metal organic chemical vapor deposition process, a molecular beam epitaxy process, and/or a (e.g., and suitable) process similar thereto.

The wet chemical process is a method including mixing a precursor material with an organic solvent and then growing quantum dot particle crystals. When the crystals grow, the organic solvent naturally acts as a dispersant coordinated on the surface of the quantum dot crystals and controls the growth of the crystals so that the growth of quantum dot particles may be controlled or selected through a process which costs less and is easier than vapor deposition methods, such as metal organic chemical vapor deposition (MOCVD) or molecular beam epitaxy (MBE).

The quantum dots may include: a Group II-VI semiconductor compound; a Group III-V semiconductor compound; a Group III-VI semiconductor compound; a Group I-III-VI semiconductor compound; a Group IV-VI semiconductor compound; a Group IV element or compound; and/or a (e.g., any suitable) combination thereof.

Examples of the Group II-VI semiconductor compound are: a binary compound, such as CdS, CdSe, CdTe, ZnS, ZnSe, ZnTe, ZnO, HgS, HgSe, HgTe, MgSe, MgS, and/or the like; a ternary compound, such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and/or the like; a quaternary compound, such as CdZnSeS, CdZnSeTe, CdZnSTe, CdHgSeS, CdHgSeTe, CdHgSTe, HgZnSeS, HgZnSeTe, HgZnSTe, and/or the like; and/or a (e.g., any suitable) combination thereof.

Examples of the Group III-V semiconductor compound may include: a binary compound, such as GaN, GaP, GaAs, GaSb, AlN, AlP, AlAs, AlSb, InN, InP, InAs, InSb, and/or the like; a ternary compound, such as GaNP, GaNAs, GaNSb, GaPAs, GaPSb, AlNP, AlNAs, AlNSb, AlPAs, AlPSb, InGaP, InNP, InAlP, InNAs, InNSb, InPAs, InPSb, GaAlNP, and/or the like; a quaternary compound, such as GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and/or the like; and/or a (e.g., any suitable) combination thereof. In one or more embodiments, the Group III-V semiconductor compound may further include a Group II element. Examples of the Group III-V semiconductor compound further including a Group II element may include InZnP, InGaZnP, InAIZnP, and/or the like.

Examples of the Group III-VI semiconductor compound may include: a binary compound, such as GaS, GaSe, Ga₂Se₃, GaTe, InS, InSe, In₂S₃, In₂Sea, InTe, and/or the like; a ternary compound, such as InGaS₃, InGaSes, and/or the like; and/or a (e.g., any suitable) combination thereof.

Examples of the Group I-III-VI semiconductor compound may include: a ternary compound, such as AgInS, AgInS₂, AgInSe₂, AgGaS, AgGaS₂, AgGaSe₂, CuInS, CulnS₂, CulnSe₂, CuGaS₂, CuGaSe₂, CuGaO₂, AgGaO₂, AgAIO₂, and/or the like; a quaternary compound, such as AgInGaS₂, AgInGaSe₂, and/or the like; and/or a (e.g., any suitable) combination thereof.

Examples of the Group IV-VI semiconductor compound may include: a binary compound, such as SnS, SnSe, SnTe, PbS, PbSe, or PbTe; a ternary compound, such as SnSeS, SnSeTe, SnSTe, PbSeS, PbSeTe, PbSTe, SnPbS, SnPbSe, SnPbTe, and/or the like; a quaternary compound, such as SnPbSSe, SnPbSeTe, SnPbSTe, and/or the like; and/or a (e.g., any suitable) combination thereof.

The Group IV element or compound may include: a single element compound, such as Si, Ge, and/or the like; a binary compound, such as SiC, SiGe, and/or the like; and/or a (e.g., any suitable) combination thereof.

Each element included in a multi-element compound, such as the binary compound, the ternary compound, and the quaternary compound, may be present at a substantially uniform concentration or non-uniform (substantially non-uniform) concentration in a particle. For example, the formulae above refer to types (kinds) of elements included in the compound, and the element ratios within the compound may vary. For example, AgInGaS₂ refers to AgInₓGa₁₋ₓS₂ (where x is a real number between and 1).

In one or more embodiments, the quantum dots may have a single structure in which the concentration of each element in the quantum dots is substantially uniform, or a core-shell dual structure. For example, materials included in the core and materials included in the shell may be different from each other.

The shell of the quantum dots may act as a protective layer that prevents chemical degeneration of the core to maintain semiconductor characteristics, and/or as a charging layer that imparts electrophoretic characteristics to the quantum dots. The shell may be single-layered or multi-layered. The interface between the core and the shell may have a concentration gradient in which the concentration of an element existing in the shell decreases toward the center of the core.

Examples of the shell of the quantum dots may include: an oxide of metal, metalloid, or non-metal; a semiconductor compound; and/or a (e.g., any suitable) combination thereof. Examples of the oxide of metal, metalloid, or non-metal may include: a binary compound, such as SiO₂, Al₂O₃, TiO₂, ZnO, MnO, Mn₂O₃, Mn₃O₄, CuO, FeO, Fe₂O₃, Fe₃O₄, CoO, CO₃O₄, NiO, and/or the like; a ternary compound, such as MgAl₂O₄, CoFe₂O₄, NiFe₂O₄, CoMn₂O₄, and/or the like; and/or a (e.g., any suitable) combination thereof. Examples of the semiconductor compound may include: as described above, a Group II-VI semiconductor compound; a Group III-V semiconductor compound; a Group III-VI semiconductor compound; a Group I-III-VI semiconductor compound; a Group IV-VI semiconductor compound; and/or a (e.g., any suitable) combination thereof. Examples of the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, and/or a (e.g., any suitable) combination thereof.

Each element included in the multi-element compound such as the binary compound and the ternary compound may be present in the particle at a substantially uniform or non-uniform (substantially non-uniform) concentration. For example, the formulae above refer to types (kinds) of elements included in the compound, and the element ratios within the compound may vary.

A full width at half maximum (FWHM) of an emission wavelength spectrum of the quantum dots may be about 45 nm or less, for example, about 40 nm or less, and for example, about 30 nm or less, and within these ranges, the color purity or color reproducibility of the quantum dots may be improved. In one or more embodiments, because light emitted through the quantum dots is emitted in all directions, the wide viewing angle may be improved.

In one or more embodiments, the quantum dots may be nanoparticles, nanotubes, nanowires, nanofibers, nanoplates, and/or the like, specifically in the form of spherical particles, pyramidal particles, multi-arm particles, or cubic particles.

By controlling the size (e.g., diameter or radius) of the quantum dots, the energy band gap may be adjustable so that light having one or more suitable wavelength bands may be obtained from the emission layer including the quantum dots. Accordingly, by using the quantum dots of different sizes, a light-emitting device that emits light of one or more suitable wavelengths may be implemented. For example, the control of the size of the quantum dots or the ratio of elements in the quantum dot compound may be selected to emit red light, green light, and/or blue light. In one or more embodiments, the size of the quantum dots may be configured to emit white light by combination of light of one or more suitable colors.

The emission layer may be formed by applying the ink composition onto the hole transport region and volatilizing at least a portion of the solvent included in the ink composition.

The ink composition may be applied by ink jet printing, spin coating, casting, micro gravure coating, gravure coating, bar coating, roll coating, wire bar coating, dip coating, spry coating, screen printing, flexographic printing, offset printing, and/or the like.

In one or more embodiments, the emission layer may further include, in addition to the quantum dots, a host and a dopant. The dopant may include a phosphorescent dopant, a fluorescent dopant, and/or a (e.g., any suitable) combination thereof.

An amount of the dopant in the emission layer may be in a range of about 0.01 parts by weight to about 15 parts by weight based on 100 parts by weight of the host.

In one or more embodiments, the emission layer may include a delayed fluorescence material. The delayed fluorescence material may act as a host or a dopant in the emission layer.

A thickness of the emission layer may be in a range of about 100 Å to about 1,000 Å, for example, about 200 Å to about 600 Å. When the thickness of the emission layer is within these ranges, excellent or suitable luminescence characteristics may be obtained without a substantial increase in driving voltage.

### Host

In one or more embodiments, the host may include a compound represented by Formula 301:

[Ar₃₀₁]xb11-[(L₃₀₁)xb1-R₃₀₁]xb21 Formula 301

In Formula 301, Ar₃₀₁ and L₃₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ, xb11 may be 1, 2, or 3, xb1 may be an integer from 0 to 5, R₃₀₁ may be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₃₀₁)(Q₃₀₂)(Q₃₀₃), —N(Q₃₀₁)(Q₃₀₂), —B(Q₃₀₁)(Q₃₀₂), —C(═O)(Q₃₀₁), —S(═O)₂(Q₃₀₁), or —P(═O)(Q₃₀₁)(Q₃₀₂), xb21 may be an integer from 1 to 5, and Q₃₀₁ to Q₃₀₃ are each the same as described in connection with Q₁.

For example, if (e.g., when) xb11 in Formula 301 is 2 or more, two or more of Ar₃₀₁ may be linked to each other via a single bond.

In one or more embodiments, the host may include a compound represented by Formula 301-1, a compound represented by Formula 301-2, and/or a (e.g., any suitable) combination thereof:

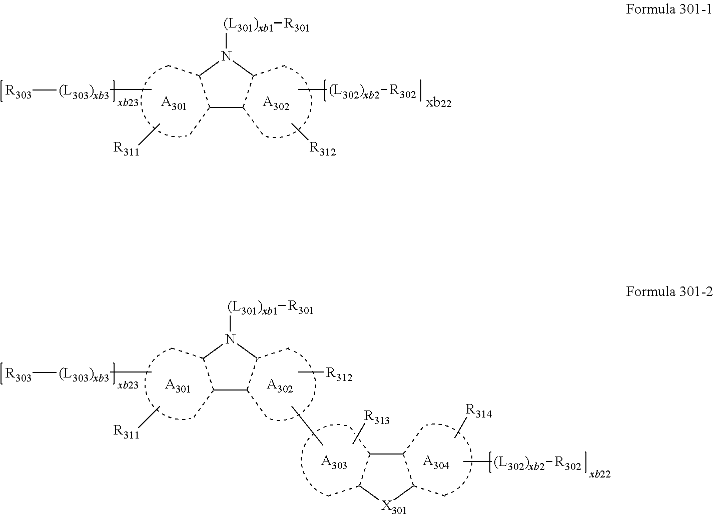

In Formulae 301-1 and 301-2, ring A₃₀₁ to ring A₃₀₄ may each independently be a C₃-C₆₀ carbocyclic group unsubstituted or substituted with at least one R₁₀ₐ or a C₁-C₆₀ heterocyclic group unsubstituted or substituted with at least one R₁₀ₐ, X₃₀₁ may be O, S, N-[(L₃₀₄)xb4-R₃₀₄], C(R₃₀₄)(R₃₀₅), or Si(R₃₀₄)(R₃₀₅), xb22 and xb23 may each independently be 0, 1, or 2, L₃₀₁, xb1, and R₃₀₁ are each the same as described herein, L₃₀₂ to L₃₀₄ may each independently be the same as described in connection with L₃₀₁, xb2 to xb4 may each independently be the same as described in connection with xb1, and R₃₀₂ to R₃₀₅ and R₃₁₁ to R₃₁₄ are each the same as described herein in connection with R₃₀₁.

In one or more embodiments, the host may include an alkali earth metal complex, a post-transition metal complex, and/or a (e.g., any suitable) combination thereof. In one or more embodiments, the host may include a Be complex (e.g., Compound H55), an Mg complex, a Zn complex, and/or a (e.g., any suitable) combination thereof.

In one or more embodiments, the host may include: at least one of Compounds H1 to H128; 9,10-di(2-naphthyl)anthracene (ADN); 2-methyl-9,10-bis(naphthalen-2-yl)anthracene (MADN); 9,10-di(2-naphthyl)-2-t-butyl-anthracene (TBADN); 4,4′-bis(N-carbazolyl)-1,1′-biphenyl (CBP); 1,3-di-9-carbazolylbenzene (mCP); 1,3,5-tri(carbazol-9-yl)benzene (TCP); and/or a (e.g., any suitable) combination thereof:

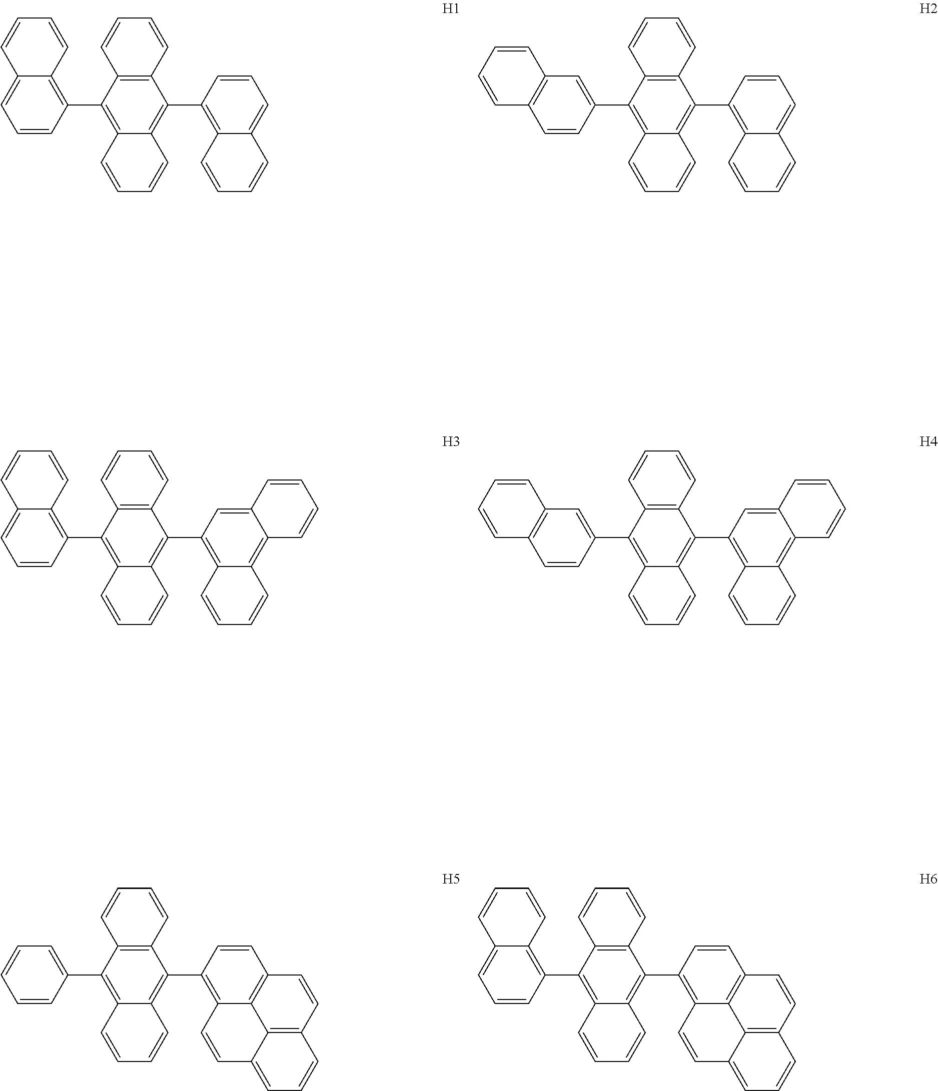

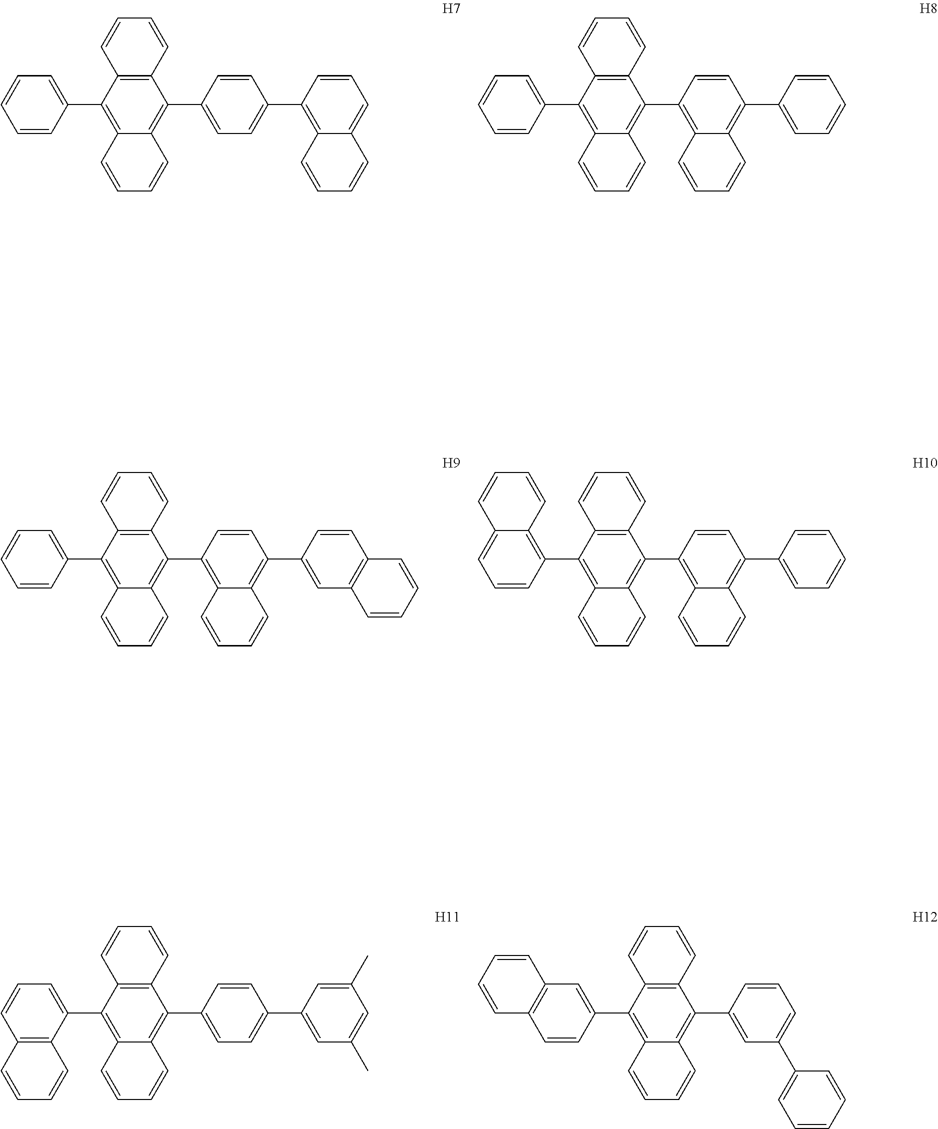

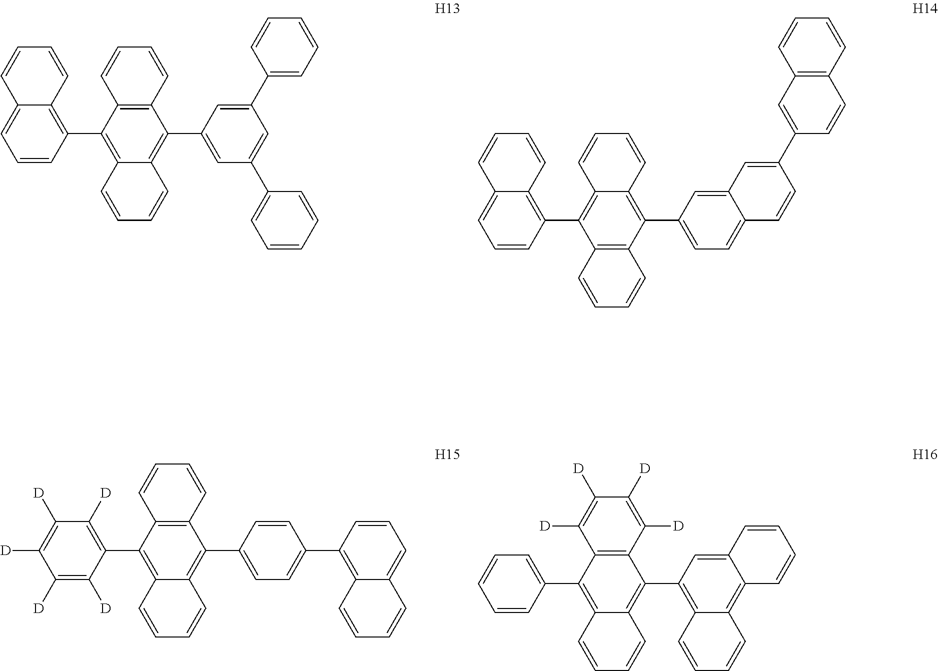

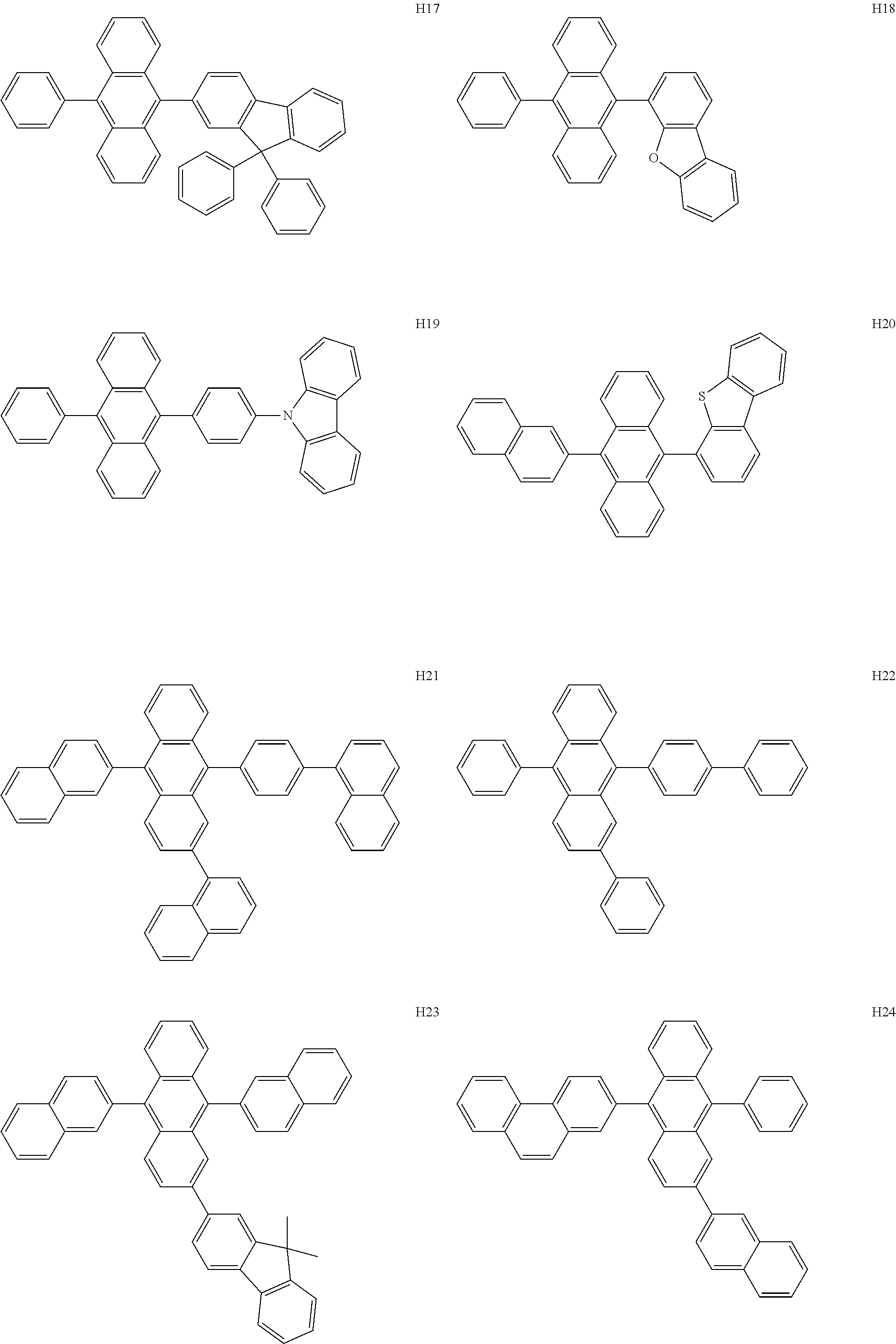

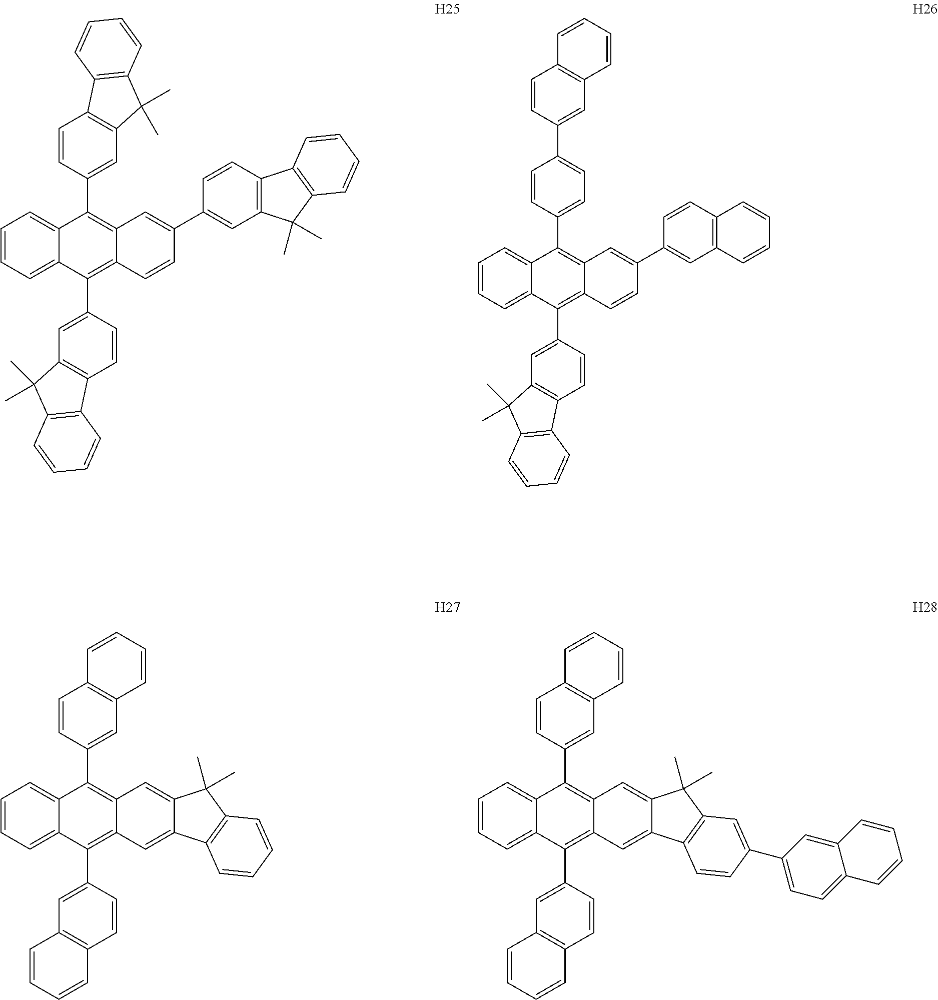

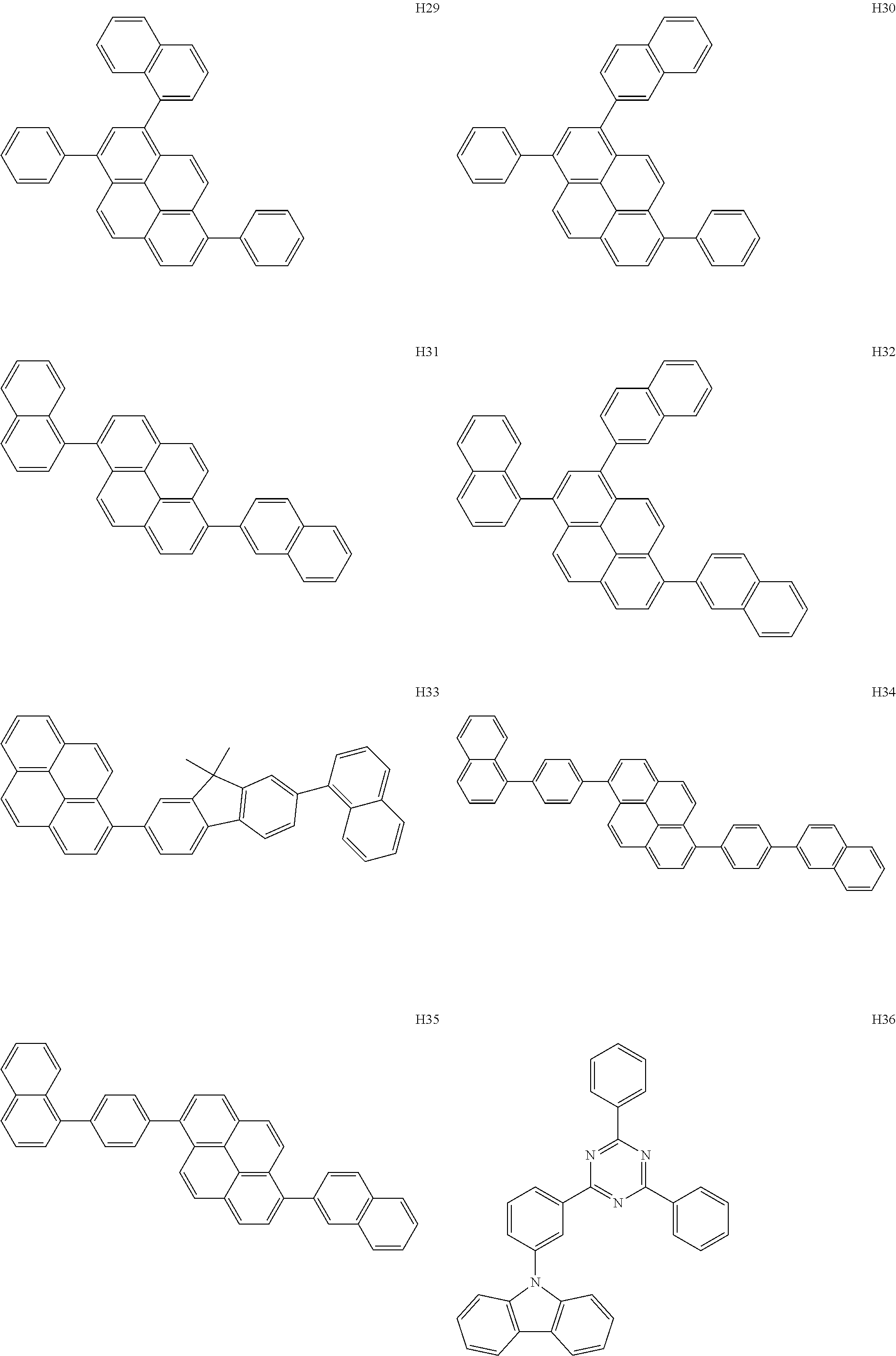

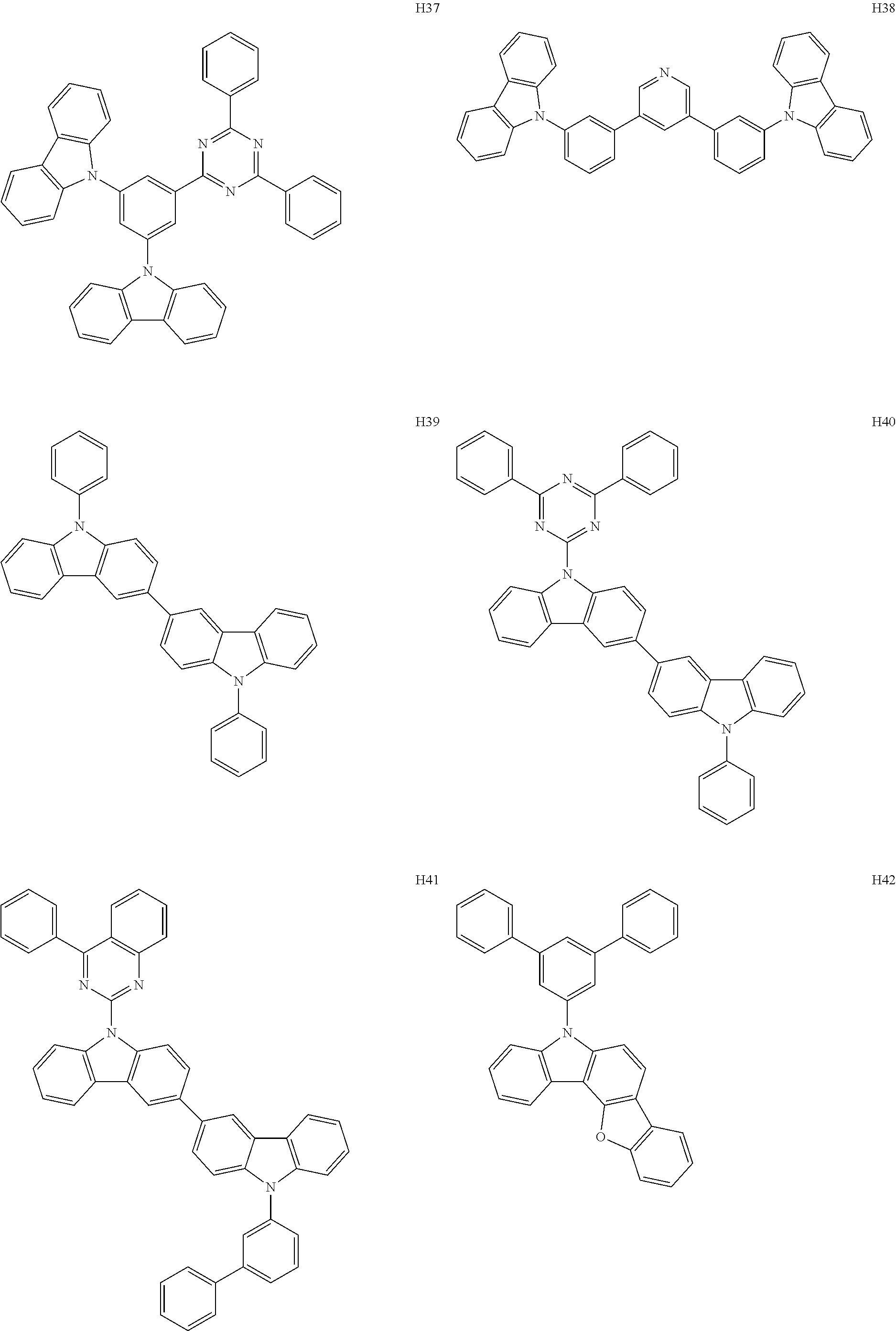 [SMILES: c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1 ; c1ccc(-n2c3ccccc3c3cc(-c4ccc5c(c4)c4ccccc4n5-c4ccccc4)ccc32)cc1 ; c1ccc(-c2nc(-c3ccccc3)nc(-n3c4ccccc4c4cc(-c5ccc6c(c5)c5ccccc5n6-c5ccccc5)ccc43)n2)cc1 ; c1ccc(-c2cccc(-n3c4ccccc4c4cc(-c5ccc6c(c5)c5ccccc5n6-c5nc(-c6ccccc6)c6ccccc6n5)ccc43)c2)cc1 ; c1ccc(-c2cc(-c3ccccc3)cc(-n3c4ccccc4c4c5oc6ccccc6c5ccc43)c2)cc1]

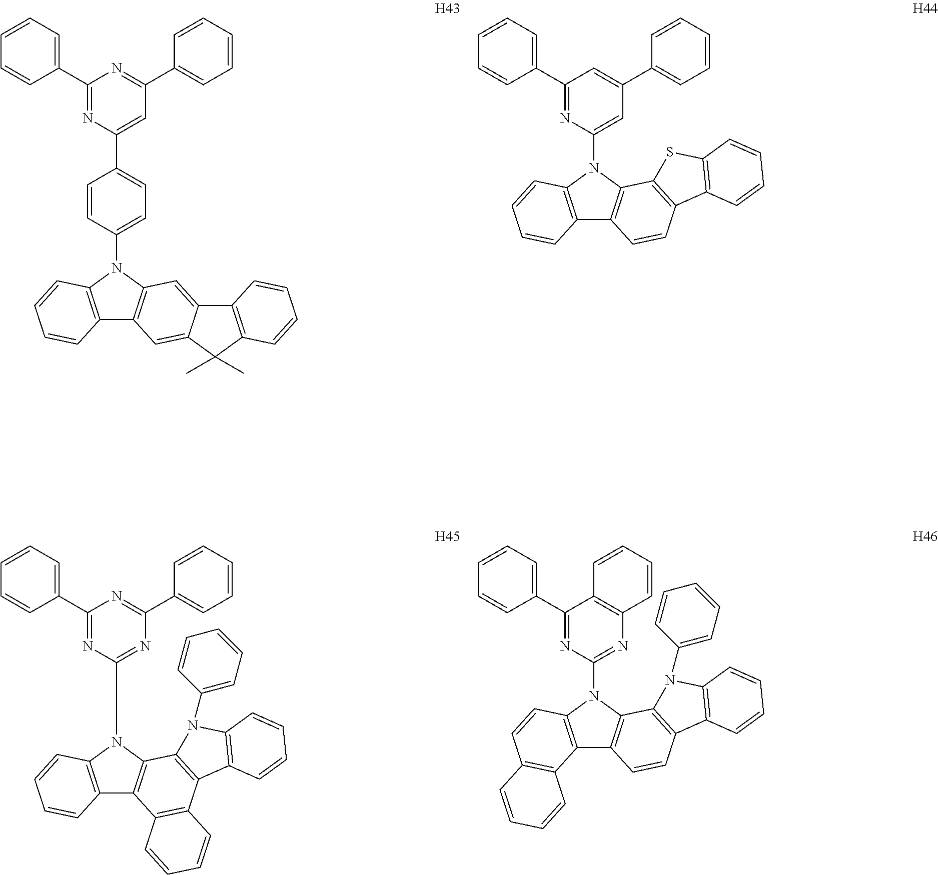 [SMILES: CC1(C)c2ccccc2-c2cc3c(cc21)c1ccccc1n3-c1ccc(-c2cc(-c3ccccc3)nc(-c3ccccc3)n2)cc1 ; c1ccc(-c2cc(-c3ccccc3)nc(-n3c4ccccc4c4ccc5c6ccccc6sc5c43)c2)cc1 ; c1ccc(-c2nc(-c3ccccc3)nc(-n3c4ccccc4c4c5ccccc5c5c6ccccc6n(-c6ccccc6)c5c43)n2)cc1 ; c1ccc(-c2nc(-n3c4ccc5ccccc5c4c4ccc5c6ccccc6n(-c6ccccc6)c5c43)nc3ccccc23)cc1]

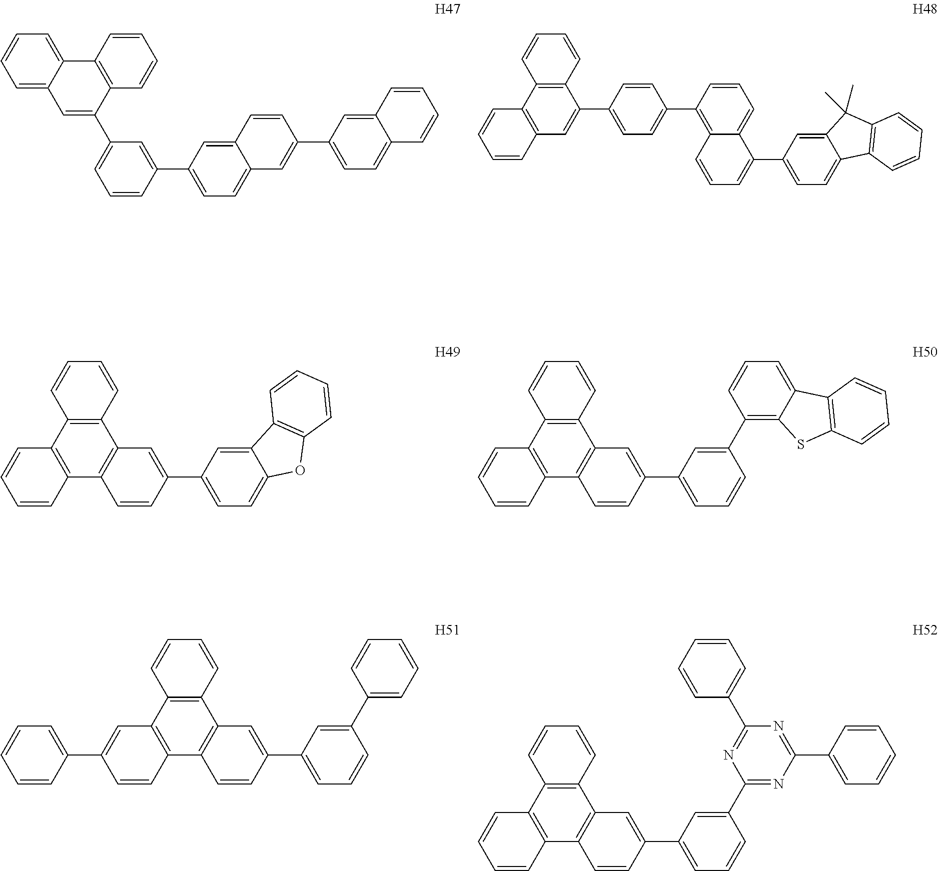

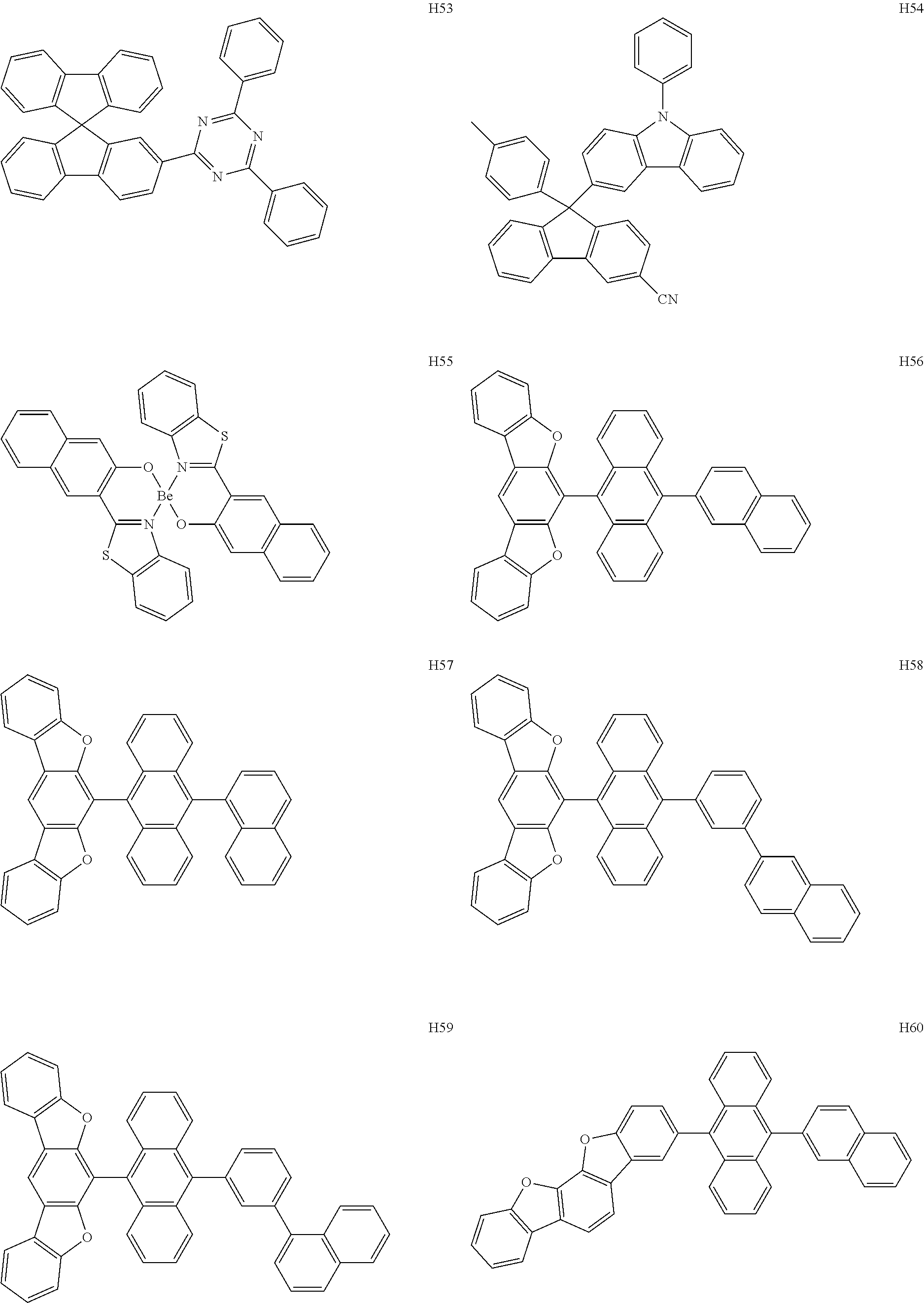

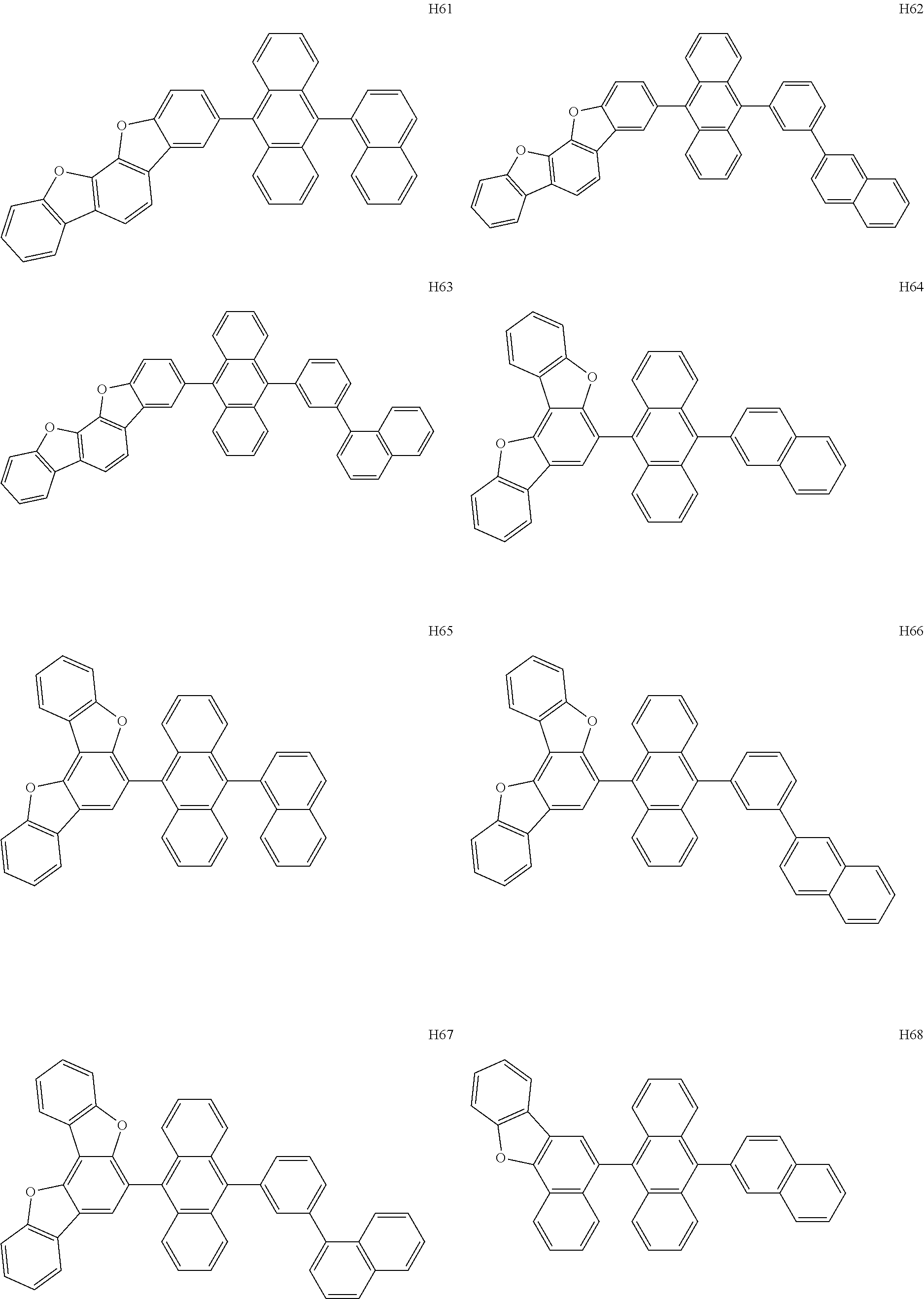

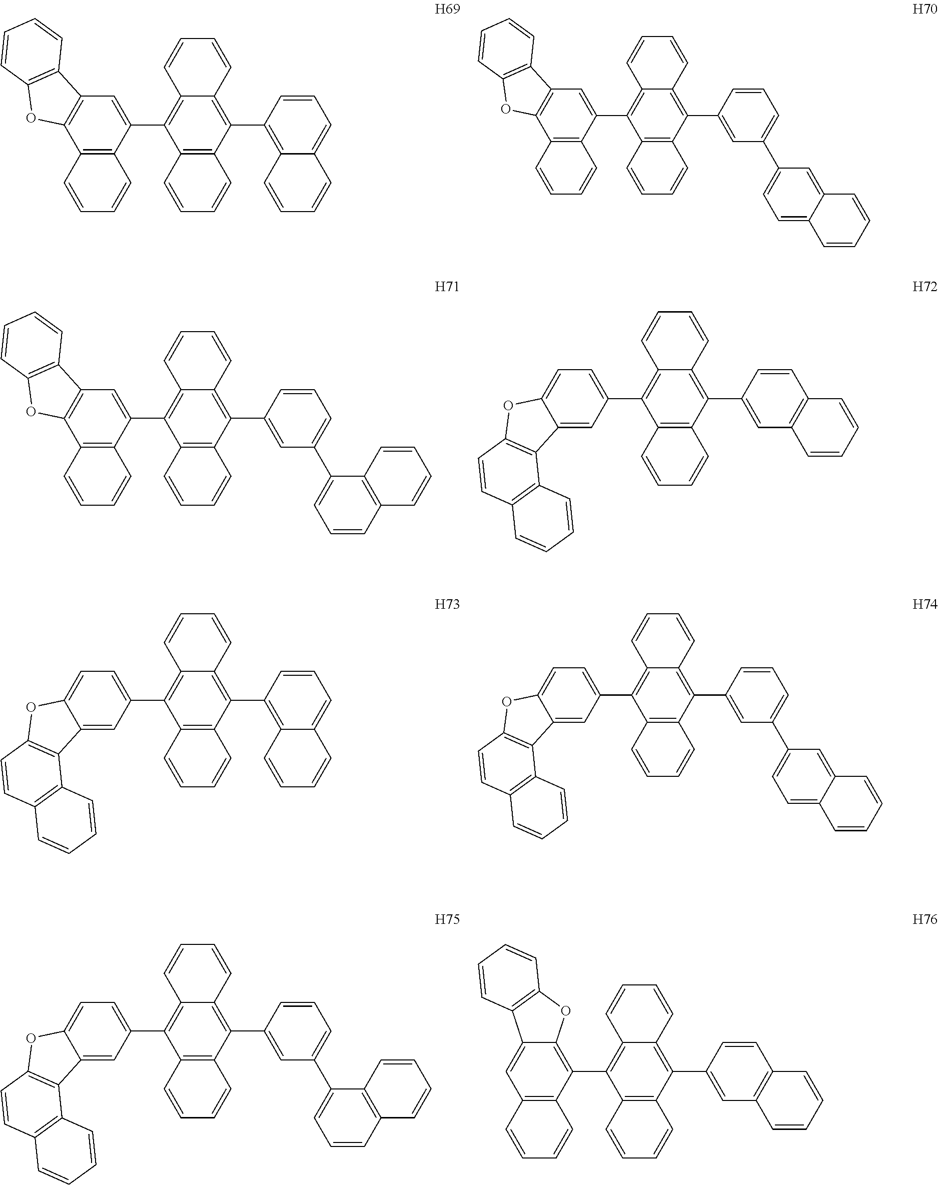

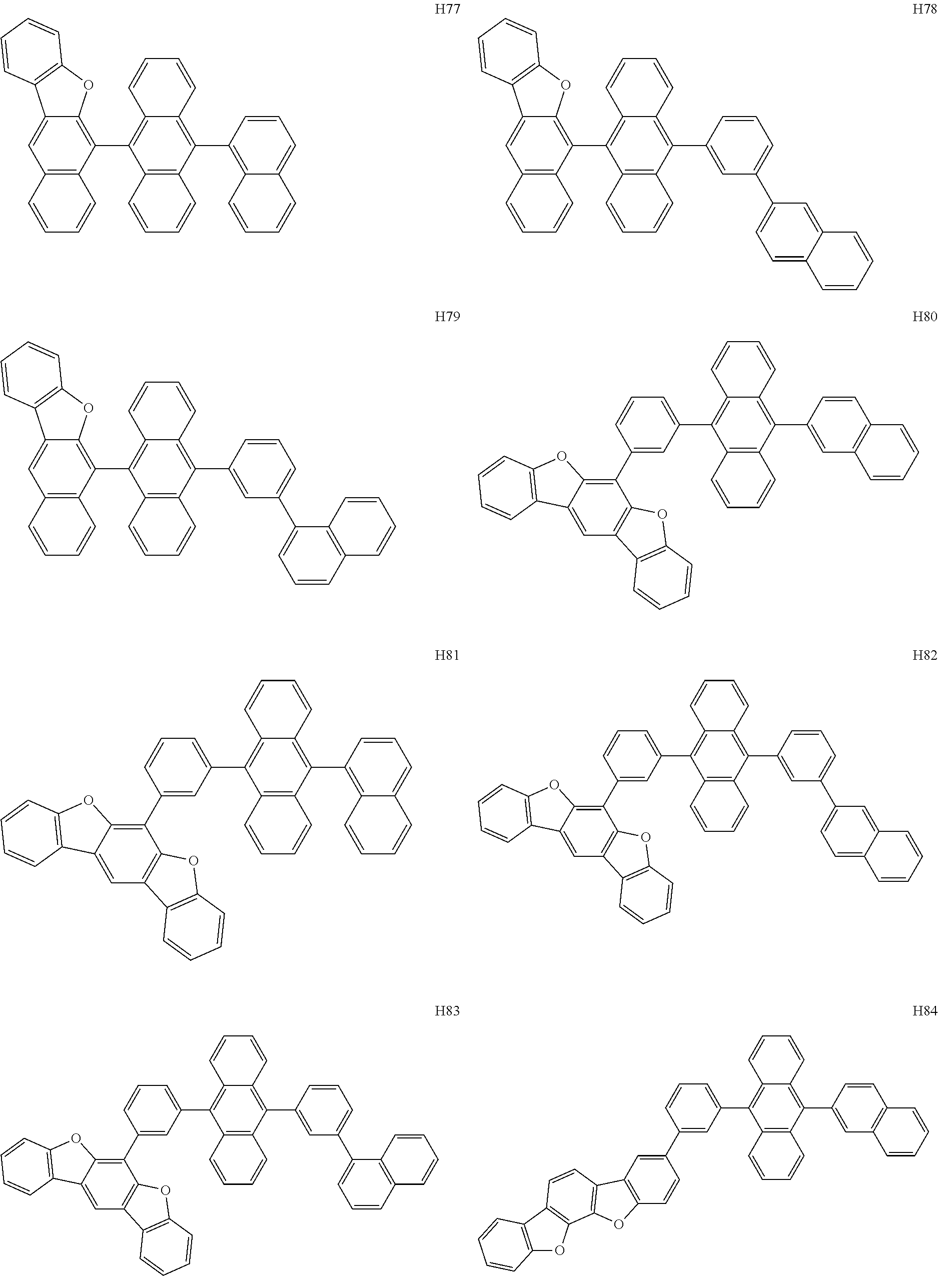

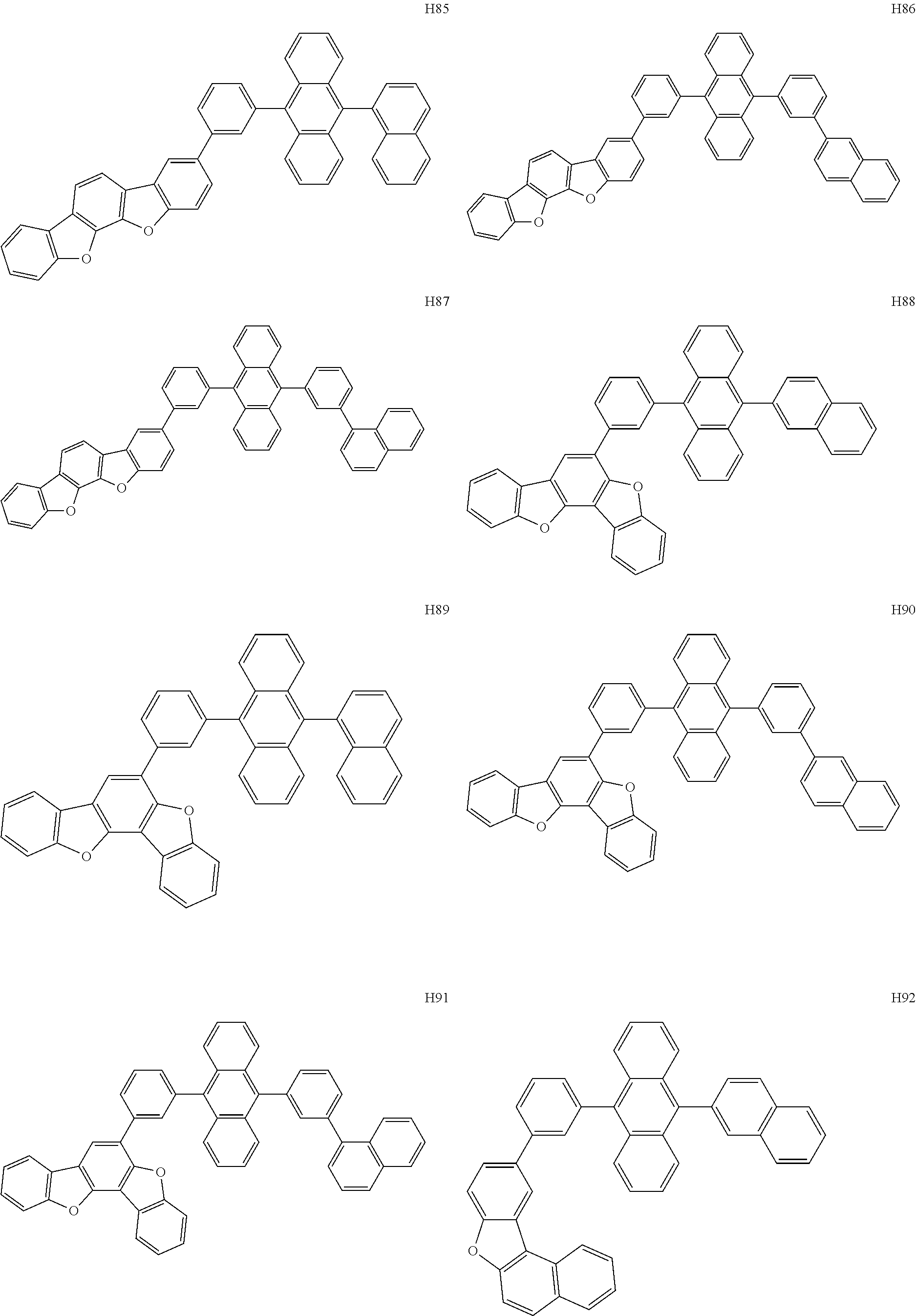

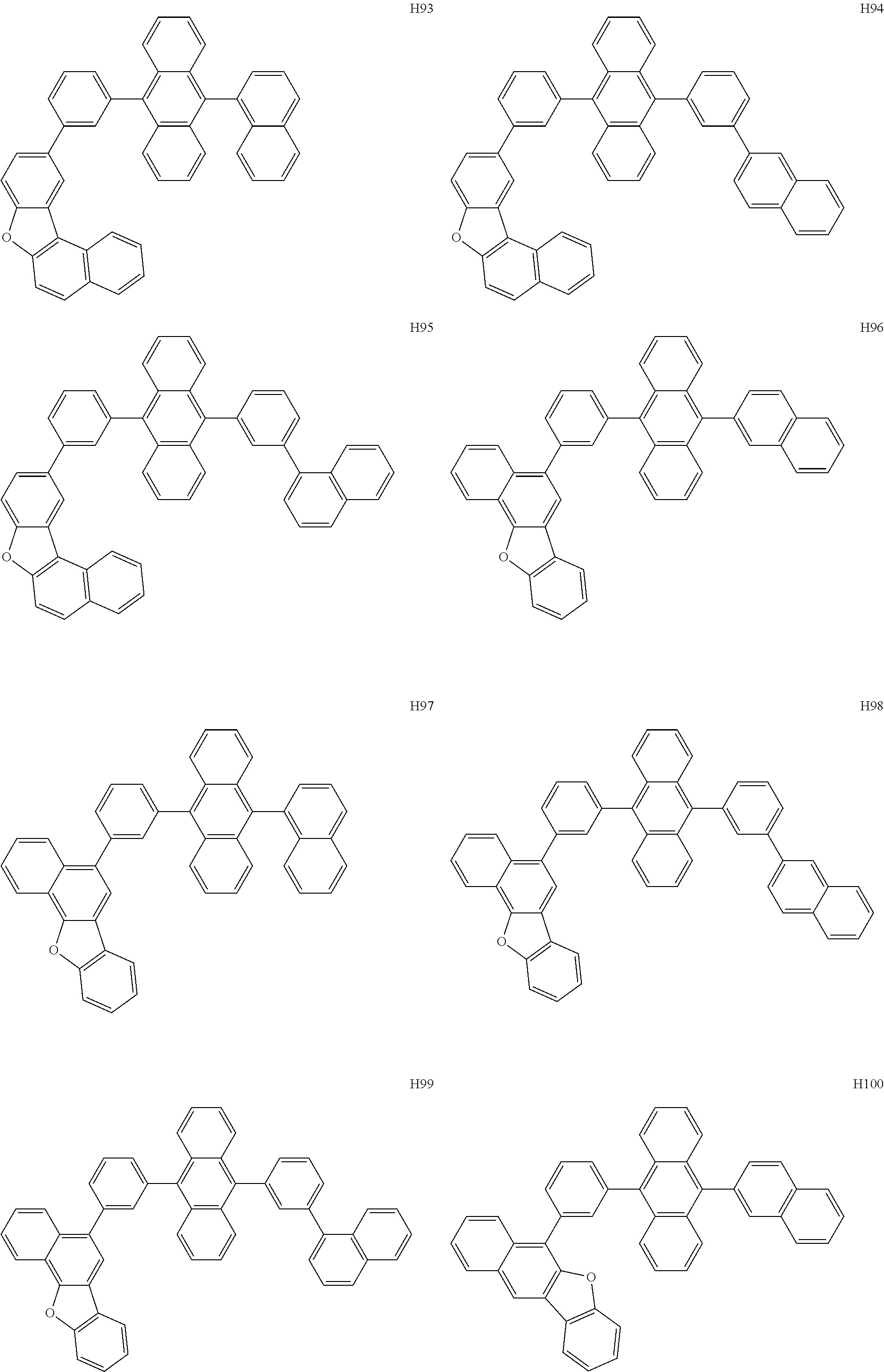

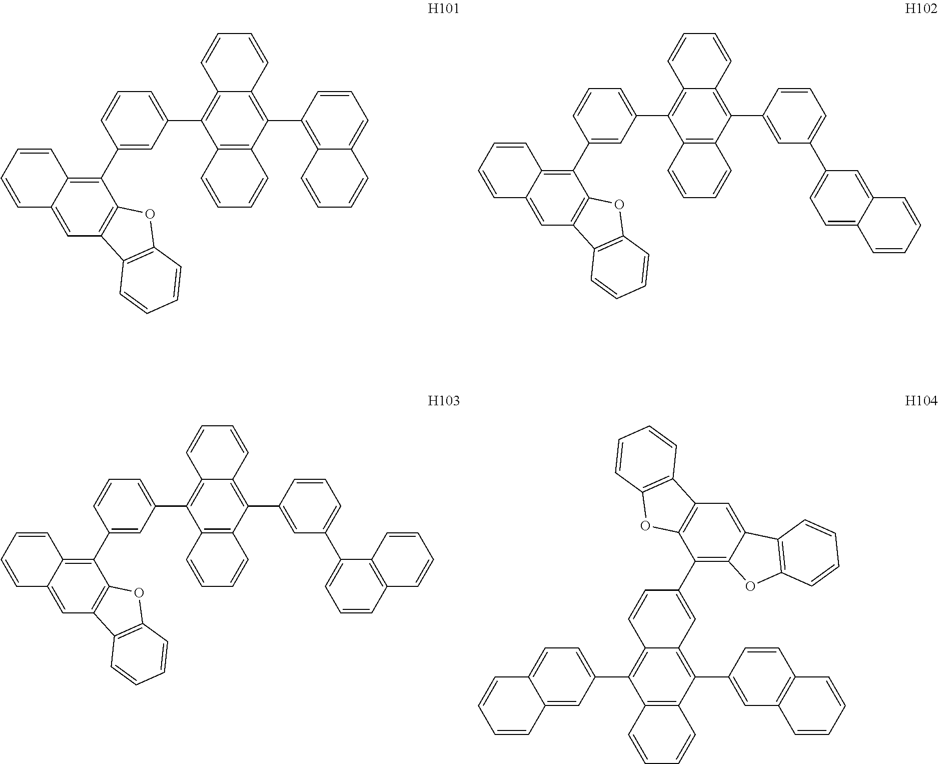 [SMILES: c1cc(-c2c3ccccc3c(-c3cccc4ccccc34)c3ccccc23)cc(-c2c3ccccc3cc3c2oc2ccccc23)c1 ; c1cc(-c2ccc3ccccc3c2)cc(-c2c3ccccc3c(-c3cccc(-c4c5ccccc5cc5c4oc4ccccc45)c3)c3ccccc23)c1 ; c1cc(-c2cccc3ccccc23)cc(-c2c3ccccc3c(-c3cccc(-c4c5ccccc5cc5c4oc4ccccc45)c3)c3ccccc23)c1 ; c1ccc2cc(-c3c4ccccc4c(-c4ccc5ccccc5c4)c4cc(-c5c6oc7ccccc7c6cc6c5oc5ccccc56)ccc34)ccc2c1]

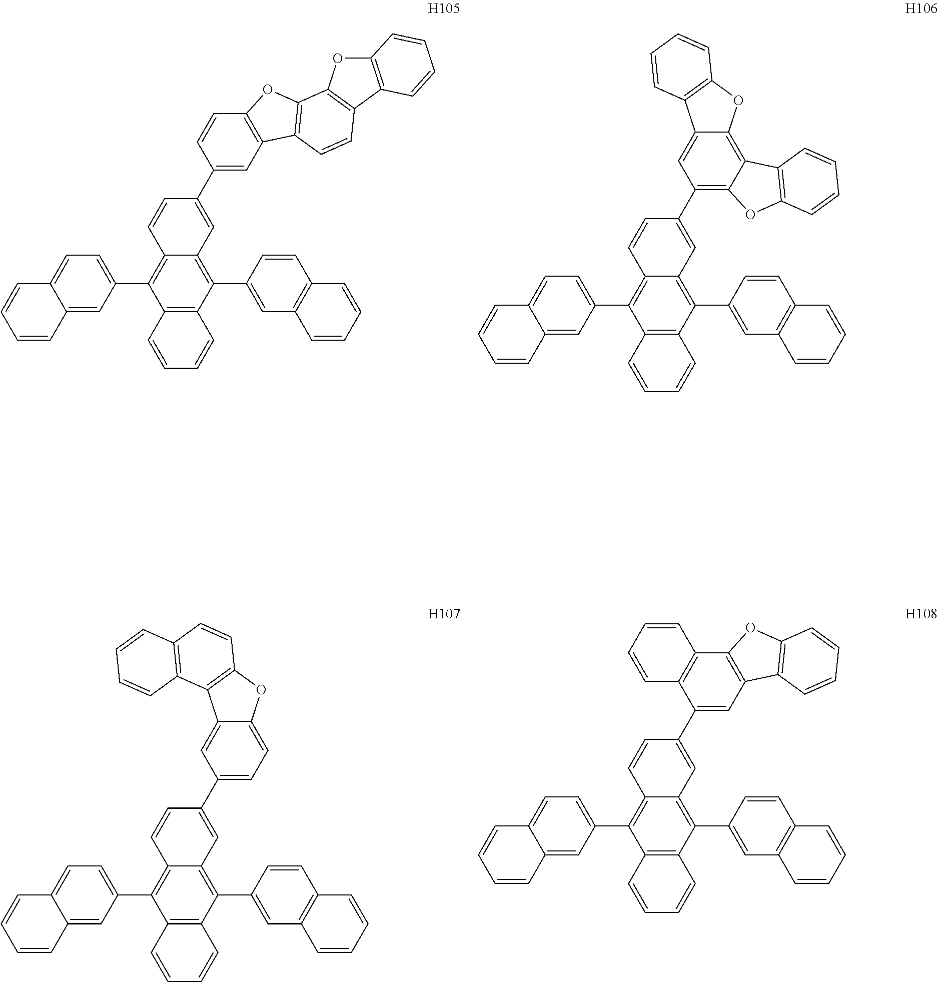 [SMILES: c1ccc2cc(-c3c4ccccc4c(-c4ccc5ccccc5c4)c4cc(-c5ccc6oc7c(ccc8c9ccccc9oc87)c6c5)ccc34)ccc2c1 ; c1ccc2cc(-c3c4ccccc4c(-c4ccc5ccccc5c4)c4cc(-c5cc6c7ccccc7oc6c6c5oc5ccccc56)ccc34)ccc2c1 ; c1ccc2cc(-c3c4ccccc4c(-c4ccc5ccccc5c4)c4cc(-c5ccc6oc7ccc8ccccc8c7c6c5)ccc34)ccc2c1 ; c1ccc2cc(-c3c4ccccc4c(-c4ccc5ccccc5c4)c4cc(-c5cc6c7ccccc7oc6c6ccccc56)ccc34)ccc2c1]

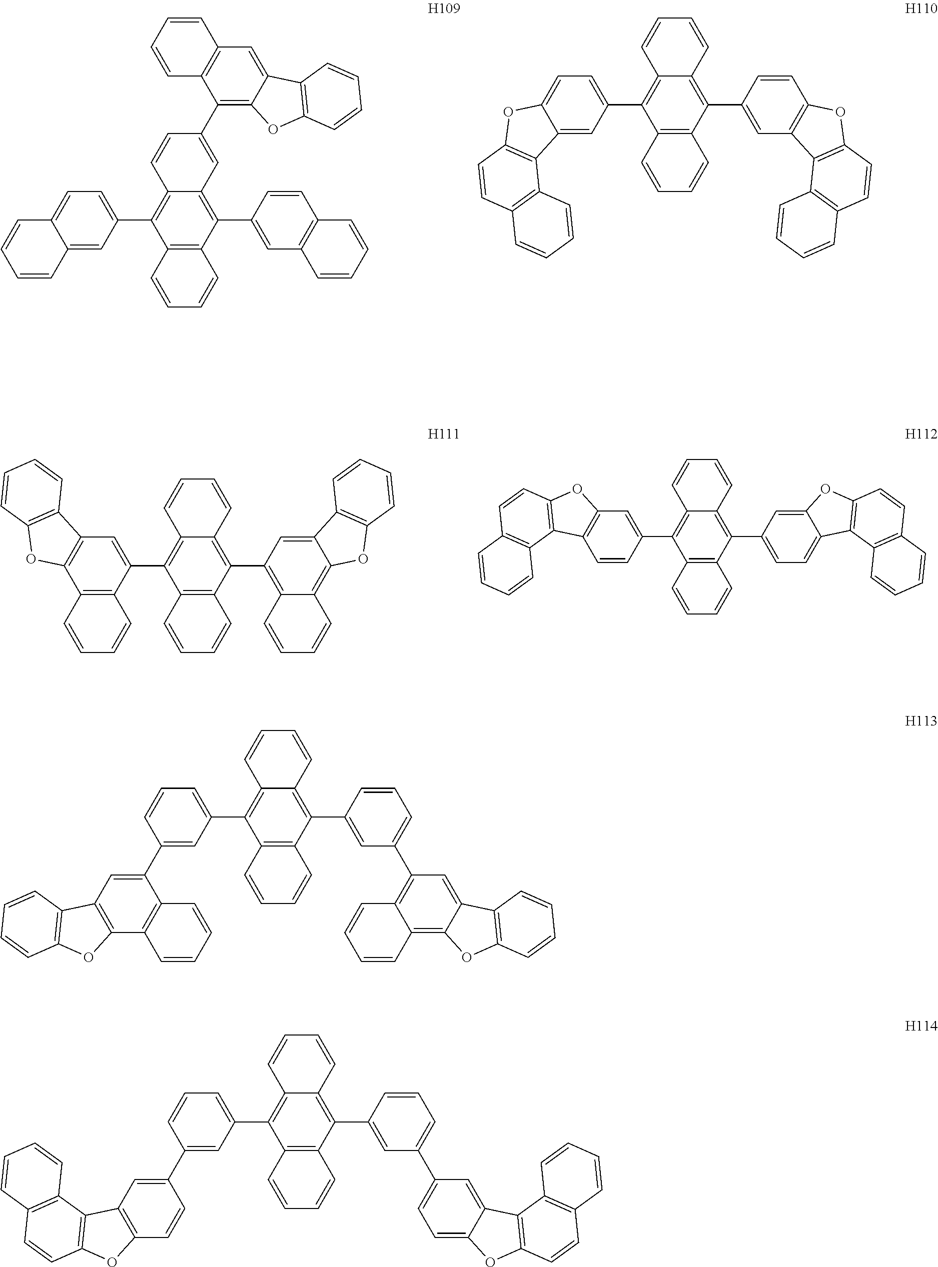

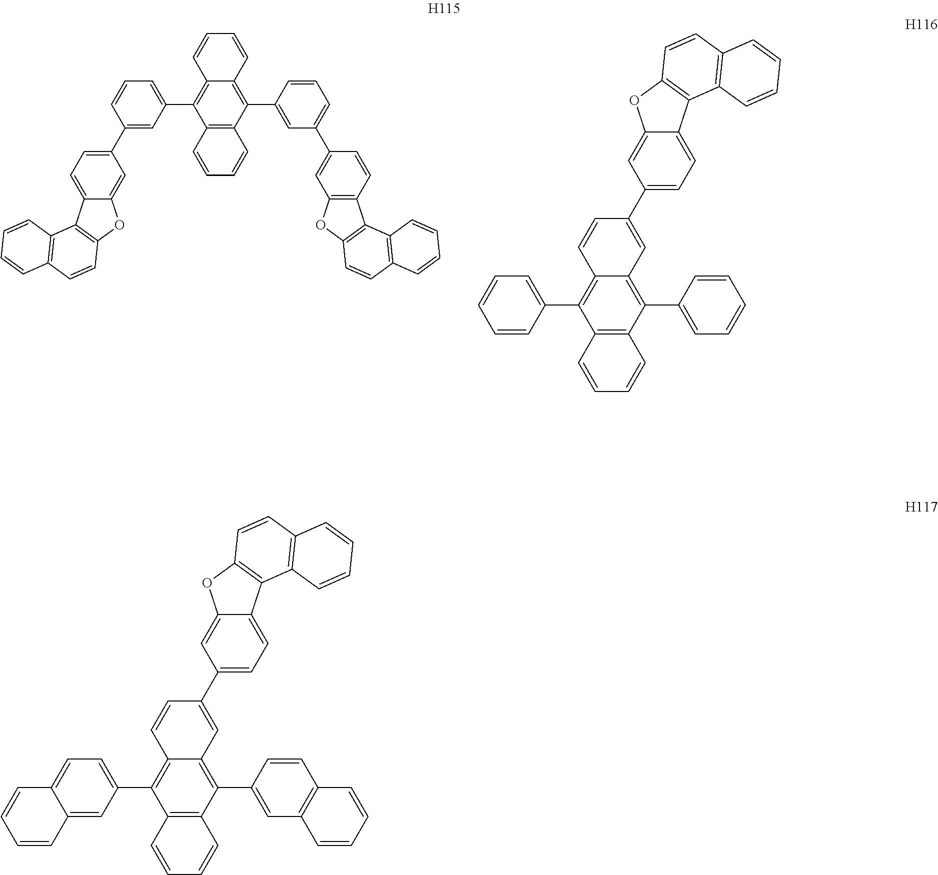 [SMILES: c1cc(-c2ccc3c(c2)oc2ccc4ccccc4c23)cc(-c2c3ccccc3c(-c3cccc(-c4ccc5c(c4)oc4ccc6ccccc6c45)c3)c3ccccc23)c1 ; c1ccc(-c2c3ccccc3c(-c3ccccc3)c3cc(-c4ccc5c(c4)oc4ccc6ccccc6c45)ccc23)cc1 ; c1ccc2cc(-c3c4ccccc4c(-c4ccc5ccccc5c4)c4cc(-c5ccc6c(c5)oc5ccc7ccccc7c56)ccc34)ccc2c1]

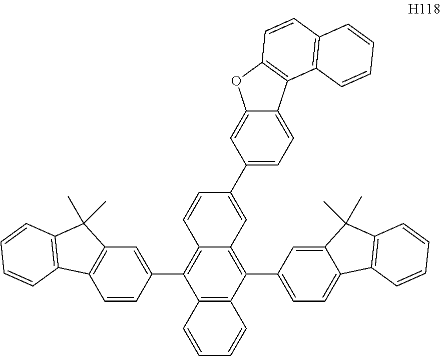 [SMILES: CC1(C)c2ccccc2-c2ccc(-c3c4ccccc4c(-c4ccc5c(c4)C(C)(C)c4ccccc4-5)c4cc(-c5ccc6c(c5)oc5ccc7ccccc7c56)ccc34)cc21]

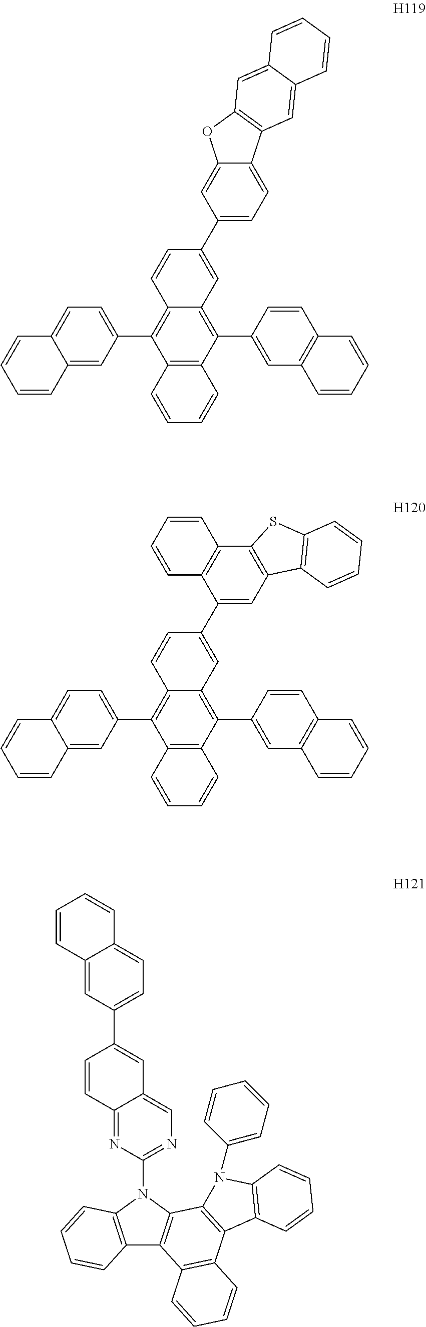 [SMILES: c1ccc2cc(-c3c4ccccc4c(-c4ccc5ccccc5c4)c4cc(-c5ccc6c(c5)oc5cc7ccccc7cc56)ccc34)ccc2c1 ; c1ccc2cc(-c3c4ccccc4c(-c4ccc5ccccc5c4)c4cc(-c5cc6c7ccccc7sc6c6ccccc56)ccc34)ccc2c1 ; c1ccc(-n2c3ccccc3c3c4ccccc4c4c5ccccc5n(-c5ncc6cc(-c7ccc8ccccc8c7)ccc6n5)c4c32)cc1]

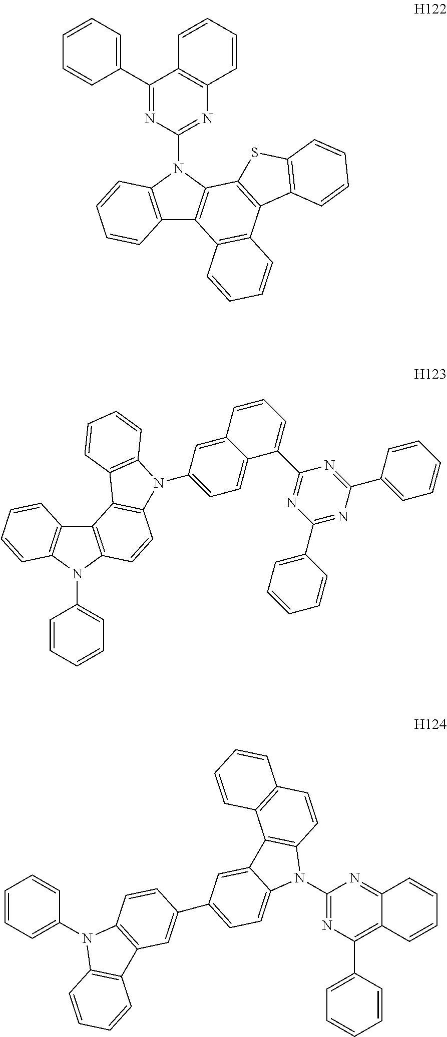 [SMILES: c1ccc(-c2nc(-n3c4ccccc4c4c5ccccc5c5c6ccccc6sc5c43)nc3ccccc23)cc1 ; c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1]

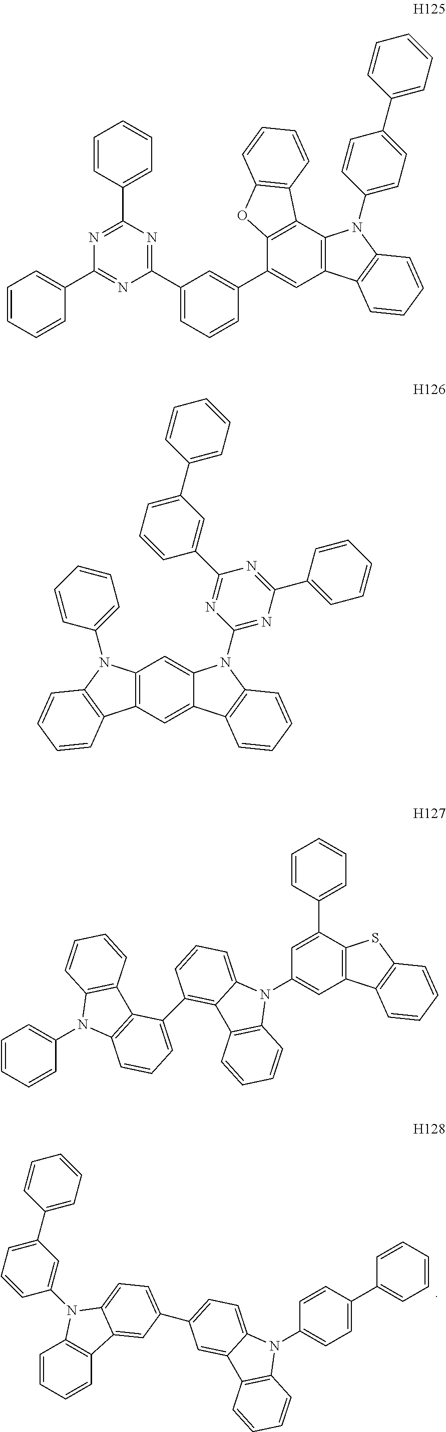 [SMILES: c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-c2cccc(-c3nc(-c4ccccc4)nc(-n4c5ccccc5c5cc6c7ccccc7n(-c7ccccc7)c6cc54)n3)c2)cc1 ; c1ccc(-c2cc(-n3c4ccccc4c4c(-c5cccc6c5c5ccccc5n6-c5ccccc5)cccc43)cc3c2sc2ccccc23)cc1 ; c1ccc(-c2ccc(-n3c4ccccc4c4cc(-c5ccc6c(c5)c5ccccc5n6-c5cccc(-c6ccccc6)c5)ccc43)cc2)cc1]

### Phosphorescent Dopant

The phosphorescent dopant may include at least one transition metal as a central metal.

The phosphorescent dopant may include a monodentate ligand, a bidentate ligand, a tridentate ligand, a tetradentate ligand, a pentadentate ligand, a hexadentate ligand, and/or a (e.g., any suitable) combination thereof.

The phosphorescent dopant may be electrically neutral.

For example, the phosphorescent dopant may include an organometallic compound represented by Formula 401:

M(L₄₀₁)xc1(L₄₀₂)xc2 Formula 401

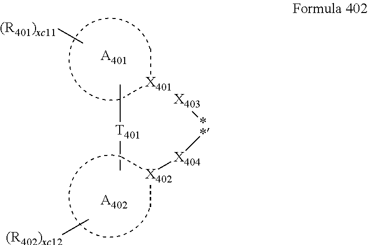

In Formulae 401 and 402, M may be a transition metal (e.g., Ir, Pt, Pd, O₃, Ti, Au, Hf, Eu, Tb, Rh, Re, or Tm); L₄₀₁ may be a ligand represented by Formula 402, and xc1 may be 1, 2, or 3, wherein, if (e.g., when) xc1 is 2 or more, two or more of L₄₀₁ may be substantially identical to or substantially different from each other; L₄₀₂ may be an organic ligand; and xc2 may be 0, 1, 2, 3, or 4, wherein, if (e.g., when) xc2 is 2 or more, two or more of L₄₀₂ may be substantially identical to or substantially different from each other; X₄₀₁ and X₄₀₂ may each independently be nitrogen or carbon; ring A₄₀₁ and ring A₄₀₂ may each independently be a C₃-C₆₀ carbocyclic group or a C₁-C₆₀ heterocyclic group; T₄₀₁ may be a single bond, *—O—*′, *—S—*′, *—C(═O)—*′, *—N(Q₄₁₁)—*′, *—C(Q₄₁₁)(Q₄₁₂)—*′, *—C(Q₄₁₁)═C(Q₄₁₂)—*′, *—C(Q₄₁₁)═*′, or *═C═*′; X₄₀₃ and X₄₀₄ may each independently be a chemical bond (e.g., a covalent bond or a coordination bond), O, S, N(Q₄₁₃), B(Q₄₁₃), P(Q₄₁₃), C(Q₄₁₃)(Q₄₁₄), or Si(Q₄₁₃)(Q₄₁₄); Q₄₁₁ to Q₄₁₄ are each the same as described in connection with Q₁; R₄₀₁ and R₄₀₂ may each independently be hydrogen, deuterium, —F, —Cl, —Br, —I, a hydroxyl group, a cyano group, a nitro group, a C₁-C₂₀ alkyl group unsubstituted or substituted with at least one R₁₀ₐ, a C₁-C₂₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₄₀₁)(Q₄₀₂)(Q₄₀₃), —N(Q₄₀₁)(Q₄₀₂), —B(Q₄₀₁)(Q₄₀₂), —C(═O)(Q₄₀₁), —S(═O)₂(Q₄₀₁), or —P(═O)(Q₄₀₁)(Q₄₀₂), Q₄₀₁ to Q₄₀₃ are each the same as described in connection with Q₁; xc11 and xc12 may each independently be an integer from 0 to 10; and * and *′ in Formula 402 each indicate a binding site to M in Formula 401.

For example, in Formula 402, i) X₄₀₁ may be nitrogen and X₄₀₂ may be carbon, or ii) each of X₄₀₁ and X₄₀₂ may be nitrogen.

In one or more embodiments, if (e.g., when) xc1 in Formula 401 is 2 or more, two ring A₄₀₁(s) among two or more L₄₀₁(s) may optionally be linked to each other via T₄₀₂, which is a linking group, and two ring A₄₀₂(s) among two or more L₄₀₁(s) may optionally be linked to each other via T₄₀₃, which is a linking group (see Compounds PD1 to PD4 and PD7). T₄₀₂ and T₄₀₃ are each the same as described in connection with T₄₀₁.

In Formula 401, L₄₀₂ may be an organic ligand. For example, L₄₀₂ may include a halogen group, a diketone group (e.g., an acetylacetonate group), a carboxylic acid group (e.g., a picolinate group), —C(═O), an isonitrile group, a —CN group, a phosphorus group (e.g., a phosphine group, a phosphite group, and/or the like), and/or a (e.g., any suitable) combination thereof.

The phosphorescent dopant may include, for example, at least one of Compounds PD1 to PD39, and/or a (e.g., any suitable) combination thereof:

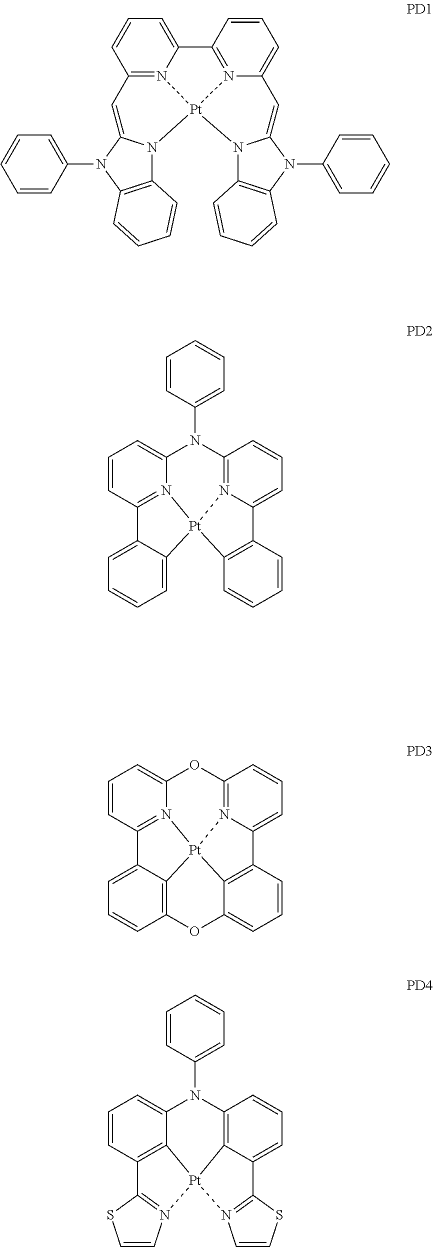

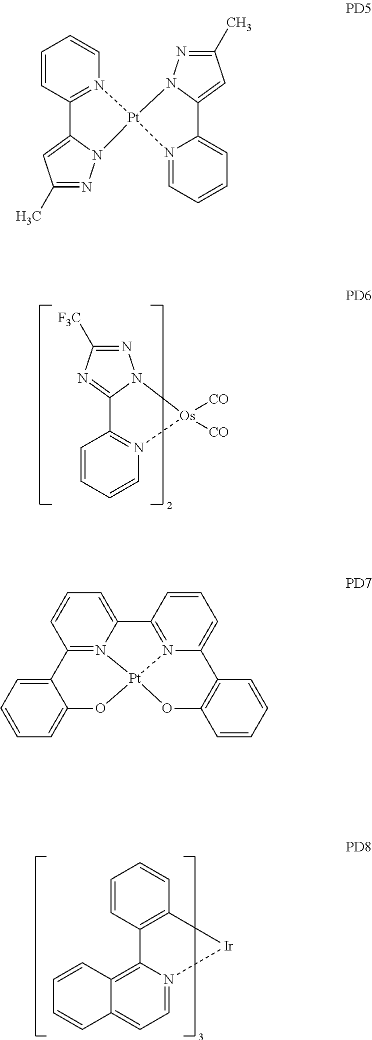

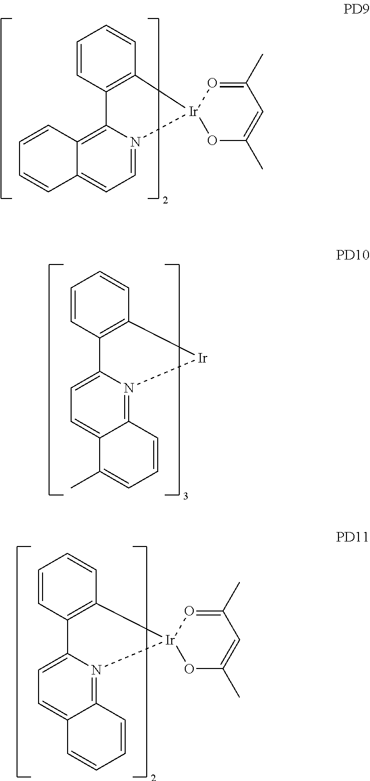

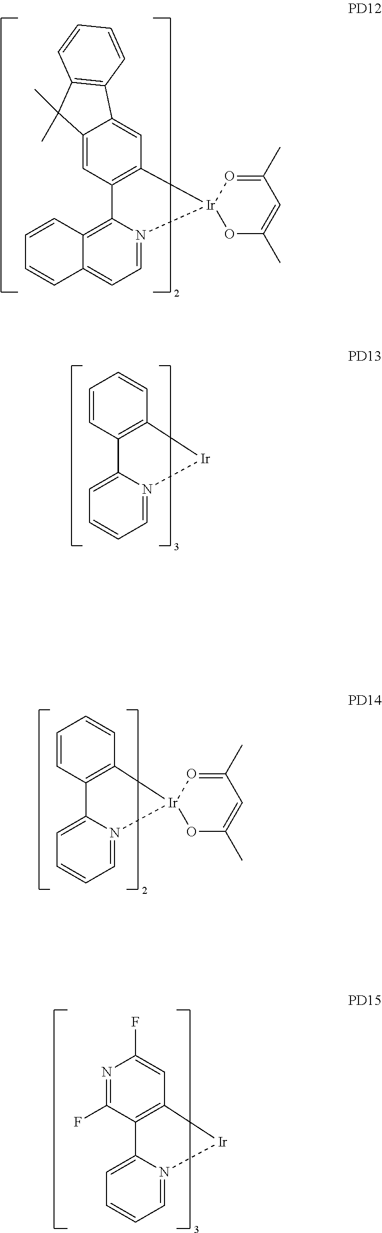

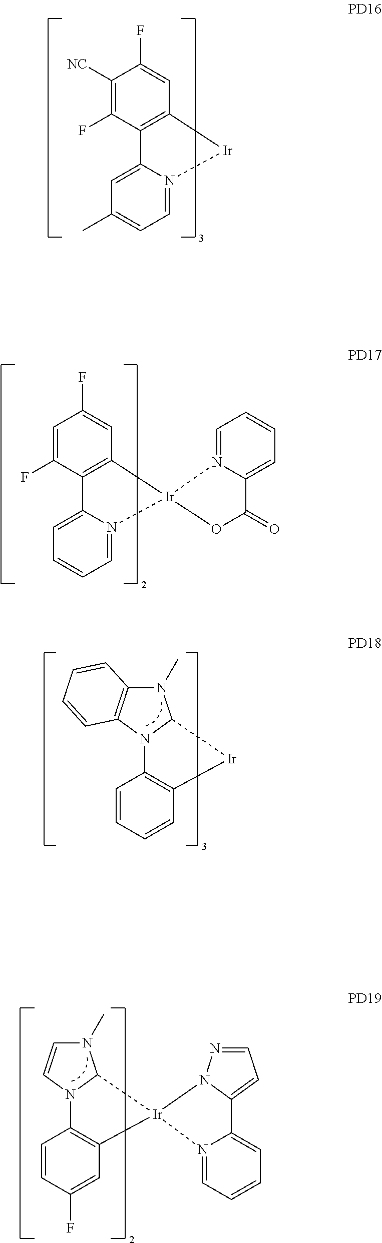

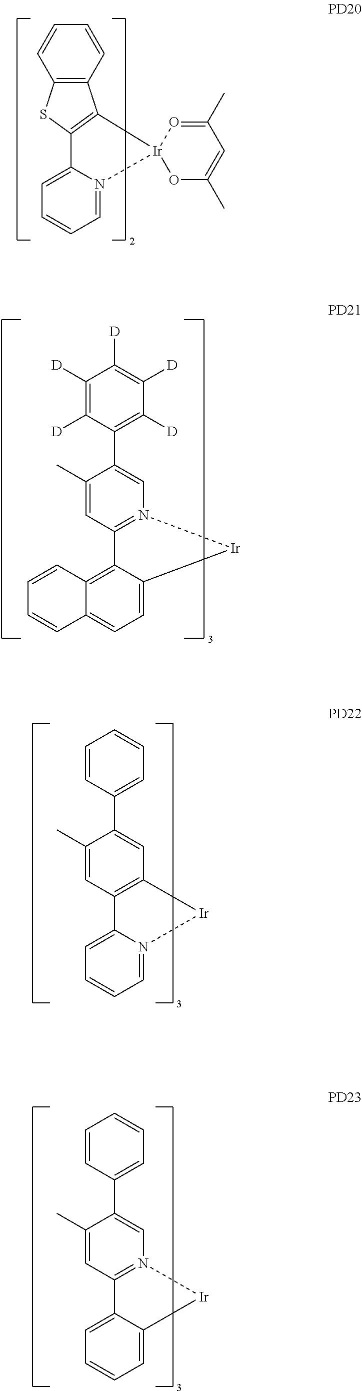

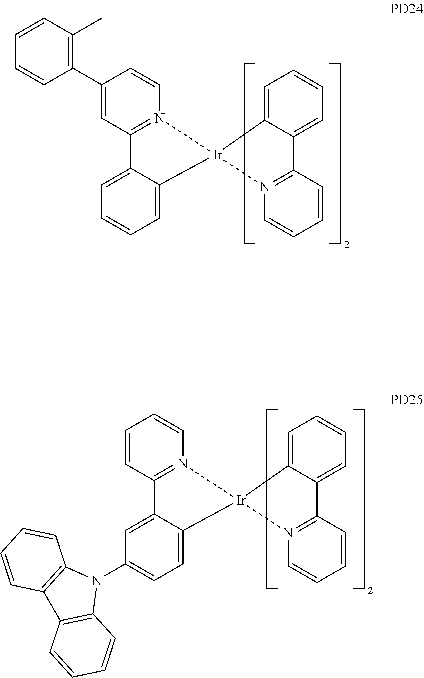

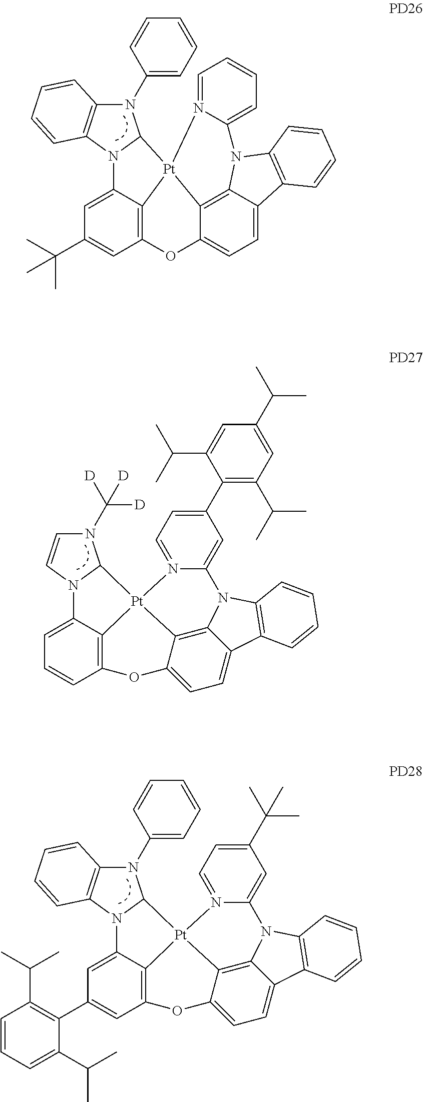

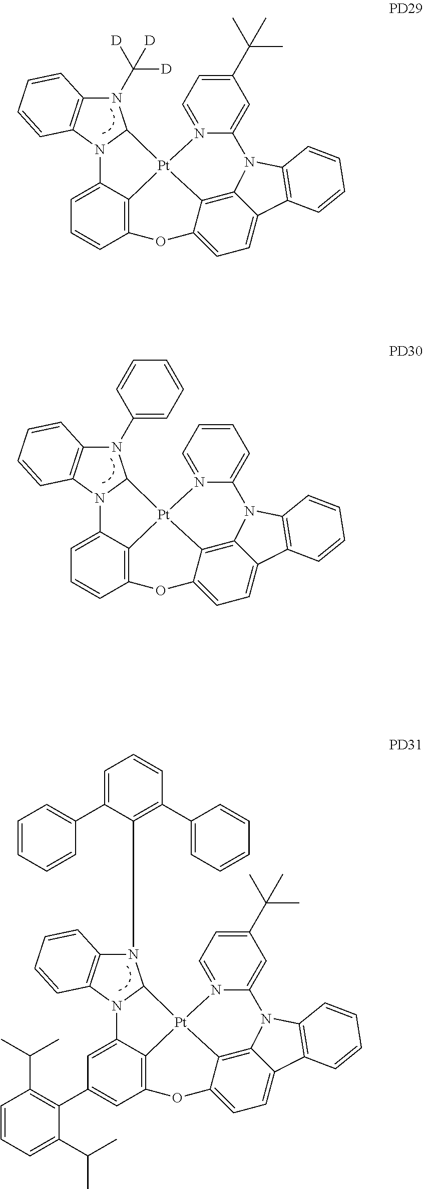

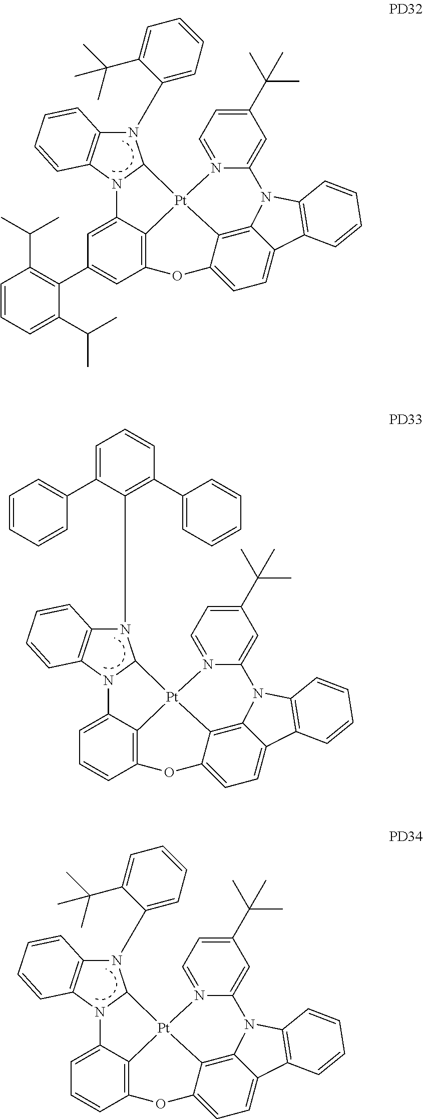

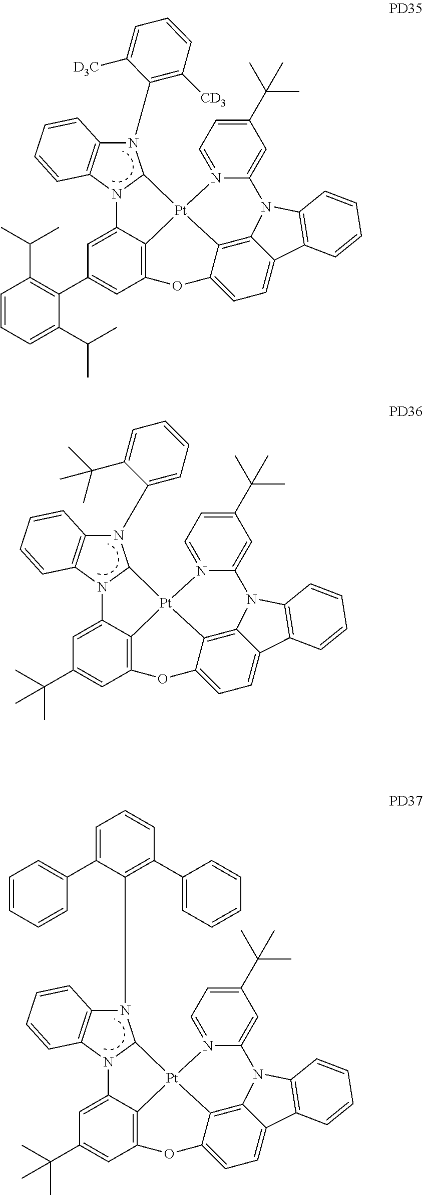

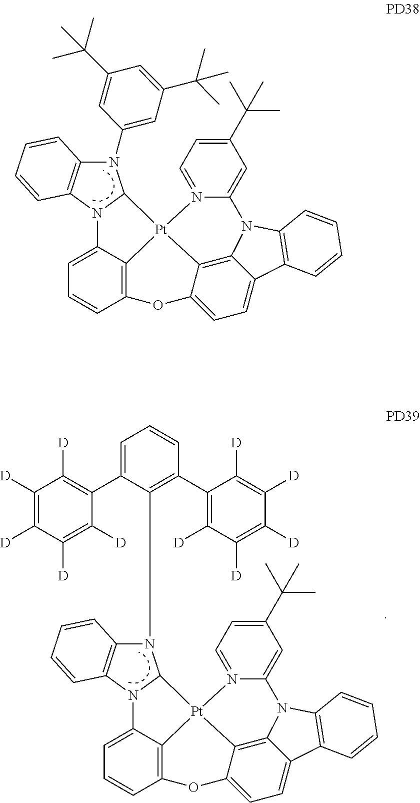

### Fluorescent Dopant

The fluorescent dopant may include an amine group-containing compound, a styryl group-containing compound, and/or a (e.g., any suitable) combination thereof.

For example, the fluorescent dopant may include a compound represented by Formula 501:

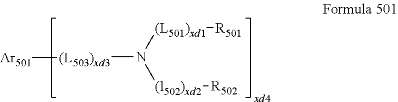

In Formula 501, Ar₅₀₁, L₅₀₁ to L₅₀₃, R₅₀₁, and R₅₀₂ may each independently include a C₃-C₆₀ carbocyclic group unsubstituted or substituted with at least one R₁₀ₐ or a C₁-C₆₀ heterocyclic group unsubstituted or substituted with at least one R₁₀ₐ, xd1 to xd3 may each independently be 0, 1, 2, or 3, and xd4 may be 1, 2, 3, 4, 5, or 6.

For example, Ar₅₀₁ in Formula 501 may be a condensed cyclic group (e.g., an anthracene group, a chrysene group, a pyrene group, and/or the like) in which three or more monocyclic groups are condensed together.

For example, xd4 in Formula 501 may be 2.

For example, the fluorescent dopant and the auxiliary dopant may each include at least one of (e.g., be any one selected from among) Compounds FD1 to FD37, DPVBi, DPAVBi, and/or a (e.g., any suitable) combination thereof:

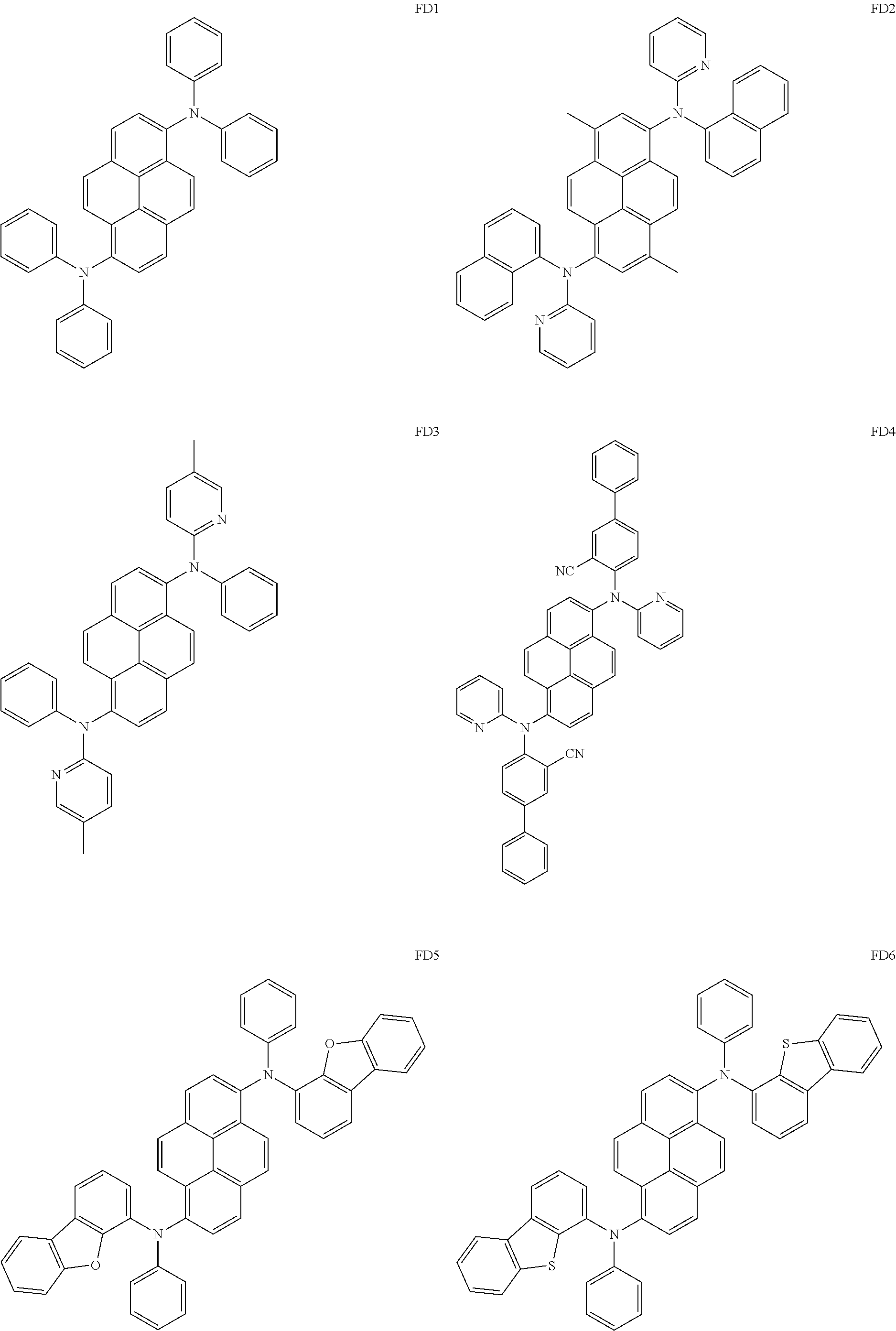

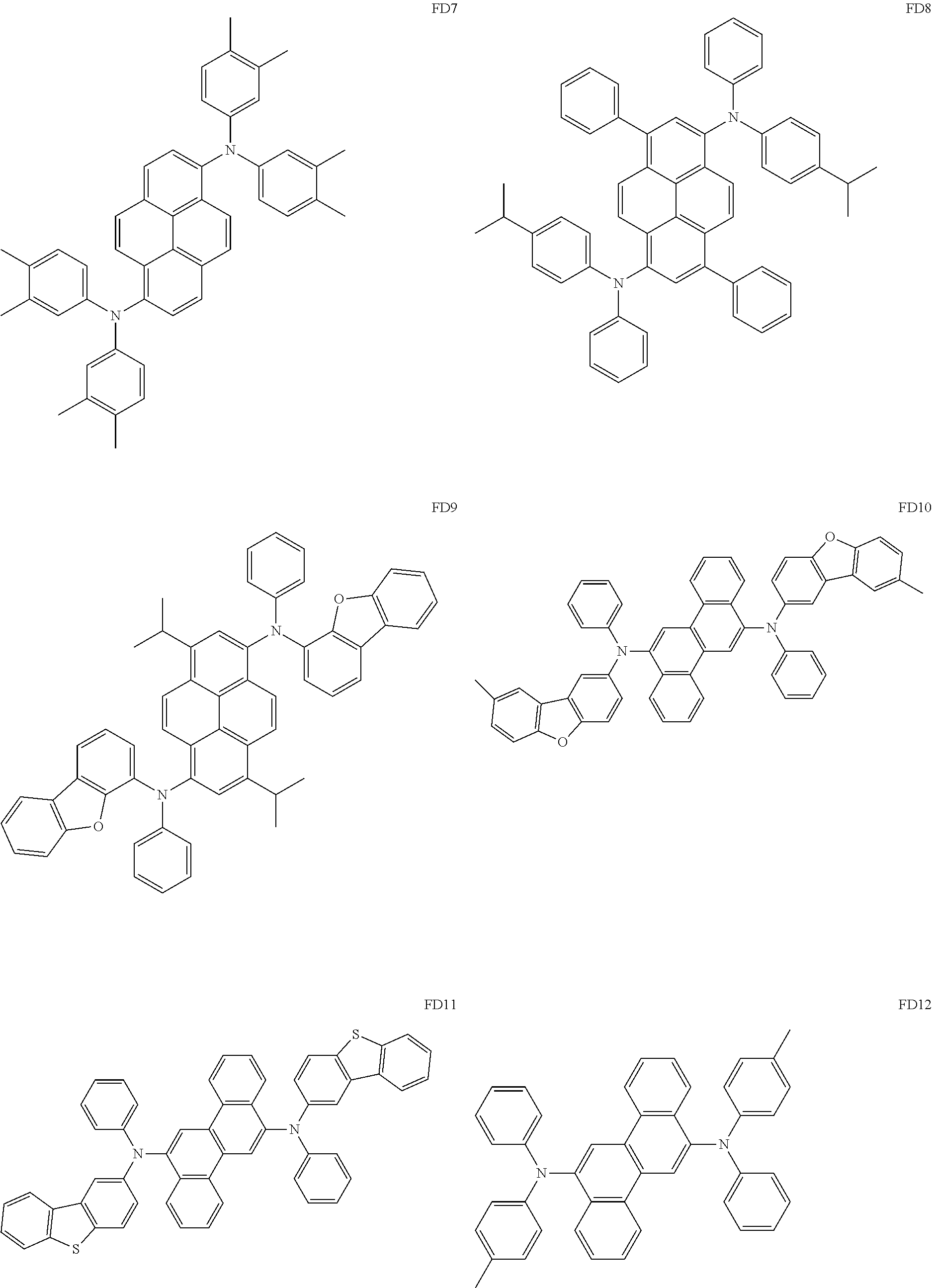

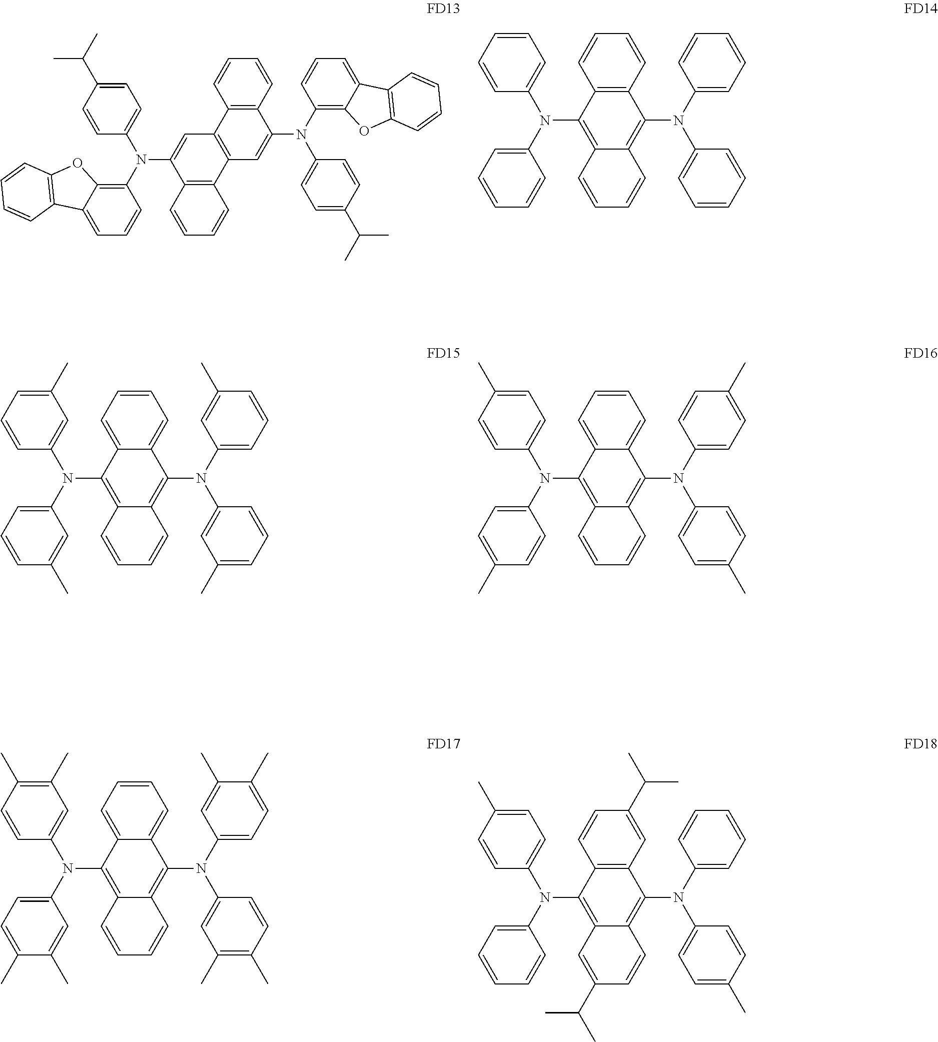

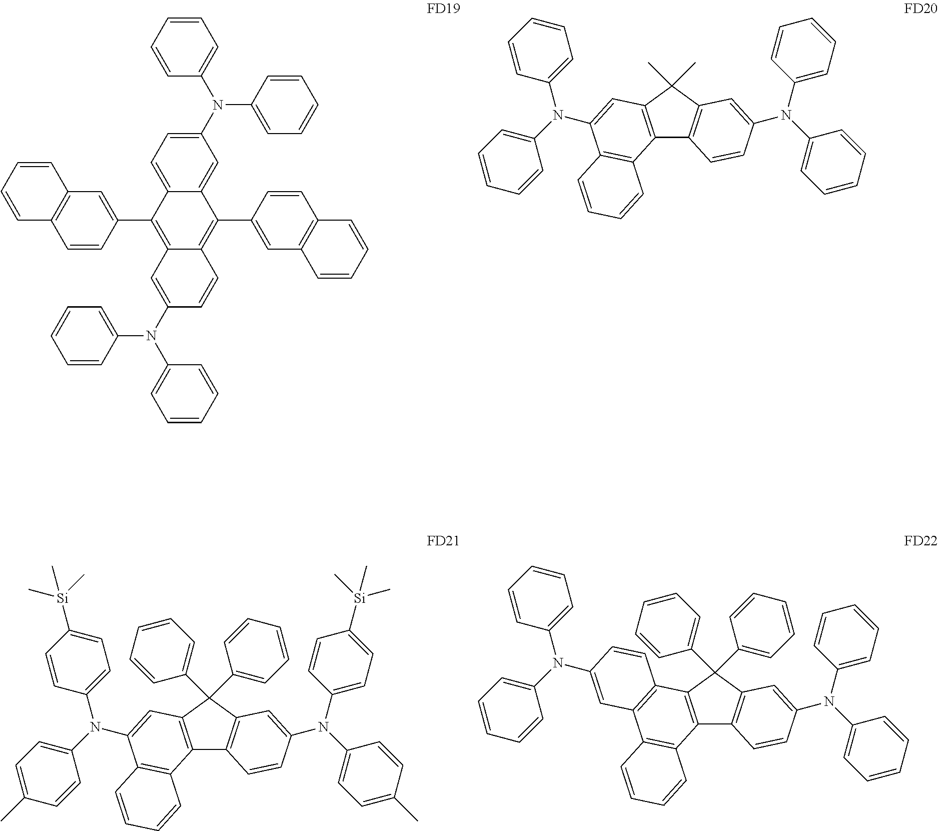

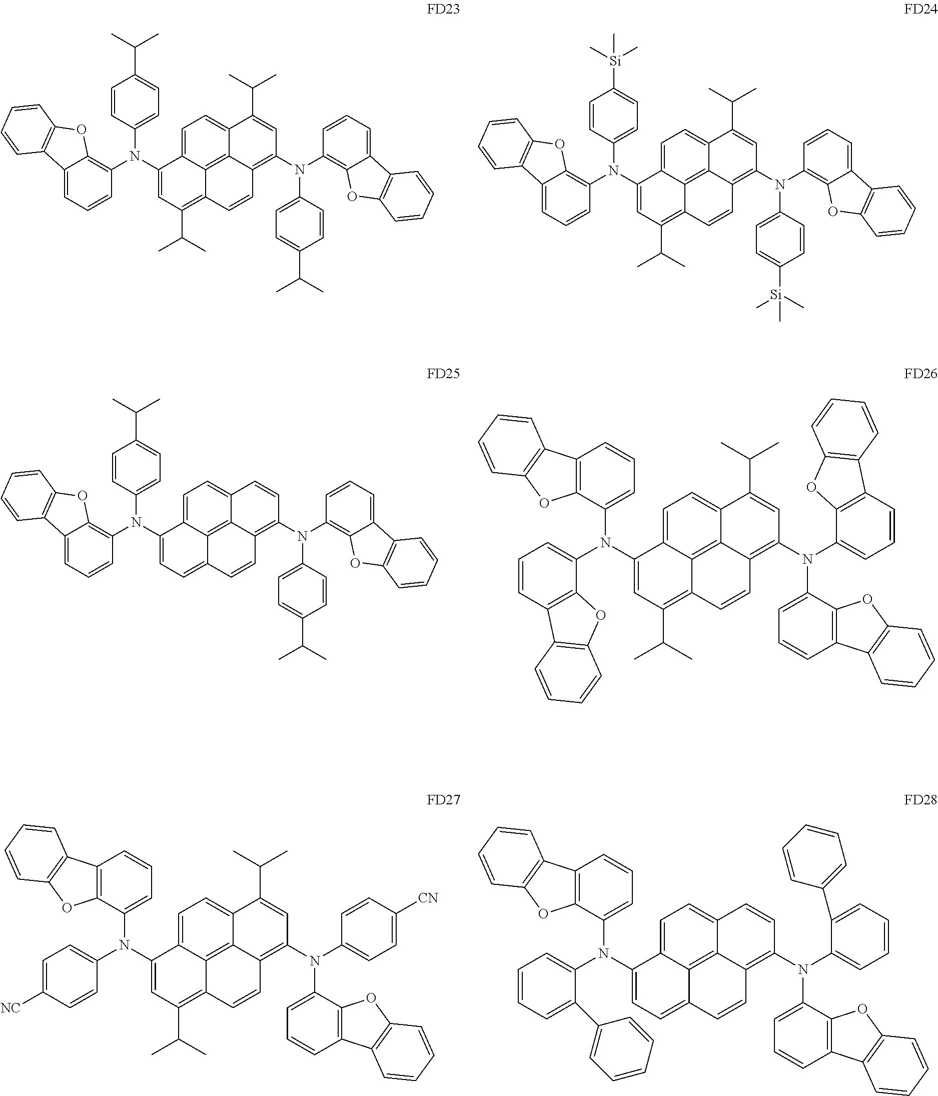

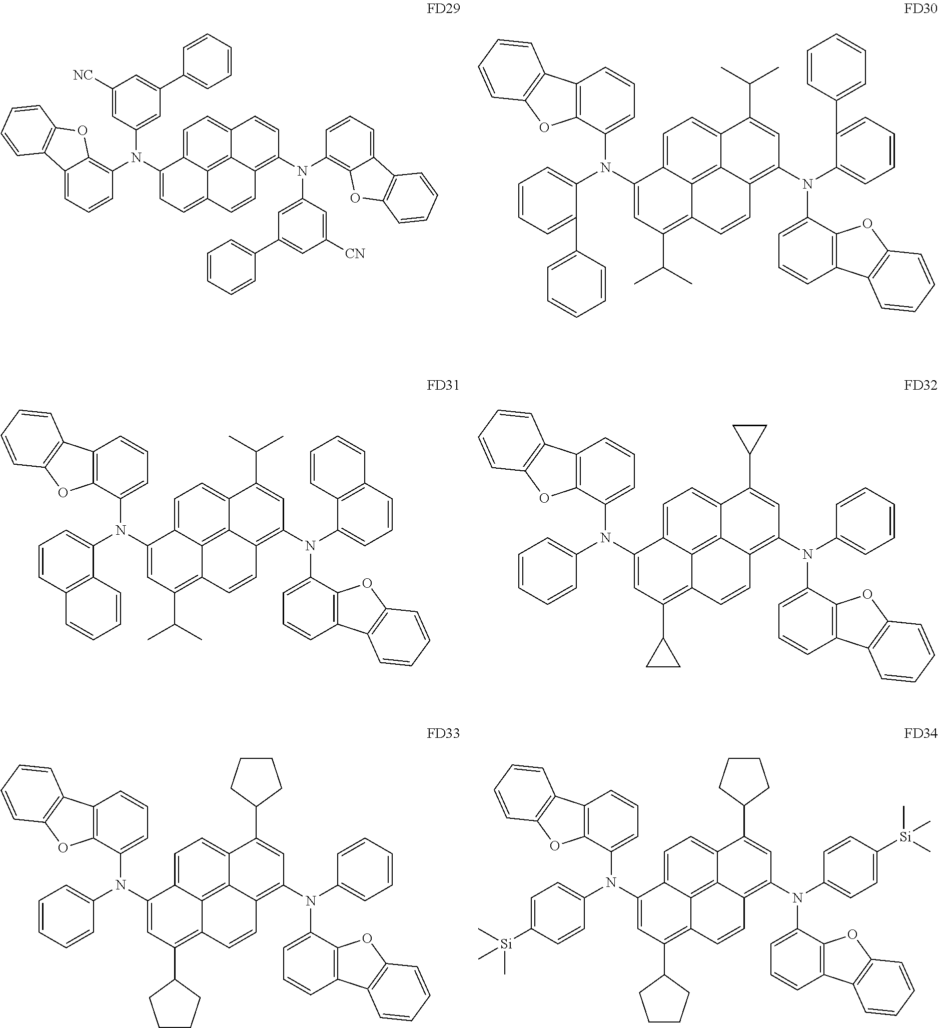

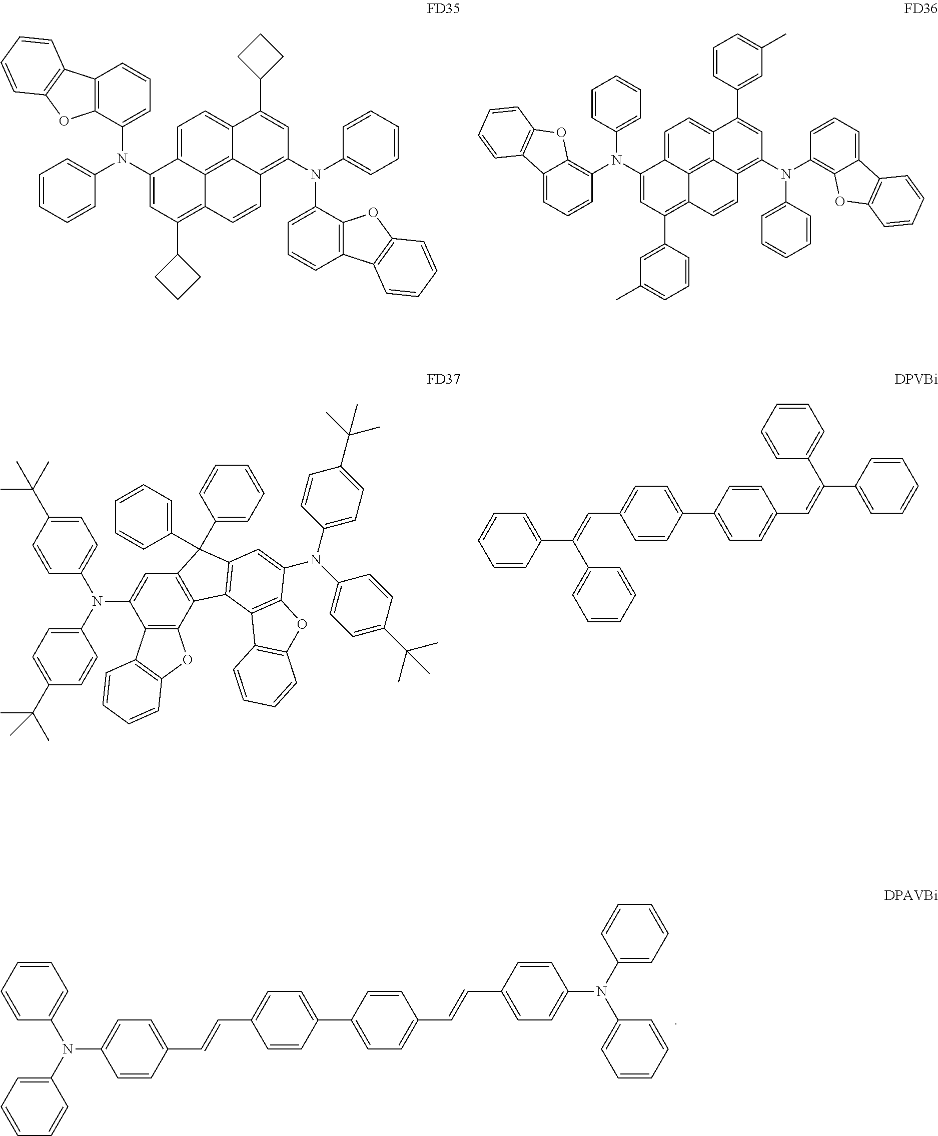

### Delayed Fluorescence Material

The emission layer may include a delayed fluorescence material.

In the present disclosure, the delayed fluorescence material may be selected from among compounds capable of emitting delayed fluorescence based on a delayed fluorescence emission mechanism.

The delayed fluorescence material included in the emission layer may act as a host or a dopant depending on the type or kind of other materials included in the emission layer.

In one or more embodiments, a difference between a triplet energy level (eV) of the delayed fluorescence material and the singlet energy level (eV) of the delayed fluorescence material may be in a range of about 0 eV to about 0.5 eV. When the difference between the triplet energy level (eV) of the delayed fluorescence material and the singlet energy level (eV) of the delayed fluorescence material is within the range above, up-conversion from the triplet state to the singlet state of the delayed fluorescence materials may effectively occur, and thus, the light-emitting device 1A may have improved luminescence efficiency.

For example, the delayed fluorescence material may include i) a material including at least one electron donor (e.g., a π electron-rich C₃-C₆₀ cyclic group, such as a carbazole group, and/or the like) and at least one electron acceptor (e.g., a sulfoxide group, a cyano group, a π electron-deficient nitrogen-containing C₁-C₆₀ cyclic group, and/or the like), and ii) a material including a C₈-C₆₀ polycyclic group in which two or more cyclic groups are condensed while sharing boron (B).

Examples of the delayed fluorescence material may include at least one of Compounds DF1 t DF14:

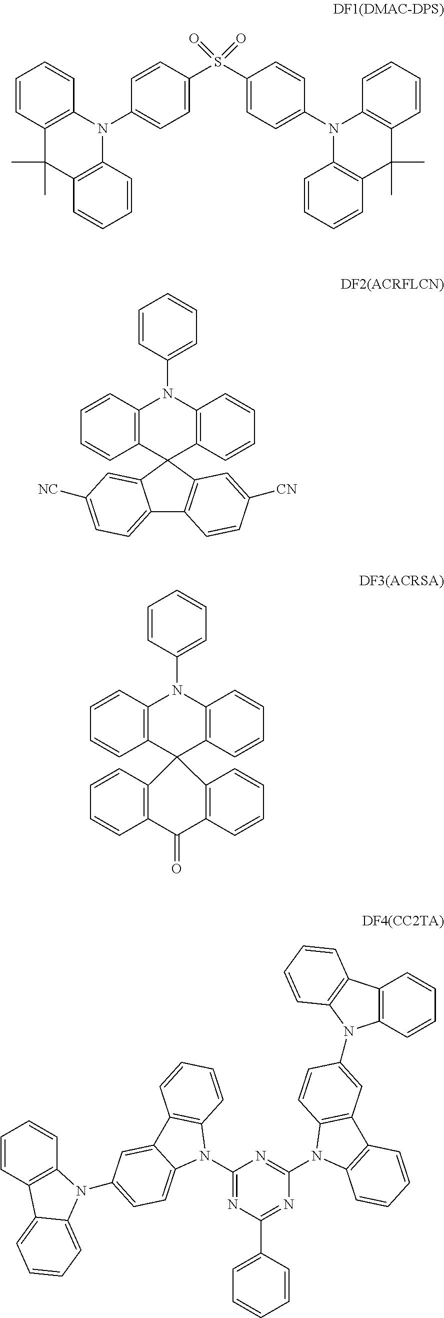

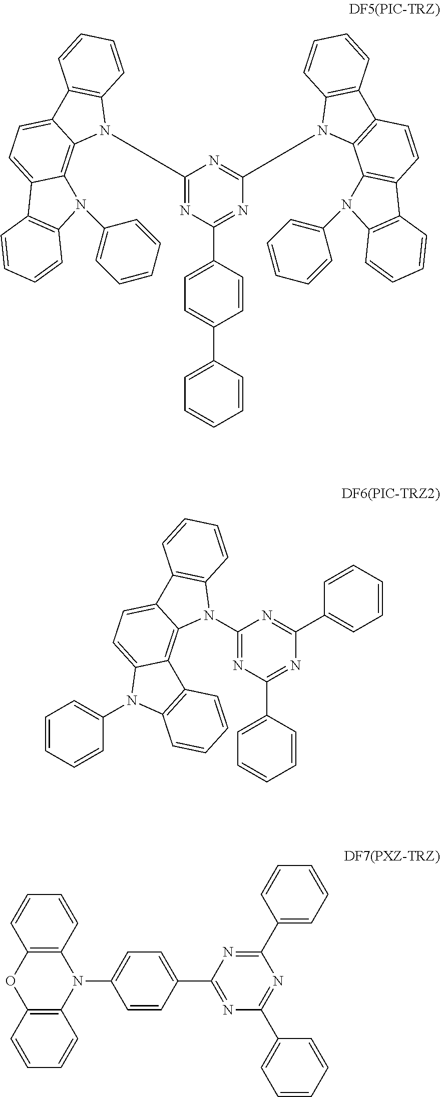 [SMILES: c1ccc(-c2ccc(-c3nc(-n4c5ccccc5c5ccc6c7ccccc7n(-c7ccccc7)c6c54)nc(-n4c5ccccc5c5ccc6c7ccccc7n(-c7ccccc7)c6c54)n3)cc2)cc1 ; c1ccc(-c2nc(-c3ccccc3)nc(-n3c4ccccc4c4ccc5c(c6ccccc6n5-c5ccccc5)c43)n2)cc1 ; c1ccc(-c2nc(-c3ccccc3)nc(-c3ccc(N4c5ccccc5Oc5ccccc54)cc3)n2)cc1]

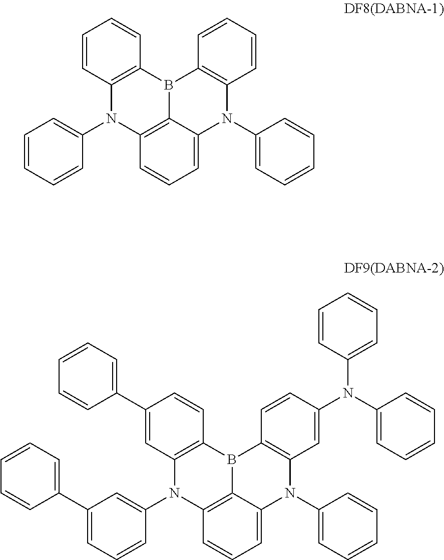 [SMILES: c1ccc(N2c3ccccc3B3c4ccccc4N(c4ccccc4)c4cccc2c43)cc1 ; c1ccc(-c2cccc(N3c4cc(-c5ccccc5)ccc4B4c5ccc(N(c6ccccc6)c6ccccc6)cc5N(c5ccccc5)c5cccc3c54)c2)cc1]

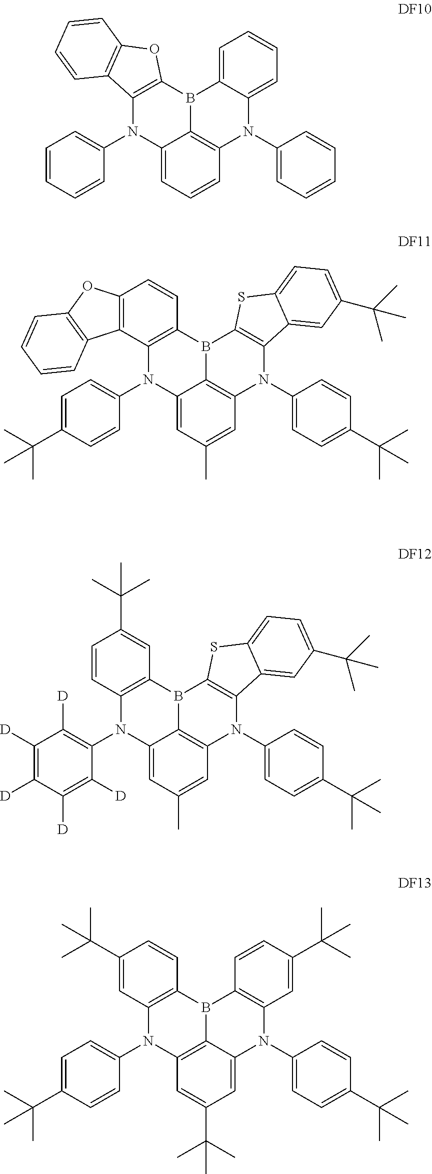

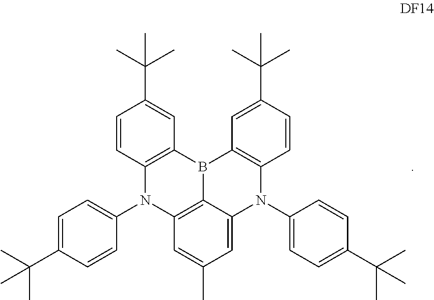 [SMILES: Cc1cc2c3c(c1)N(c1ccc(C(C)(C)C)cc1)c1ccc(C(C)(C)C)cc1B3c1cc(C(C)(C)C)ccc1N2c1ccc(C(C)(C)C)cc1]

### Electron Transport Region in Interlayer 130

The electron transport region may have: i) a single-layer structure including (e.g., consisting of) a single layer including (e.g., consisting of) a single material, ii) a single-layer structure including (e.g., consisting of) a single layer including (e.g., consisting of) multiple materials that are different from each other, or iii) a multi-layer structure including multiple layers including multiple materials that are different from each other.

The electron transport region may include a buffer layer, a hole blocking layer, an electron control layer, an electron transport layer, an electron injection layer, and/or a (e.g., any suitable) combination thereof.

For example, the electron transport region may have an electron transport layer/electron injection layer structure, a hole blocking layer/electron transport layer/electron injection layer structure, an electron control layer/electron transport layer/electron injection layer structure, or a buffer layer/electron transport layer/electron injection layer structure, wherein layers in each structure are sequentially stacked from the emission layer.

In one or more embodiments, the electron transport region (e.g., the buffer layer, the hole blocking layer, the electron control layer, or the electron transport layer in the electron transport region) may include a metal-free compound including at least one π electron-deficient nitrogen-containing C₁-C₆₀ cyclic group.

For example, the electron transport region may include a compound represented by Formula 601:

[Ar₆₀₁]xe11-[(L₆₀₁)xe1-R₆₀₁]xe21. Formula 601

In Formula 601, Ar₆₀₁ and L₆₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ; xe11 may be 1, 2, or 3; xe1 may be 0, 1, 2, ₃, 4, or 5; R₆₀₁ may be a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₆₀₁)(Q₆₀₂)(Q₆₀₃), —C(═O)(Q₆₀₁), —S(═O)₂(Q₆₀₁), or —P(═O)(Q₆₀₁)(Q₆₀₂); Q₆₀₁ to Q₆₀₃ are each the same as described in connection with Q₁; xe21 may be 1, 2, 3, 4, or 5; and at least one of A₆₀₁, L₆₀₁, and R₆₀₁ may each independently be a π electron-deficient nitrogen-containing C₁-C₆₀ cyclic group unsubstituted or substituted with at least one R₁₀ₐ.

For example, if (e.g., when) xe11 in Formula 601 is 2 or more, two or more of Ar₃₀₁ may be linked to each other via a single bond.

In one or more embodiments, A₆₀₁ in Formula 601 may be an anthracene group unsubstituted or substituted with at least one R₁₀ₐ.

In one or more embodiments, the electron transport region may include a compound represented by Formula 601-1:

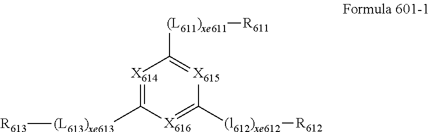

In Formula 601-1, X₆₁₄ may be N or C(R₆₁₄), X₆₁₅ may be N or C(R₆₁₅), and X₆₁₆ may be N or C(R₆₁₆), wherein at least one of X₆₁₄ to X₆₁₆ may be N; L₆₁₁ to L₆₁₃ are each the same as described in connection with L₆₀₁; xe611 to xe613 are each the same as described in connection with xe1; R₆₁₁ to R₆₁₃ are each the same as described in connection with R₆₀₁; and R₆₁₄ to R₆₁₆ may each independently be hydrogen, deuterium, —F, —Cl, —Br, —I, a hydroxyl group, a cyano group, a nitro group, a C₁-C₂₀ alkyl group, a C₁-C₂₀ alkoxy group, a C₃-C₆₀ carbocyclic group unsubstituted or substituted with at least one R₁₀ₐ, or a C₁-C₆₀ heterocyclic group unsubstituted or substituted with at least one R₁₀ₐ.

For example, xe1 and xe611 to xe613 in Formulae 601 and 601-1 may each independently be 0, 1, or 2.

In one or more embodiments, the electron transport region may include: at least one of Compounds ET1 to ET45; 2,9-dimethyl-4,7-diphenyl-1,10-phenanthroline (BCP); 4,7-diphenyl-1,10-phenanthroline (Bphen); Alq₃; BAlq; TAZ; NTAZ; ZnMgO; and/or a (e.g., any suitable) combination thereof:

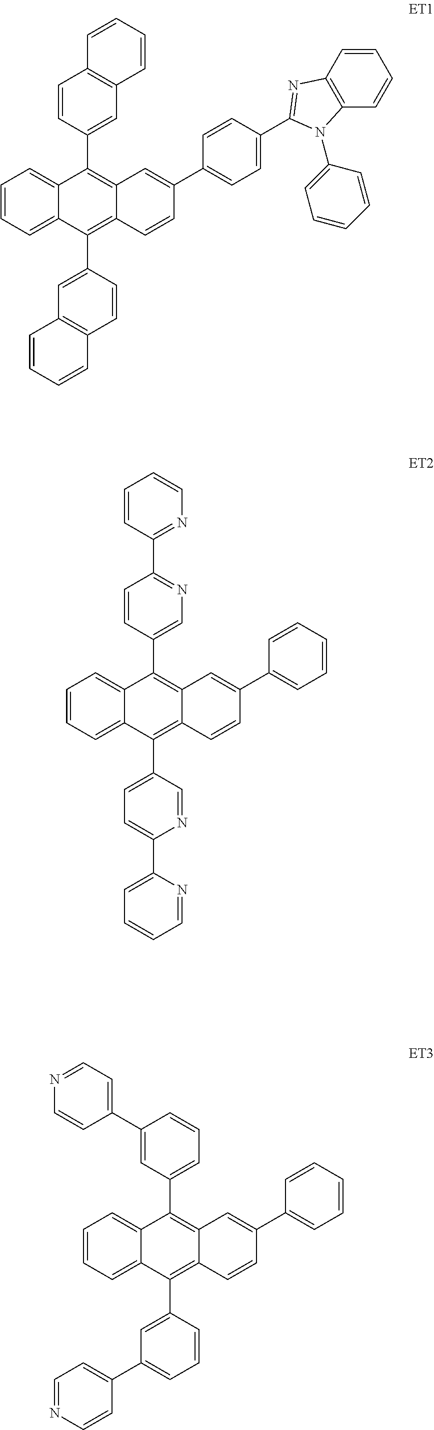 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

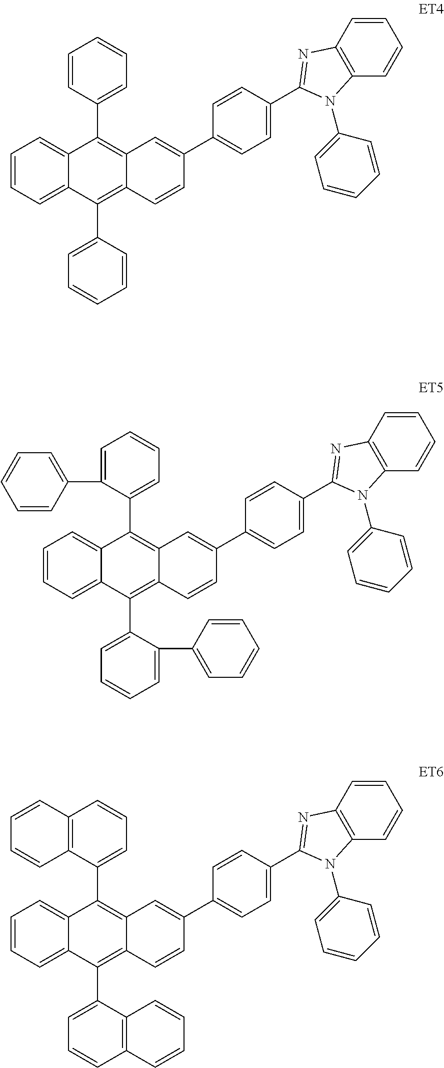 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1]

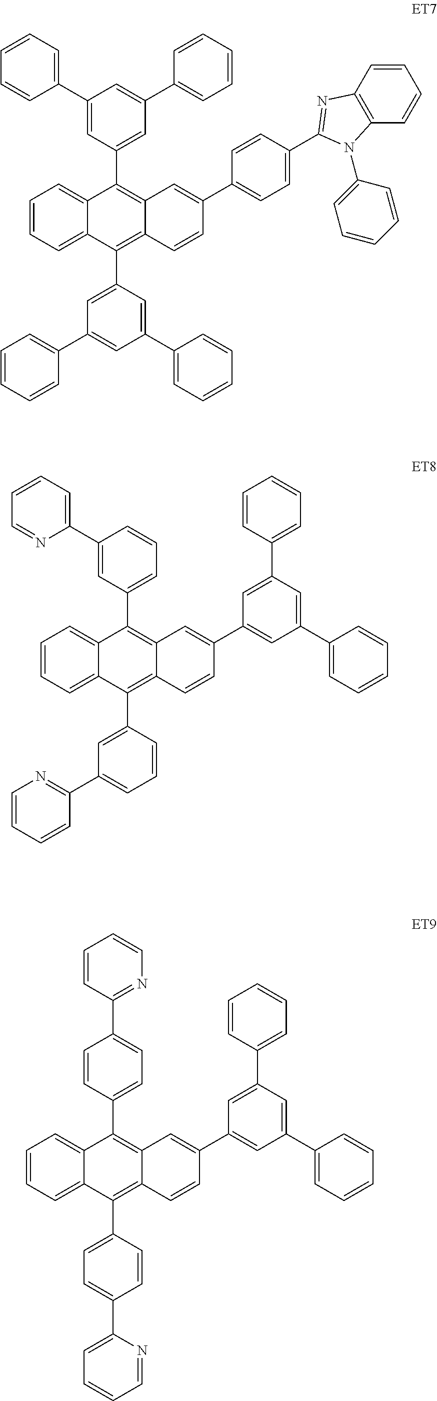 [SMILES: c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

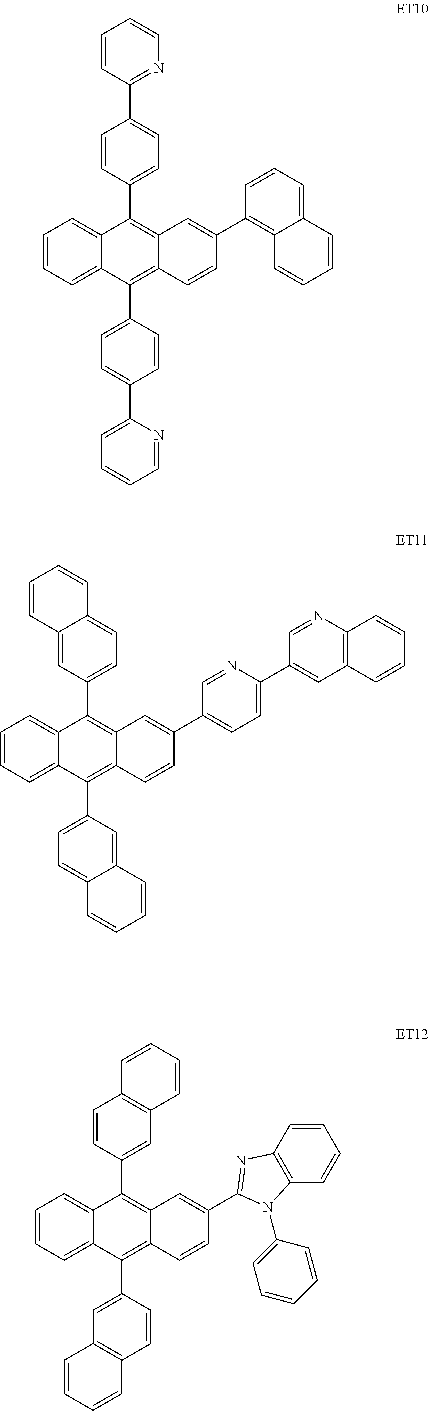 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1]

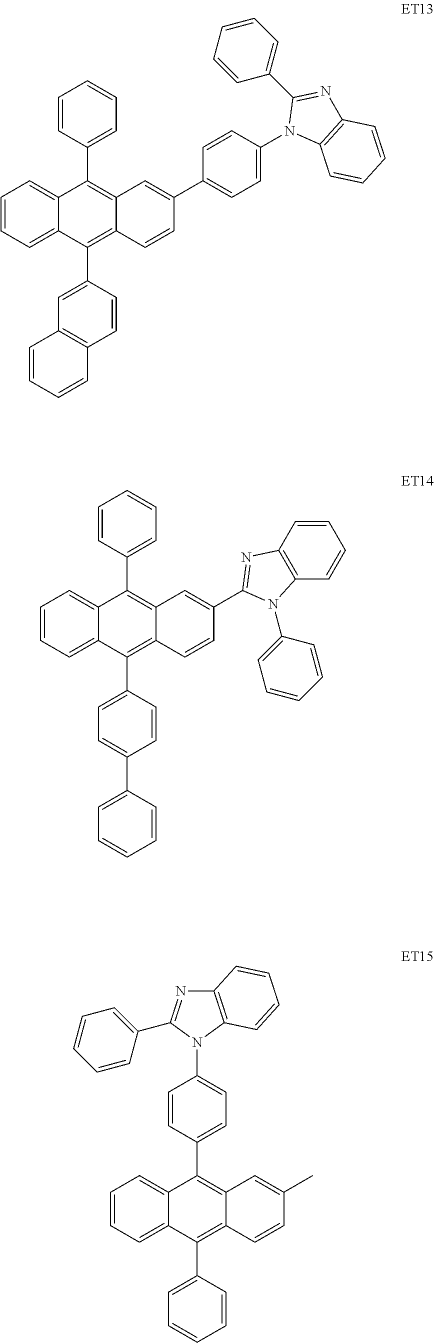 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1]

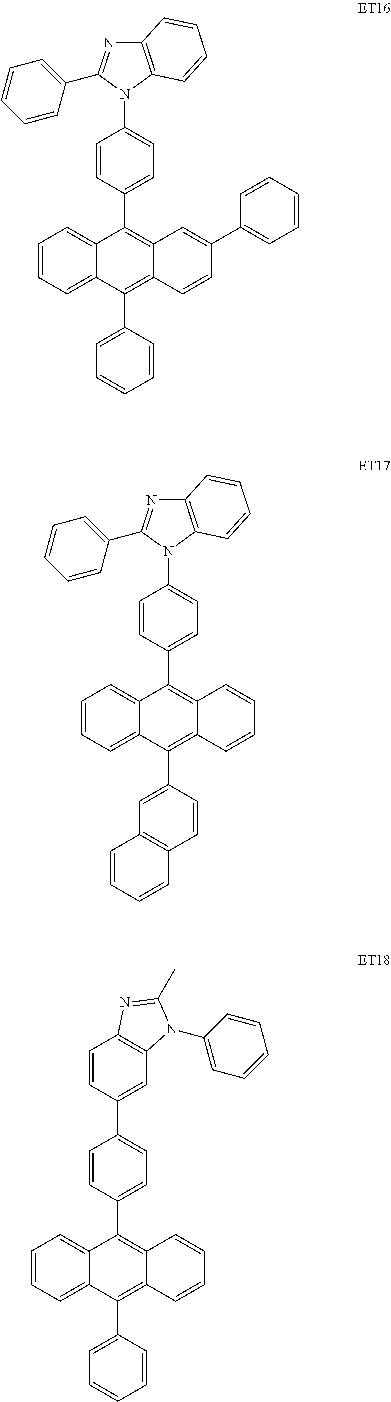 [SMILES: c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

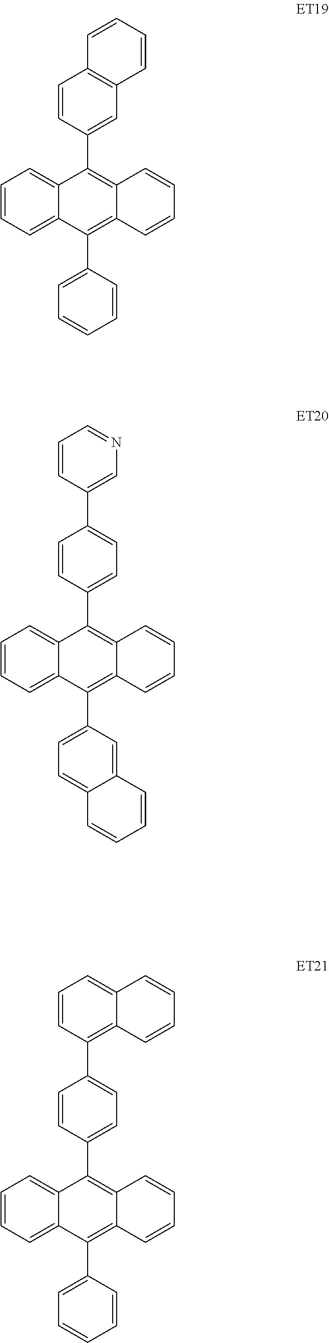

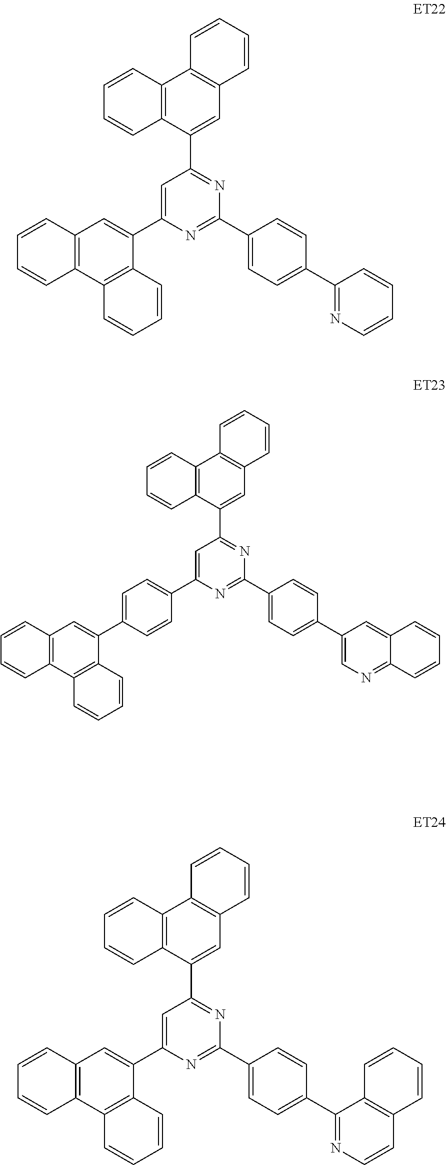 [SMILES: c1ccc(-c2ccc(-c3nc(-c4cc5ccccc5c5ccccc45)cc(-c4cc5ccccc5c5ccccc45)n3)cc2)nc1 ; c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1]

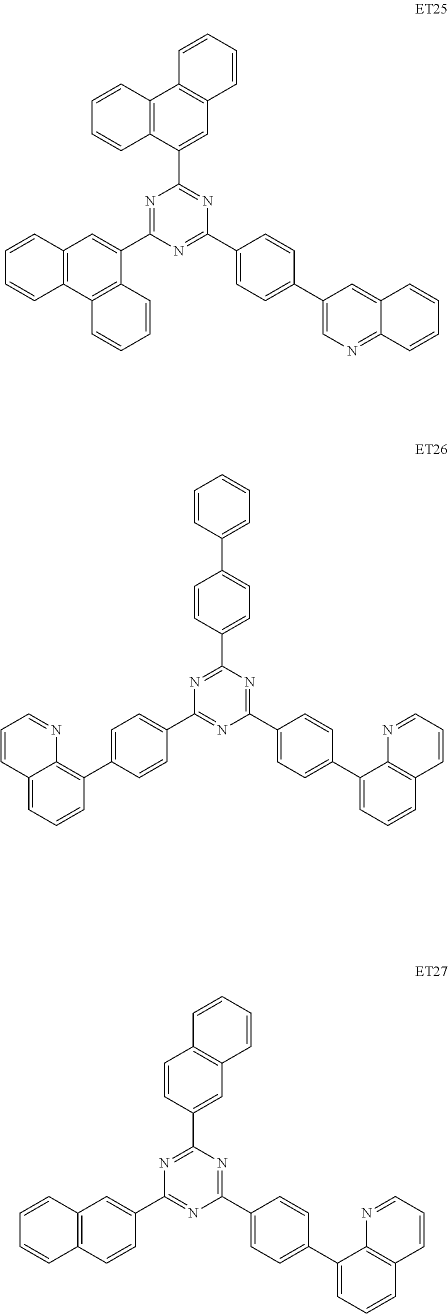 [SMILES: c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1]

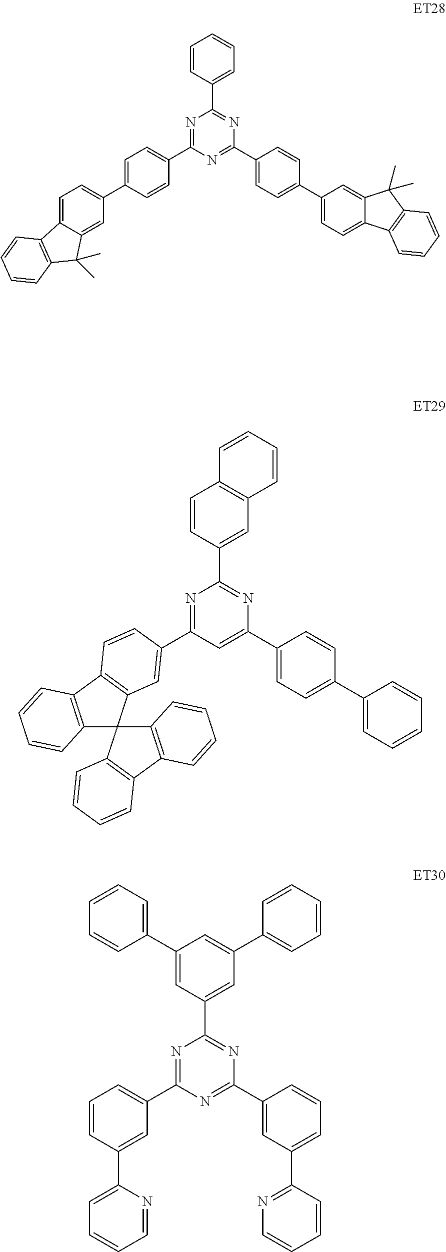 [SMILES: CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

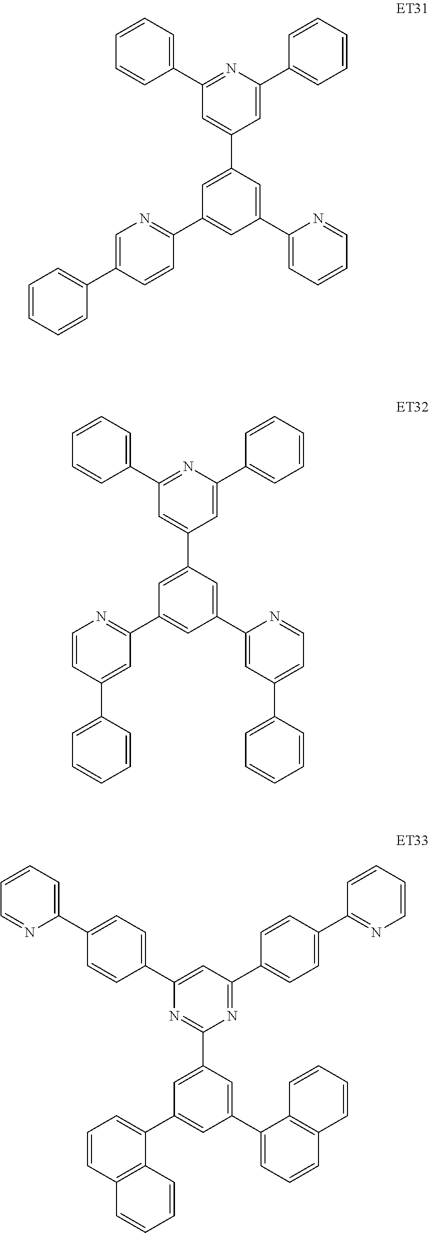 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

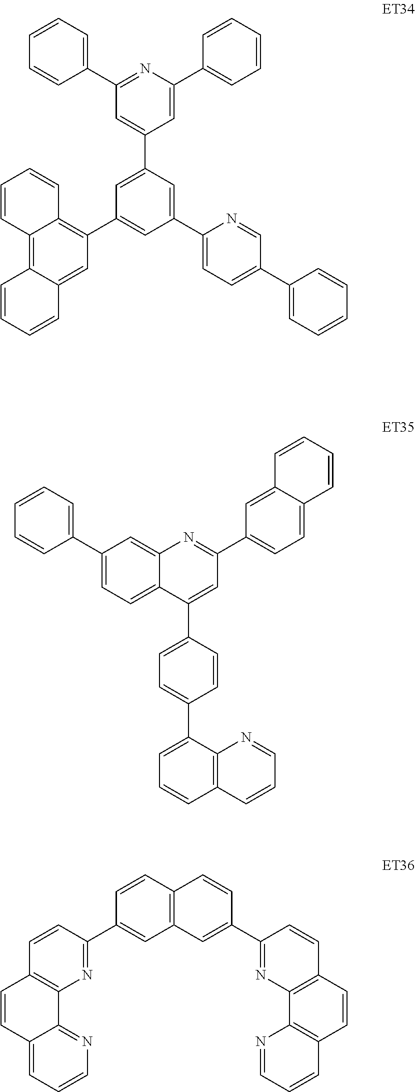 [SMILES: c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

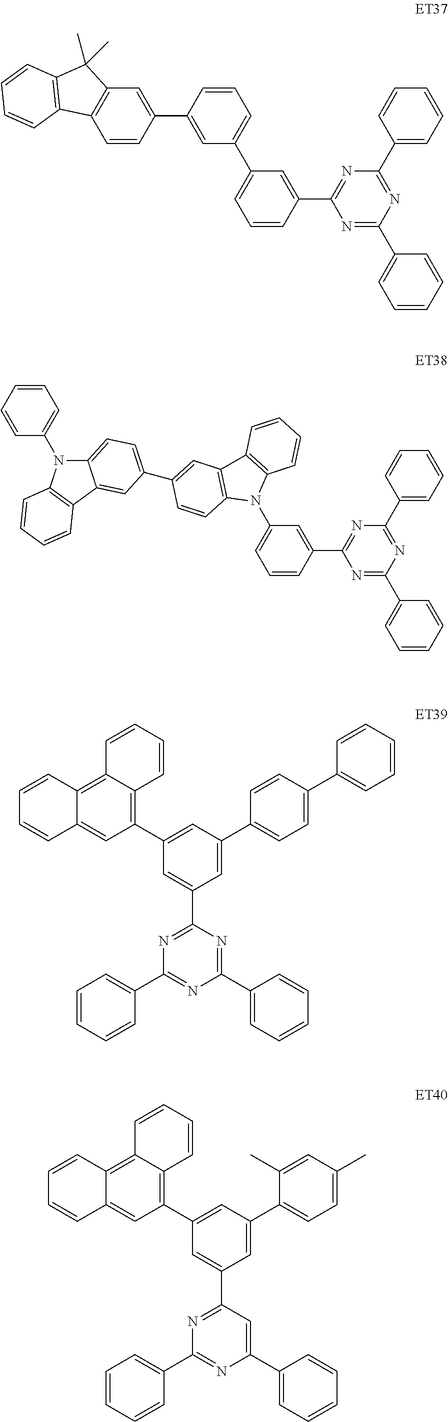 [SMILES: CC1(C)c2ccccc2-c2ccc(-c3cccc(-c4cccc(-c5nc(-c6ccccc6)nc(-c6ccccc6)n5)c4)c3)cc21 ; c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1 ; c1ccc(-c2ccc(-c3cc(-c4nc(-c5ccccc5)nc(-c5ccccc5)n4)cc(-c4cc5ccccc5c5ccccc45)c3)cc2)cc1 ; Cc1ccc(-c2cc(-c3cc(-c4ccccc4)nc(-c4ccccc4)n3)cc(-c3cc4ccccc4c4ccccc34)c2)c(C)c1]

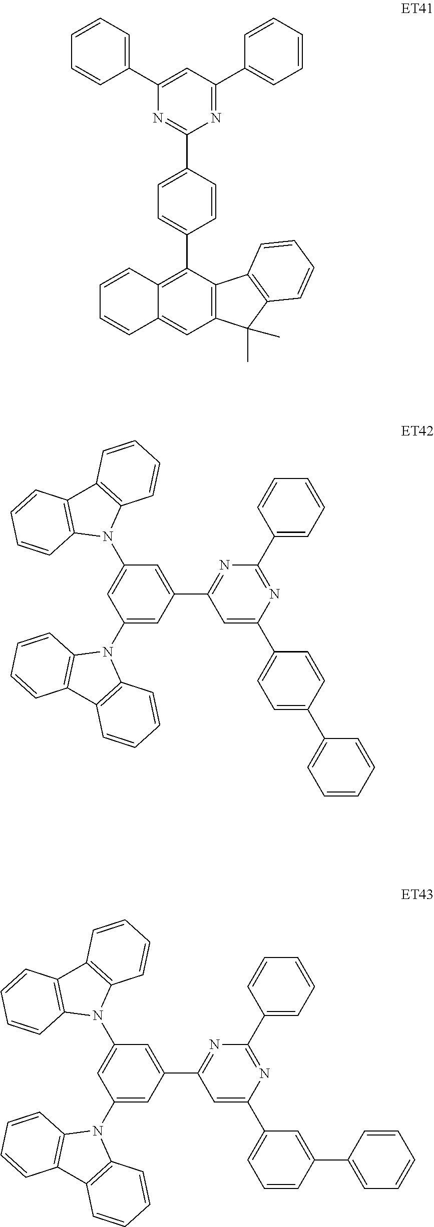 [SMILES: CC1(C)c2ccccc2-c2c1cc1ccccc1c2-c1ccc(-c2nc(-c3ccccc3)cc(-c3ccccc3)n2)cc1 ; c1ccc(-c2ccc(-c3cc(-c4cc(-n5c6ccccc6c6ccccc65)cc(-n5c6ccccc6c6ccccc65)c4)nc(-c4ccccc4)n3)cc2)cc1 ; c1ccc(-c2cccc(-c3cc(-c4cc(-n5c6ccccc6c6ccccc65)cc(-n5c6ccccc6c6ccccc65)c4)nc(-c4ccccc4)n3)c2)cc1]

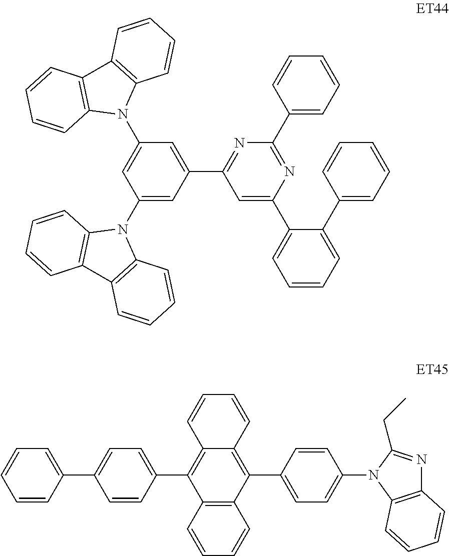 [SMILES: c1ccc(-c2nc(-c3cc(-n4c5ccccc5c5ccccc54)cc(-n4c5ccccc5c5ccccc54)c3)cc(-c3ccccc3-c3ccccc3)n2)cc1 ; CCc1nc2ccccc2n1-c1ccc(-c2c3ccccc3c(-c3ccc(-c4ccccc4)cc3)c3ccccc23)cc1]

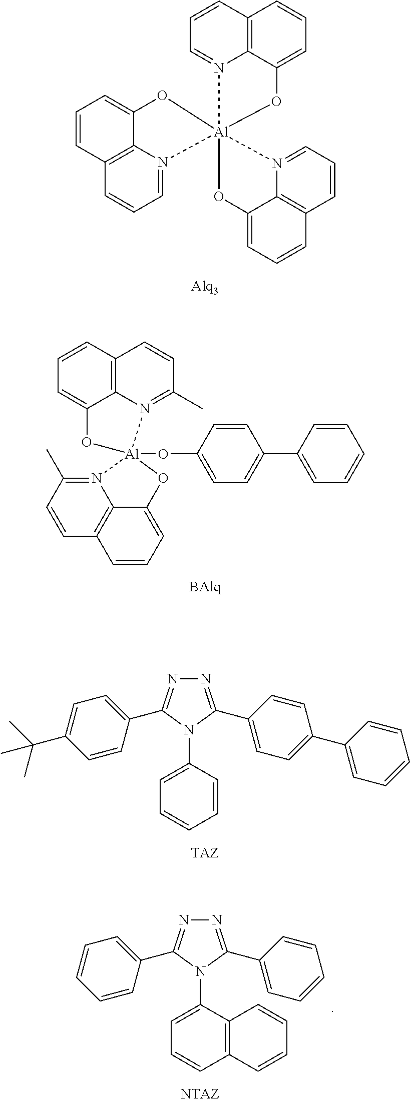

A thickness of the electron transport region may be in a range of about 100 Å to about 5,000 Å, for example, about 160 Å to about 4,000 Å. When the electron transport region includes a buffer layer, a hole blocking layer, an electron control layer, an electron transport layer, or a (e.g., any suitable) combination thereof, a thickness of the buffer layer, the hole blocking layer, or the electron control layer may each independently be in a range of about 20 Å to about 1,000 Å, for example, about 30 Å to about 300 Å, and a thickness of the electron transport layer may be in a range of about 100 Å to about 1,000 Å, for example, about 150 Å to about 500 Å. When the thicknesses of the buffer layer, the hole blocking layer, the electron control layer, the electron transport layer, and/or the electron transport region are within these ranges, satisfactory or suitable electron transporting characteristics may be obtained without a substantial increase in driving voltage.

The electron transport region (e.g., an electron transport layer in the electron transport region) may further include, in addition to the aforementioned materials, a metal-containing material.

The metal-containing material may include an alkali metal complex, an alkaline earth metal complex, and/or a (e.g., any suitable) combination thereof. A metal ion of the alkali metal complex may be a Li ion, a Na ion, a K ion, a Rb ion, or a Cs ion, and a metal ion of the alkaline earth metal complex may be a Be ion, a Mg ion, a Ca ion, a Sr ion, or a Ba ion. A ligand coordinated with the metal ion of the alkali metal complex or the metal ion of the alkaline earth-metal complex may include a hydroxyquinoline, a hydroxyisoquinoline, a hydroxybenzoquinoline, a hydroxyacridine, a hydroxyphenanthridine, a hydroxyphenyloxazole, a hydroxyphenylthiazole, a hydroxyphenyloxadiazole, a hydroxyphenylthiadiazole, a hydroxyphenylpyridine, a hydroxyphenylbenzimidazole, a hydroxyphenylbenzothiazole, a bipyridine, a phenanthroline, a cyclopentadiene, and/or a (e.g., any suitable) combination thereof.

For example, the metal-containing material may include a Li complex. The Li complex may include, for example, Compound ET-D1 (LiQ) or ET-D2:

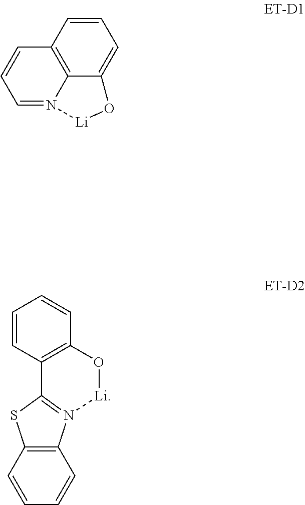

The electron transport region may include an electron injection layer that facilitates the injection of electrons from the second electrode 150. The electron injection layer may directly contact the second electrode 150.

The electron injection layer may have: i) a single-layer structure including (e.g., consisting of) a single layer including (e.g., consisting of) a single material, ii) a single-layer structure including (e.g., consisting of) a single layer including (e.g., consisting of) multiple layers that are different from each other, or iii) a multi-layer structure including multiple layers including multiple materials that are different from each other.

In one or more embodiments, the electron injection layer may include an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, and/or a (e.g., any suitable) combination thereof.

The alkali metal may include Li, Na, K, Rb, Cs, and/or a (e.g., any suitable) combination thereof. The alkaline earth metal may include Mg, Ca, Sr, Ba, and/or a (e.g., any suitable) combination thereof. The rare earth metal may include Sc, Y, Ce, Tb, Yb, Gd, and/or a (e.g., any suitable) combination thereof.

The alkali metal-containing compound, the alkaline earth metal-containing compound, and the rare earth metal-containing compound may be oxides, halides (e.g., fluorides, chlorides, bromides, or iodides), or tellurides of the alkali metal, the alkaline earth metal, and the rare earth metal, and/or a (e.g., any suitable) combination thereof.

The alkali metal-containing compound may include: an alkali metal oxide, such as Li₂O, Cs₂O, K₂O, and/or the like; alkali metal halides, such as UF, NaF, CsF, KF, Lil, Nal, Csl, KI, and/or the like; and/or a (e.g., any suitable) combination thereof.

The alkaline earth metal-containing compound may include an alkaline earth metal compound, such as BaO, SrO, CaO, BaₓSr₁₋ₓO (wherein x is a real number satisfying 0<x<1), BaₓCa₁₋ₓO (wherein x is a real number satisfying 0<x<1), and/or the like. The rare earth metal-containing compound may include YbF₃, ScF₃, Sc₂O₃, Y₂O₃, Ce₂O₃, GdF₃, TbF₃, YbI₃, ScI₃, Tbl₃, and/or a (e.g., any suitable) combination thereof. In one or more embodiments, the rare earth metal-containing compound may include lanthanide metal telluride. Examples of the lanthanide metal telluride may include LaTe, CeTe, PrTe, NdTe, PmTe, SmTe, EuTe, GdTe, TbTe, DyTe, HoTe, ErTe, TmTe, YbTe, LuTe, La₂Tes, Ce₂Te₃, Pr₂Te₃, Nd₂Te₃, Pm₂Te₃, Sm₂Te₃, Eu₂Te₃, Gd₂Te₃, Tb₂Tes, Dy₂Te₃, Ho₂Te₃, Er₂Te₃, Tm₂Tes, Yb₂Te₃, Lu₂Tes, and/or the like.

The alkali metal complex, the alkaline earth-metal complex, and the rare earth metal complex may include i) one of ions of the alkali metal, the alkaline earth metal, and the rare earth metal and ii), as a ligand bonded to the metal ion, for example, hydroxyquinoline, hydroxyisoquinoline, hydroxybenzoquinoline, hydroxyacridine, hydroxyphenanthridine, hydroxyphenyloxazole, hydroxyphenylthiazole, hydroxyphenyloxadiazole, hydroxyphenylthiadiazole, hydroxyphenylpyridine, hydroxyphenyl benzimidazole, hydroxyphenylbenzothiazole, bipyridine, phenanthroline, cyclopentadiene, and/or a (e.g., any suitable) combination thereof.

In one or more embodiments, the electron injection layer may include (e.g., consist of) an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, and/or a (e.g., any suitable) combination thereof, as described above. In one or more embodiments, the electron injection layer may further include an organic material (e.g., the compound represented by Formula 601).

In one or more embodiments, the electron injection layer may include (e.g., consist of) i) an alkali metal-containing compound (e.g., an alkali metal halide), or ii) a) an alkali metal-containing compound (e.g., an alkali metal halide), and b) an alkali metal, an alkaline earth metal, a rare earth metal, and/or a (e.g., any suitable) combination thereof. For example, the electron injection layer may be a KI:Yb co-deposited layer, an Rbl:Yb co-deposited layer, a LiF:Yb co-deposited layer, and/or the like.

When the electron injection layer further includes an organic material, the alkali metal, the alkaline earth metal, the rare earth metal, the alkali metal-containing compound, the alkaline earth metal-containing compound, the rare earth metal-containing compound, the alkali metal complex, the alkaline earth-metal complex, the rare earth metal complex, and/or a (e.g., any suitable) combination thereof, the above material or materials may be uniformly (e.g., substantially uniformly) or non-uniformly (e.g., substantially non-uniformly) dispersed in a matrix including the organic material.

The thickness of the electron injection layer may be in a range of about 1 Å to about 100 Å, and, for example, about 3 Å to about 90 Å. When the thickness of the electron injection layer is within these ranges, satisfactory electron injection characteristics may be obtained without a substantial increase in driving voltage.

### Second Electrode 150

The second electrode 150 is arranged on the interlayer 130 having the aforementioned structure. The second electrode 150 may be a cathode, which is an electron injection electrode, and as a material for forming the second electrode 150, a metal, an alloy, an electrically conductive compound, and/or a (e.g., any suitable) combination thereof, each having a low-work function, may be used.

The second electrode 150 may include Li, Ag, Mg, Al, Al—Li, Ca, Mg—In, Mg—Ag, Yb, Ag—Yb, ITO, IZO, and/or a (e.g., any suitable) combination thereof. The second electrode 150 may be a transmissive electrode, a semi-transmissive electrode, or a reflective electrode.

The second electrode 150 may have a single-layer structure or a multi-layer structure including multiple layers.

### Capping Layer

A first capping layer may be arranged outside the first electrode 110, and/or a second capping layer may be arranged outside the second electrode 150. For example, the light-emitting device 1A may have a structure in which the first capping layer, the first electrode 110, the interlayer 130, and the second electrode 150 are sequentially stacked in the stated order, a structure in which the first electrode 110, the interlayer 130, the second electrode 150, and the second capping layer are sequentially stacked in the stated order, or a structure in which the first capping layer, the first electrode 110, the interlayer 130, the second electrode 150, and the second capping layer are sequentially stacked in the stated order.

Light generated in an emission layer of the interlayer 130 of the light-emitting device 1A may be extracted toward the outside through the first electrode 110 which is a semi-transmissive electrode or a transmissive electrode, and the first capping layer. Light generated in an emission layer of the interlayer 130 of the light-emitting device 1A may be extracted toward the outside through the second electrode 150 which is a semi-transmissive electrode or a transmissive electrode, and the second capping layer.

The first capping layer and the second capping layer may increase external emission efficiency according to the principle of constructive interference. Accordingly, the light extraction efficiency of the light-emitting device 1A may be increased, so that the luminescence efficiency of the light-emitting device 1A may be improved.

Each of the first capping layer and the second capping layer may include a material having a refractive index of 1.6 or more (at 589 nm).

The first capping layer and the second capping layer may each independently be a capping layer including the quantum dots, an organic capping layer including organic materials, an inorganic capping layer including inorganic materials, or an organic-inorganic composite capping layer including organic materials and inorganic materials.

At least one of the first capping layer and/or the second capping layer may include a carbocyclic compound, a heterocyclic compound, an amine group-containing compound, a porphine derivative, a phthalocyanine derivative, a naphthalocyanine derivative, an alkali metal complex, an alkaline earth metal complex, and/or a (e.g., any suitable) combination thereof. The carbocyclic compound, the heterocyclic compound, and the amine group-containing compound may optionally be substituted with a substituent including O, N, S, Se, Si, F, Cl, Br, I, and/or a (e.g., any suitable) combination thereof. In one or more embodiments, at least one of the first capping layer and/or the second capping layer may include an amine group-containing compound.

In one or more embodiments, at least one of the first capping layer and/or the second capping layer may include the compound represented by Formula 201, the compound represented by Formula 202, and/or a (e.g., any suitable) combination thereof.

In one or more embodiments, at least one of the first capping layer and/or the second capping layer may include: at least one of Compounds HT28 to HT33; at least one of Compounds CP1 to CP6; β-NPB; and/or a (e.g., any suitable) combination thereof:

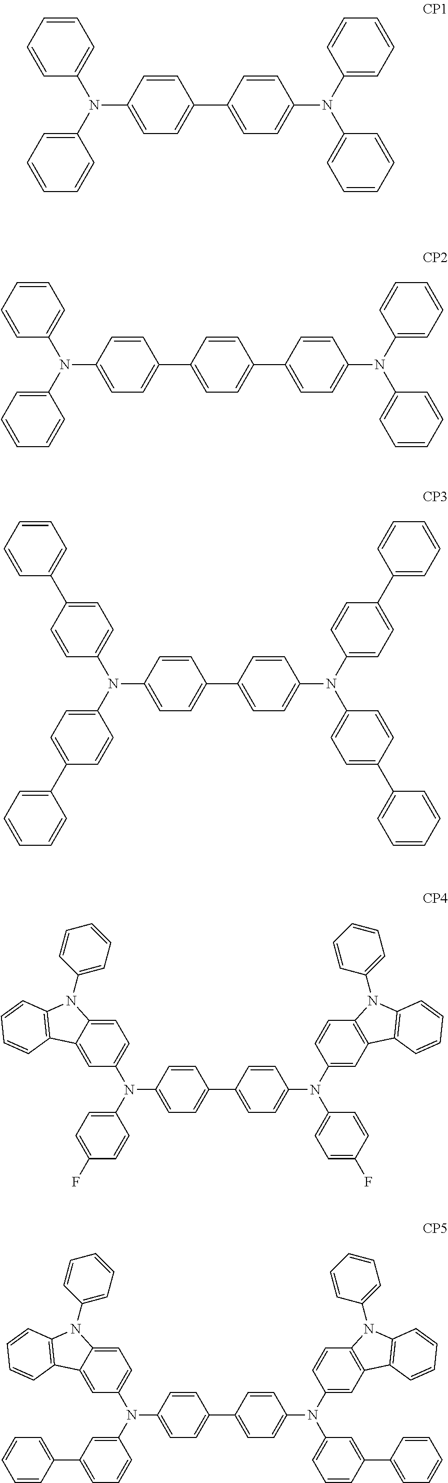 [SMILES: c1ccc(N(c2ccccc2)c2ccc(-c3ccc(N(c4ccccc4)c4ccccc4)cc3)cc2)cc1 ; c1ccc(N(c2ccccc2)c2ccc(-c3ccc(-c4ccc(N(c5ccccc5)c5ccccc5)cc4)cc3)cc2)cc1 ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; Fc1ccc(N(c2ccc(-c3ccc(N(c4ccc(F)cc4)c4ccc5c(c4)c4ccccc4n5-c4ccccc4)cc3)cc2)c2ccc3c(c2)c2ccccc2n3-c2ccccc2)cc1 ; c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1]

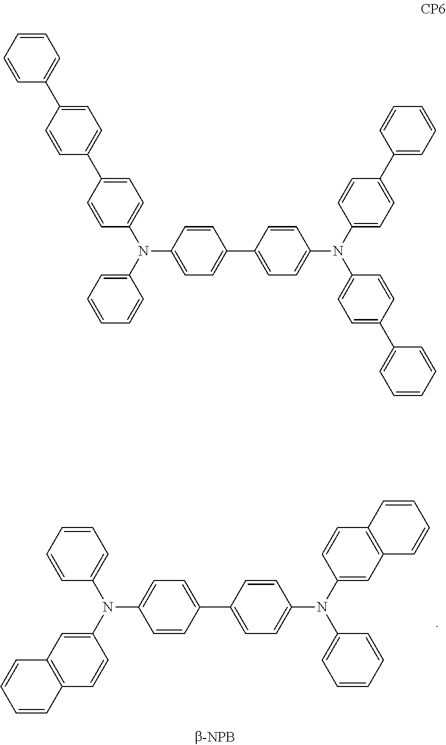 [SMILES: c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1]

### Film

The quantum dots may be included in one or more suitable films. Accordingly, one or more embodiments of the present disclosure include a film including the quantum dots. The film may be, for example, an optical member (or a light control means) (e.g., a color filter, a color conversion member, a capping layer, a light extraction efficiency enhancement layer, a selective light absorbing layer, a polarizing layer, a quantum dot-containing layer, and/or the like), a light blocking member (e.g., a light reflective layer, a light absorbing layer, and/or the like), and/or a protective member (e.g., an insulating layer, a dielectric layer, and/or the like).

### Optical Member

The quantum dots may be used in one or more suitable optical members. Accordingly, one or more embodiments of the present disclosure includes an optical member including the quantum dots.

In one or more embodiments, the optical member may be a light control means.

In one or more embodiments, the optical member may be a color filter, a color conversion member, a capping layer, a light-extraction efficiency enhancement layer, a selective light-absorption layer, or a polarizing layer.

The optical member may be a color conversion member. The color conversion member may include a substrate and a pattern layer formed on the substrate.

The substrate may be a substrate constituting the color conversion member, or may be a region of an apparatus (for example, a display apparatus) in which the color conversion member is located. The substrate may be glass, silicon (Si), silicon oxide (SiOₓ), or a polymer substrate, and the polymer substrate may be polyethersulfone (PES) or polycarbonate (PC).

The pattern layer may include the quantum dots in the form of a thin film. For example, the pattern layer may be the quantum dots in the form of a thin film.

The color conversion member including the substrate and the pattern layer may further include a partition wall or a black matrix formed between pattern layers. In one or more embodiments, the color conversion member may further include a color filter to further improve light conversion efficiency.

The color conversion member may include a red pattern layer capable of emitting red light, a green pattern layer capable of emitting green light, a blue pattern layer capable of emitting blue light, and/or a (e.g., any suitable) combination thereof. The red pattern layer, the green pattern layer, and/or the blue pattern layer may be implemented by controlling components, compositions, and/or structures of the quantum dots.

One or more embodiments of the present disclosure includes an apparatus including the quantum dots (or an optical member including the quantum dots).

The apparatus may further include a light source, and the quantum dots (or an optical member including the quantum dots) may be arranged in a path of light that may be emitted from the light source.

The light source may be to emit blue light, red light, green light, or white light. For example, the light source may be to emit blue light. In one or more embodiments, light emitted from the light source may be absorbed by the quantum dots.

The light source may be an organic light-emitting device (OLED) or a light-emitting diode (LED).

The light emitted from the light source as described above may be photo-converted by the quantum dots while passing through the quantum dots, such that light having a wavelength different from the wavelength of the light emitted from the light source may be emitted by the quantum dots.

For example, the quantum dots may be to absorb and convert light emitted from the light source to emit light having a maximum emission wavelength in a range of about 400 nm to about 2,500 nm.

### Electronic Apparatus

The quantum dots and the light-emitting devices including the same may be included in one or more suitable electronic apparatuses. For example, an electronic apparatus including the quantum dots and the light-emitting device including the quantum dots may be a light-emitting apparatus, an authentication apparatus, and/or the like.

The electronic apparatus (e.g., a light-emitting apparatus) may further include i) a color filter, ii) a color conversion layer, or iii) a color filter and a color conversion layer, in addition to the light-emitting device. The color filter and/or the color conversion layer may be arranged in at least one direction in which light emitted from the light-emitting device travels. For example, the light emitted from the light-emitting device may be blue light or white light. Details on the light-emitting device are the same as described herein. In one or more embodiments, the color conversion layer may include quantum dots. The quantum dots may be, for example, the aforementioned quantum dots.

The electronic apparatus may include a first substrate. The first substrate may include a plurality of subpixel areas, the color filter may include a plurality of color filter areas respectively corresponding to the subpixel areas, and the color conversion layer may include a plurality of color conversion areas respectively corresponding to the subpixel areas.

A pixel-defining film may be arranged among the subpixel areas to define each of the subpixel areas.

The color filter may further include a plurality of color filter areas and light-shielding patterns thereon, and the color conversion layer may further include a plurality of color conversion areas and light-shielding patterns thereon.

The plurality of color filter areas (or the plurality of color conversion areas) may include: a first area emitting first color light; a second area emitting second color light; and/or a third area emitting third color light, wherein the first color light, the second color light, and/or the third color light may have different maximum emission wavelengths from one another. For example, the first color light may be red light, the second color light may be green light, and the third color light may be blue light. For example, the plurality of color filter areas (or the plurality of color conversion areas) may include quantum dots. In particular, the first area may include red quantum dots, the second area may include green quantum dots, and the third area may not include (e.g., may exclude) quantum dots. Details on the quantum dots are the same as described herein. Each of the first area, the second area, and/or the third area may further include a scatter (e.g., scattering particles).

For example, in the light-emitting device emitting first light, the first area may be to absorb the first light to emit 1-1 color light, the second area may be to absorb the first light to emit 2-1 color light, and the third area may be to absorb the first light to emit 3-1 color light. Here, the 1-1 color light, the 2-1 color light, and the 3-1 color light may have different maximum emission wavelengths from one another. In particular, the first light may be blue light, the 1-1 color light may be red light, the 2-1 color light may be green light, and the 3-1 color light may be blue light.

The electronic apparatus may further include a thin-film transistor, in addition to the aforementioned light-emitting device. The thin-film transistor may include a source electrode, a drain electrode, and an activation layer, wherein any one of the source electrode and the drain electrode may be electrically connected to any one of the first electrode and the second electrode of the light-emitting device.

The thin-film transistor may further include a gate electrode, a gate insulating film, and/or the like.

The activation layer may include crystalline silicon, amorphous silicon, an organic semiconductor, an oxide semiconductor, and/or the like.

The electronic apparatus may further include a sealing portion for sealing the light-emitting device. The sealing portion may be arranged between the color filter and/or the color conversion layer and the light-emitting device. The sealing portion allows light from the light-emitting device to be extracted to the outside, and concurrently (e.g., simultaneously) prevents ambient air and moisture from penetrating into the light-emitting device. The sealing portion may be a sealing substrate including a transparent glass substrate or a plastic substrate. The sealing portion may be a thin-film encapsulation layer including at least one layer of an organic layer and/or an inorganic layer. When the sealing portion is a thin-film encapsulation layer, the electronic apparatus may be flexible.

Various functional layers may be additionally arranged on the sealing portion, in addition to the color filter and/or the color conversion layer, according to the use of the electronic apparatus. Examples of the functional layers may include a touch screen layer, a polarizing layer, and/or the like. The touch screen layer may be a pressure-sensitive touch screen layer, a capacitive touch screen layer, or an infrared touch screen layer. The authentication apparatus may be, for example, a biometric authentication apparatus that authenticates an individual by using biometric information of a living body (e.g., fingertips, pupils, and/or the like).

The authentication apparatus may further include, in addition to the light-emitting device as described above, a biometric information collector.

The electronic apparatus may be applied to one or more suitable displays, light sources, lighting, personal computers (e.g., mobile personal computers), mobile phones, digital cameras, electronic organizers, electronic dictionaries, electronic game machines, medical instruments (e.g., electronic thermometers, sphygmomanometers, blood glucose meters, pulse measurement devices, pulse wave measurement devices, electrocardiogram displays, ultrasonic diagnostic devices, or endoscope displays), fish finders, one or more suitable measuring instruments, meters (e.g., meters for a vehicle, an aircraft, and a vessel), projectors, and/or the like.

### Electronic Device

The quantum dots and the light-emitting devices including the same may be included in one or more suitable electronic devices.

For example, the electronic device including the light-emitting device may be one of a flat panel display, a curved display, a computer monitor, a medical monitor, a television, a billboard, a light for indoor or outdoor lighting and/or signaling, a head-up display, a fully or partially transparent display, a flexible display, a rollable display, a foldable display, a stretchable display, a laser printer, a telephone, a mobile phone, a tablet, a phablet, a personal digital assistant (PDA), a wearable device, a laptop computer, a digital camera, a camcorder, a viewfinder, a micro display, a 3D display, a virtual or augmented-reality display, a vehicle, a video wall including multiple displays tiled together, a theater or stadium screen, a phototherapy device, and/or a signboard.

The light-emitting device may have excellent or suitable luminescence efficiency and long lifespan, and thus the electronic device including the light-emitting device may have characteristics, such as high luminance, high resolution, and low power consumption.

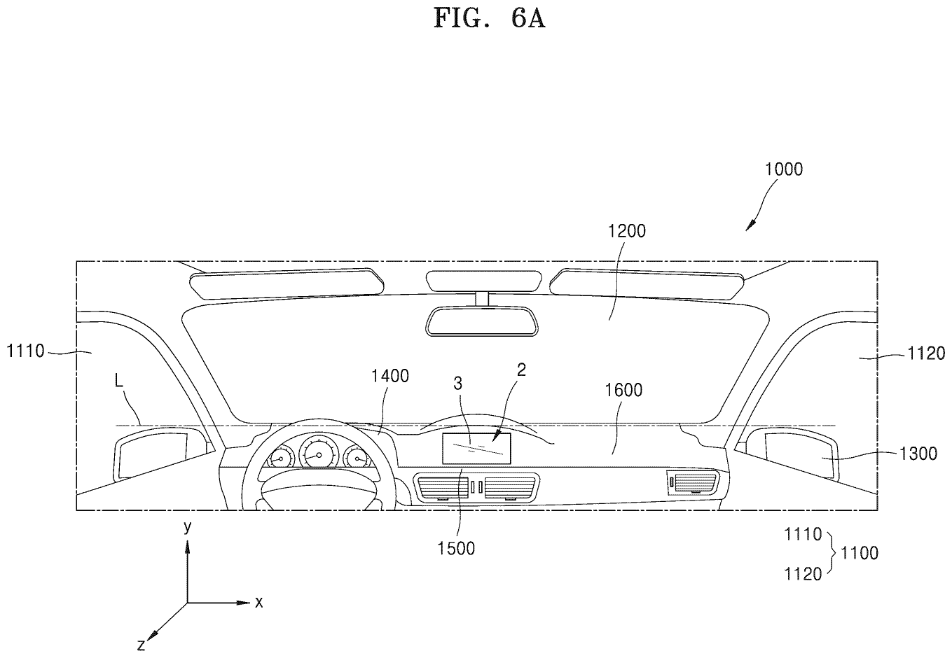

### Description of FIG. 4

FIG. 4 is a schematic perspective view of electronic device 1 including the quantum dot according to one or more embodiments of the present disclosure. The electronic device 1 may be, as a device apparatus that displays a moving image or still image, a portable electronic device, such as a mobile phone, a smart phone, a tablet personal computer (PC), a mobile communication terminal, an electronic notebook, an electronic book, a portable multimedia player (PMP), a navigation, or a ultra-mobile PC (UMPC), as well as one or more suitable products, such as a television, a laptop, a monitor, a billboard, or an Internet of things (IoT). The electronic device 1 may be such a product above or a part thereof. In one or more embodiments, the electronic apparatus 1 may be a wearable device, such as a smart watch, a watch phone, a glasses-type or kind display, or a head mounted display (HMD), or a part of such a wearable device. However, the present disclosure is not limited thereto. For example, the electronic device 1 may include a dashboard of a vehicle, a center information display on a center fascia or dashboard of a vehicle, a room mirror display replacing a side mirror of a vehicle, an entertainment display arranged for the rear seat of a vehicle or arranged on the back of the front seat, a head-up display (HUD) installed at the front of a vehicle or projected on a front window glass, or a computer generated hologram augmented reality heads-up display (CGH AR HUD). FIG. 4 illustrates a case in which the electronic device 1 is a smart phone for convenience of explanation.

The electronic device 1 may include a display area DA and a non-display area NDA outside the display area DA. A display device may implement an image through an array of a plurality of pixels that are two-dimensionally arranged in the display area DA.

The non-display area NDA is an area that does not display an image, and may be entirely around (e.g., may surround) the display area DA. In the non-display area NDA, a driver for providing electrical signals or power to display devices arranged in the display area DA may be arranged. In the non-display area NDA, a pad, which is an area to which an electronic element or a printing circuit board may be electrically connected, may be arranged.

In the electronic device 1, a length in the x-axis direction and a length in the y-axis direction may be different from each other. In one or more embodiments, as shown in FIG. 4, the length in the x-axis direction may be shorter than the length in the y-axis direction. In one or more embodiments, the length in the x-axis direction may be the same as the length in the y-axis direction. In one or more embodiments, the length in the x-axis direction may be longer than the length in the y-axis direction.

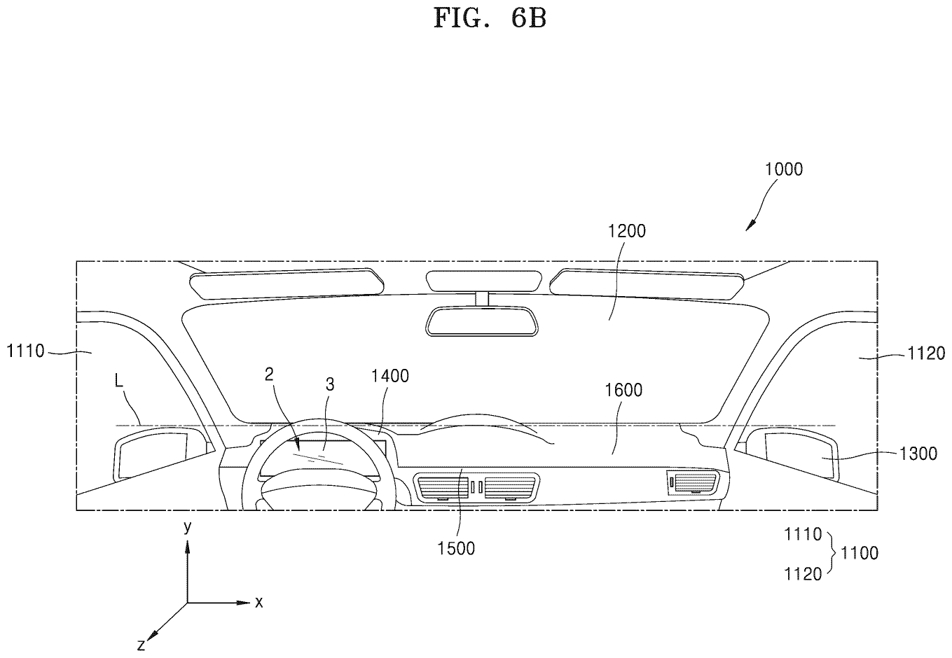

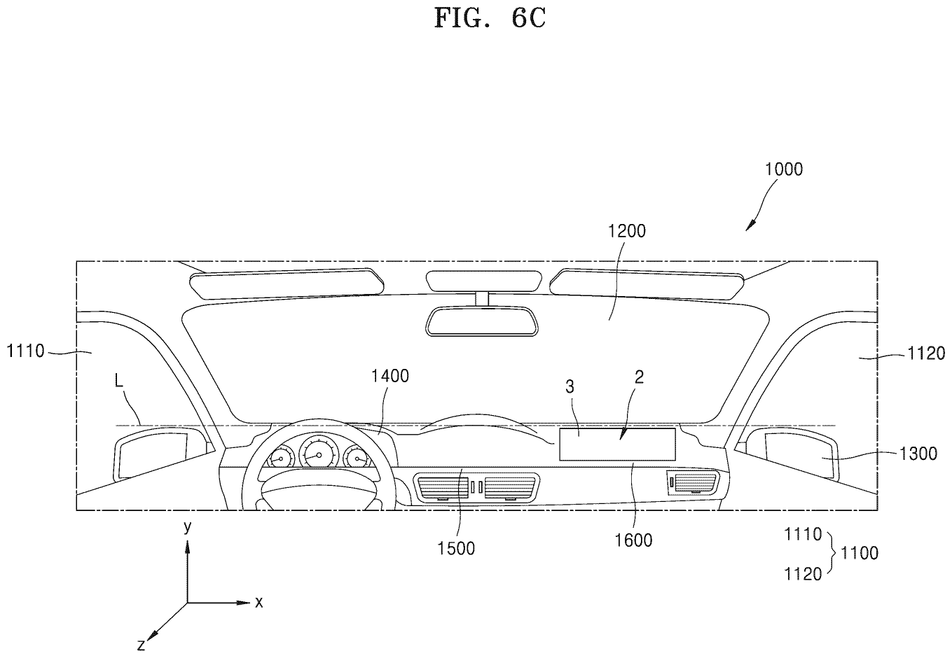

### Descriptions of FIGS. 5 and 6A to 6C

FIG. 5 is a schematic view of the exterior of a vehicle 1000 as an electronic device including the quantum dot according to one or more embodiments of the present disclosure. FIGS. 6A to 6C are each a schematic view of the interior of the vehicle 1000 according to embodiments of the present disclosure.

Referring to FIGS. 5, 6A, 6B, and 6C, the vehicle 1000 may refer to one or more suitable apparatuses for moving a subject to be transported, such as a human, an object, or an animal, from a departure point to a destination point. The vehicle 1000 may include a vehicle traveling on a road or a track, a vessel moving over the sea or river, an airplane flying in the sky using the action of air, and/or the like.

The vehicle 1000 may travel on a road or a track. The vehicle 1000 may move in a set or predetermined direction according to rotation of at least one wheel. For example, the vehicle 1000 may include a three-wheeled or four-wheeled vehicle, a construction machine, a two-wheeled vehicle, a prime mover device, a bicycle, and/or a train running on a track.

The vehicle 1000 may include a body having an interior and an exterior, and a chassis in which mechanical apparatuses necessary for driving are installed as other parts except for the body. The exterior of the body may include a front panel, a bonnet, a roof panel, a rear panel, a trunk, a pillar provided at a boundary between doors, and/or the like. The chassis of the vehicle 1000 may include a power generating device, a power transmitting device, a driving device, a steering device, a braking device, a suspension device, a transmission device, a fuel device, front and rear left and right wheels, and/or the like.

The vehicle 1000 may include a side window glass 1100, a front window glass 1200, a side mirror 1300, a cluster 1400, a center fascia 1500, a passenger seat dashboard 1600, and a display device 2.

The side window glass 1100 and the front window glass 1200 may be partitioned by a pillar arranged between the side window glass 1100 and the front window glass 1200.

The side window glass 1100 may be installed on the side of the vehicle 1000. In one or more embodiments, the side window glass 1100 may be installed on a door of the vehicle 1000. A plurality of side window glasses 1100 may be provided and may face each other. In one or more embodiments, the side window glass 1100 may include a first side window glass 1110 and a second side window glass 1120. In one or more embodiments, the first side window glass 1110 may be arranged adjacent to the cluster 1400. The second side window glass 1120 may be arranged adjacent to the passenger seat dashboard 1600.

In one or more embodiments, the side window glasses 1100 may be spaced and/or apart (e.g., spaced apart or separated) from each other in the x-direction or the -x-direction. For example, the first side window glass 1110 and the second side window glass 1120 may be spaced and/or apart (e.g., spaced apart or separated) from each other in the x direction or the -x direction. For example, an imaginary straight line L connecting the side window glasses 1100 may extend in the x-direction or the -x-direction. For example, an imaginary straight line L connecting the first side window glass 1110 and the second side window glass 1120 to each other may extend in the x direction or the -x direction.

The front window glass 1200 may be installed in front of the vehicle 1000.

The front window glass 1200 may be arranged between the side window glasses 1100 facing each other.

The side mirror 1300 may provide a rear view of the vehicle 1000. The side mirror 1300 may be installed on the exterior of the vehicle body. In one or more embodiments, a plurality of side mirrors 1300 may be provided. Any one of the plurality of side mirrors 1300 may be arranged outside the first side window glass 1110. The other one of the plurality of side mirrors 1300 may be arranged outside the second side window glass 1120.

The cluster 1400 may be arranged in front of the steering wheel. The cluster may include a tachometer, a speedometer, a coolant thermometer, a fuel gauge turn indicator, a high beam indicator, a warning lamp, a seat belt warning lamp, an odometer, a tachograph, an automatic shift selector indicator lamp, a door open warning lamp, an engine oil warning lamp, and/or a low fuel warning light.

The center fascia 1500 may include a control panel on which a plurality of buttons for adjusting an audio device, an air conditioning device, and/or a heater of a seat are arranged. The center fascia 1500 may be arranged on one side of the cluster 1400.

A passenger seat dashboard 1600 may be spaced and/or apart (e.g., spaced apart or separated) from the cluster 1400 with the center fascia 1500 arranged therebetween. In one or more embodiments, the cluster 1400 may be arranged to correspond to a driver seat, and the passenger seat dashboard 1600 may be arranged to correspond to a passenger seat. In one or more embodiments, the cluster 1400 may be adjacent to the first side window glass 1110, and the passenger seat dashboard may be adjacent to the second side window glass 1120.

In one or more embodiments, the display device 2 may include a display panel 3, and the display panel 3 may display an image. The display device 2 may be arranged inside the vehicle 1000. In one or more embodiments, the display device 2 may be arranged between the side window glasses 1100 facing each other. The display device 2 may be arranged on at least one of the cluster 1400, the center fascia 1500, and/or the passenger seat dashboard 1600.

The display device 2 may include an organic light-emitting display device, an inorganic electroluminescent display device, a quantum dot display device, and/or the like. Hereinafter, as the display device 2 according to one or more embodiments, an organic light-emitting display apparatus including the aforementioned light-emitting device will be described as an example, but one or more suitable types (kinds) of the aforementioned display apparatus may be used in embodiments.

Referring to FIG. 6A, the display device 2 may be arranged on the center fascia 1500. In one or more embodiments, the display device 2 may display navigation information. In one or more embodiments, the display device 2 may display audio, video, and/or information regarding vehicle settings.

Referring to FIG. 6B, the display device 2 may be arranged on the cluster 1400. When the display device 2 is arranged on the cluster 1400, the cluster 1400 may display driving information and/or the like through the display device 2. For example, the cluster 1400 may be implemented digitally. The digital cluster 1400 may display vehicle information and driving information as images. For example, a needle and a gauge of a tachometer and one or more suitable warning light icons may be displayed by a digital signal.

Referring to FIG. 6C, the display device 2 may be arranged on the passenger seat dashboard 1600. The display device 2 may be embedded in the passenger seat dashboard 1600 or arranged on the passenger seat dashboard 1600.

In one or more embodiments, the display device 2 arranged on the passenger seat dashboard 1600 may display an image related to information displayed on the cluster and/or information displayed on the center fascia 1500. In one or more embodiments, the display device 2 arranged on the passenger seat dashboard 1600 may display information different from information displayed on the cluster 1400 and/or information displayed on the center fascia 1500.

### Manufacturing Method

Layers constituting the hole transport region, the emission layer, and the layers constituting the electron transport region may be formed in a certain region by using one or more suitable methods such as vacuum deposition, spin coating, casting, Langmuir-Blodgett (LB) deposition, ink-jet printing, laser-printing, laser-induced thermal imaging, and/or the like.

When layers constituting the hole transport region, the emission layer, and the layers constituting the electron transport region are formed by vacuum deposition, the deposition may be performed at a deposition temperature in a range of about 100° C. to about 500° C., at a vacuum degree in a range of about 10⁻⁸ torr to about 10⁻³ torr, and at a deposition speed in a range of about 0.01 Å/see (angstroms per second) to about 100 Å/see, depending on a material to be included in a layer to be formed and the structure of a layer to be formed.

### Definition of Terms

The term “C₃-C₆₀ carbocyclic group” as used herein refers to a cyclic group including (e.g., consisting of) carbon only as a ring-forming atom and having three to sixty carbon atoms, and the term “C₁-C₆₀ heterocyclic group” as used herein refers to a cyclic group that has 1 to 60 carbon atoms and further has, in addition to carbon, a heteroatom as a ring-forming atom. The C₃-C₆₀ carbocyclic group and the C₁-C₆₀ heterocyclic group may each be: a monocyclic group including (e.g., consisting of) one ring; or a polycyclic group in which two or more rings are condensed with each other. For example, the number of ring-forming atoms of the C₁-C₆₀ heterocyclic group may be from 3 to 61.

The term “cyclic group” as used herein may include both the C₃-C₆₀ carbocyclic group and the C₁-C₆₀ heterocyclic group.

The term “π electron-rich C₃-C₆₀ cyclic group” as used herein refers to a cyclic group that has three to sixty carbon atoms and does not include *—N═*′ as a ring-forming moiety, and the term “π electron-deficient nitrogen-containing C₁-C₆₀ cyclic group” as used herein refers to a heterocyclic group that has one to sixty carbon atoms and includes *—N═*′ as a ring-forming moiety.

For example, the C₃-C₆₀ carbocyclic group may be i) Group T1 or ii) a condensed cyclic group in which two or more of Group T1 are condensed with each other (e.g., a cyclopentadiene group, an adamantane group, a norbornane group, a benzene group, a pentalene group, a naphthalene group, an azulene group, an indacene group, an acenaphthylene group, a phenalene group, a phenanthrene group, an anthracene group, a fluoranthene group, a triphenylene group, a pyrene group, a chrysene group, a perylene group, a pentaphene group, a heptalene group, a naphthacene group, a picene group, a hexacene group, a pentacene group, a rubicene group, a coronene group, an ovalene group, an indene group, a fluorene group, a spiro-bifluorene group, a benzofluorene group, an indenophenanthrene group, or an indenoanthracene group).

The C₁-C₆₀ heterocyclic group may be i) Group T2, ii) a condensed cyclic group in which at least two of Group T2 are condensed with each other, or iii) a condensed cyclic group in which at least one Group T2 and at least one Group T1 are condensed with each other (e.g., a pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, and/or the like).

The π electron-rich C₃-C₆₀ cyclic group may be i) Group T1, ii) a condensed cyclic group in which two or more of Group T1 are condensed with each other, iii) Group T₃, iv) a condensed cyclic group in which two or more of Group T3 are condensed with each other, or v) a condensed cyclic group in which at least one Group T3 and at least one Group T1 are condensed with each other (e.g., the C₃-C₆₀ carbocyclic group, a 1H-pyrrole group, a silole group, a borole group, a 2H-pyrrole group, a 3H-pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, and/or the like).

The π electron-deficient nitrogen-containing C₁-C₆₀ cyclic group may be i) Group T₄, ii) a condensed cyclic group in which at least two of Groups T4 are condensed with each other, iii) a condensed cyclic group in which at least one Group T4 and at least one Group T1 are condensed with each other, iv) a condensed cyclic group in which at least one Group T4 and at least one Group T3 are condensed with each other, or v) a condensed cyclic group in which at least one Group T₄, at least one Group T1, and at least one Group T3 are condensed with one another (e.g., a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, and/or the like).

Group T1 may be a cyclopropane group, a cyclobutane group, a cyclopentane group, a cyclohexane group, a cycloheptane group, a cyclooctane group, a cyclobutene group, a cyclopentene group, a cyclopentadiene group, a cyclohexene group, a cyclohexadiene group, a cycloheptene group, an adamantane group, a norborane (or bicyclo[2.2.1]heptane) group, a norbornene group, a bicyclo[1.1.1]pentane group, a bicyclo[2.1.1]hexane group, a bicyclo[2.2.2]octane group, or a benzene group.

Group T2 may be a furan group, a thiophene group, a 1H-pyrrole group, a silole group, a borole group, a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, a tetrazine group, a pyrrolidine group, an imidazolidine group, a dihydropyrrole group, a piperidine group, a tetrahydropyridine group, a dihydropyridine group, a hexahydropyrimidine group, a tetrahydropyrimidine group, a dihydropyrimidine group, a piperazine group, a tetrahydropyrazine group, a dihydropyrazine group, a tetrahydropyridazine group, or a dihydropyridazine group.

Group T3 may be a furan group, a thiophene group, a 1H-pyrrole group, a silole group, or a borole group.

Group T4 may include a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, or a tetrazine group.

The terms “the cyclic group, the C₃-C₆₀ carbocyclic group, the C₁-C₆₀ heterocyclic group, the π electron-rich C₃-C₆₀ cyclic group, or the π electron-deficient nitrogen-containing C₁-C₆₀ cyclic group” as used herein refer to a group condensed to any cyclic group, a monovalent group, or a polyvalent group (e.g., a divalent group, a trivalent group, a tetravalent group, and/or the like) according to the structure of a formula for which the corresponding term is used. For example, the “benzene group” may be a benzo group, a phenyl group, a phenylene group, and/or the like, which may be easily understood by one of ordinary skill in the art according to the structure of a formula including the “benzene group.”

Examples of the monovalent C₃-C₆₀ carbocyclic group and monovalent C₁-C₆₀ heterocyclic group are a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, and a monovalent non-aromatic condensed heteropolycyclic group, and examples of the divalent C₃-C₆₀ carbocyclic group and the monovalent C₁-C₆₀ heterocyclic group may include a C₃-C₁ cycloalkylene group, a C₁-C₁₀ heterocycloalkylene group, a C₃-C₁ cycloalkenylene group, a C₁-C₁₀ heterocycloalkenylene group, a C₆-C₆₀ arylene group, a C₁-C₆₀ heteroarylene group, a divalent non-aromatic condensed polycyclic group, and/or a substituted or unsubstituted divalent non-aromatic condensed heteropolycyclic group.

The term “C₁-C₆₀ alkyl group” as used herein refers to a linear or branched aliphatic hydrocarbon monovalent group that has 1 to 60 carbon atoms, and specific examples thereof may include a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, and/or a tert-decyl group. The term “C₁-C₆₀ alkylene group” as used herein refers to a divalent group having the same structure as the C₁-C₆₀ alkyl group.

The term “C₂-C₆₀ alkenyl group” as used herein refers to a monovalent hydrocarbon group having at least one carbon-carbon double bond in the middle or at the terminus of the C₂-C₆₀ alkyl group, and examples thereof may include an ethenyl group, a propenyl group, a butenyl group, and the like. The term “C₂-C₆₀ alkenylene group” as used herein refers to a divalent group having the same structure as the C₂-C₆₀ alkenyl group.

The term “C₂-C₆₀ alkynyl group” as used herein refers to a monovalent hydrocarbon group having at least one carbon-carbon triple bond in the middle or at the terminus of the C₂-C₆₀ alkyl group, and examples thereof may include an ethynyl group, a propynyl group, and the like. The term “C₂-C₆₀ alkynylene group” as used herein refers to a divalent group having the same structure as the C₂-C₆₀ alkynyl group.

The term “C₁-C₆₀ alkoxy group” as used herein refers to a monovalent group represented by —OA₁₀₁ (wherein A₁₀₁ is the C₁-C₆₀ alkyl group), and examples thereof may include a methoxy group, an ethoxy group, an isopropyloxy group, and/or the like.

The term “C₃-C₁ cycloalkyl group” as used herein refers to a monovalent saturated hydrocarbon cyclic group having 3 to 10 carbon atoms, and examples thereof may include a cyclopropyl group, a cyclobutyl group, a cyclopentyl group, a cyclohexyl group, a cycloheptyl group, a cyclooctyl group, an adamantanyl group, a norbornanyl group (or bicyclo[2.2.1]heptyl group), a bicyclo[1.1.1]pentyl group, a bicyclo[2.1.1]hexyl group, a bicyclo[2.2.2]octyl group, and the like. The term “C₃-C₁₀ cycloalkylene group” as used herein refers to a divalent group having the same structure as the C₃-C₁₀ cycloalkyl group.

The term “C₁-C₁₀ heterocycloalkyl group” as used herein refers to a monovalent cyclic group of 1 to 10 carbon atoms, further including, in addition to carbon atoms, at least one heteroatom as ring-forming atoms, and specific examples thereof may include a 1, 2, 3, 4-oxatriazolidinyl group, a tetrahydrofuranyl group, a tetrahydrothiophenyl group, and the like. The term “C₁-C₁₀ heterocycloalkylene group” as used herein refers to a divalent group having the same structure as the C₁-C₁₀ heterocycloalkyl group.

The term “C₃-C₁₀ cycloalkenyl group” as used herein refers to a monovalent cyclic group that 3 to 10 carbon atoms, at least one carbon-carbon double bond in the ring thereof, and no aromaticity, and specific examples thereof may include a cyclopentenyl group, a cyclohexenyl group, a cycloheptenyl group, and the like. The term “C₃-C₁₀ cycloalkenylene group” as used herein refers to a divalent group having the same structure as the C₃-C₁₀ cycloalkenyl group.

The term “C₁-C₁₀ heterocycloalkenyl group” as used herein refers to a monovalent cyclic group of 1 to 10 carbon atoms, further including, in addition to carbon atoms, at least one heteroatom as ring-forming atoms and at least one carbon-carbon double bond in the cyclic structure thereof. Examples of the C₁-C₁₀ heterocycloalkenyl group may include a 4,5-dihydro-1, 2, 3, 4-oxatriazolyl group, a 2,3-dihydrofuranyl group, a 2,3-dihydrothiophenyl group, and the like. The term “C₁-C₁₀ heterocycloalkylene group” as used herein refers to a divalent group having the same structure as the C₁-C₁₀ heterocycloalkyl group.

The term “C₆-C₆₀ aryl group” as used herein refers to a monovalent group having a carbocyclic aromatic system of 6 to 60 carbon atoms, and the term “C₆-C₆₀ arylene group” as used herein refers to a divalent group having a carbocyclic aromatic system of 6 to 60 carbon atoms. Examples of the C₆-C₆₀ aryl group may include a phenyl group, a pentalenyl group, a naphthyl group, an azulenyl group, an indacenyl group, an acenaphthyl group, a phenalenyl group, a phenanthrenyl group, an anthracenyl group, a fluoranthenyl group, a triphenylenyl group, a pyrenyl group, a chrysenyl group, a perylenyl group, a pentaphenyl group, a heptalenyl group, a naphthacenyl group, a picenyl group, a hexacenyl group, a pentacenyl group, a rubicenyl group, a coronenyl group, an ovalenyl group, and the like. When the C₆-C₆₀ aryl group and the C₆-C₆₀ arylene group each include two or more rings, the rings may be condensed with each other.

The term “C₁-C₆₀ heteroaryl group” as used herein refers to a monovalent group having a heterocyclic aromatic system of 1 to 60 carbon atoms, further including, in addition to carbon atoms, at least one heteroatom as ring-forming atoms. The term “C₁-C₆₀ heteroarylene group” as used herein refers to a divalent group having a heterocyclic aromatic system of 1 to 60 carbon atoms, further including, in addition to carbon atoms, at least one heteroatom as ring-forming atoms. Examples of the C₁-C₆₀ heteroaryl group may include a pyridinyl group, a pyrimidinyl group, a pyrazinyl group, a pyridazinyl group, a triazinyl group, a quinolinyl group, a benzoquinolinyl group, an isoquinolinyl group, a benzoisoquinolinyl group, a quinoxalinyl group, a benzoquinoxalinyl group, a quinazolinyl group, a benzoquinazolinyl group, a cinnolinyl group, a phenanthrolinyl group, a phthalazinyl group, a naphthyridinyl group, and the like. When the C₁-C₆₀ heteroaryl group and the C₁-C₆₀ heteroarylene group each include two or more rings, the rings may be condensed with each other.

The term “monovalent non-aromatic condensed polycyclic group” as used herein refers to a monovalent group (e.g., having 8 to 60 carbon atoms) having two or more rings condensed to each other, only carbon atoms as ring-forming atoms, and no aromaticity in the entire molecular structure. Examples of the monovalent non-aromatic condensed polycyclic group may include an indenyl group, a fluorenyl group, a spiro-bifluorenyl group, a benzofluorenyl group, an indenophenanthrenyl group, an indeno anthracenyl group, and the like. The term “divalent non-aromatic condensed polycyclic group” as used herein refers to a divalent group having the same structure as the monovalent non-aromatic condensed polycyclic group described above.

The term “monovalent non-aromatic hetero-condensed polycyclic group” as used herein refers to a monovalent group (e.g., having 1 to 60 carbon atoms) having two or more rings condensed to each other, further including, in addition to carbon atoms, at least one heteroatom, as ring-forming atoms, and having non-aromaticity in its entire molecular structure. Examples of the monovalent non-aromatic hetero-condensed polycyclic group may include a pyrrolyl group, a thiophenyl group, a furanyl group, an indolyl group, a benzoindolyl group, a naphthoindolyl group, an isoindolyl group, a benzoisoindolyl group, a naphthoisoindolyl group, a benzosilolyl group, a benzothiophenyl group, a benzofuranyl group, a carbazolyl group, a dibenzosilolyl group, a dibenzothiophenyl group, a dibenzofuranyl group, an azacarbazolyl group, an azafluorenyl group, an azadibenzosilolyl group, an azadibenzothiophenyl group, an azadibenzofuranyl group, a pyrazolyl group, an imidazolyl group, a triazolyl group, a tetrazolyl group, an oxazolyl group, an isoxazolyl group, a thiazolyl group, an isothiazolyl group, an oxadiazolyl group, a thiadiazolyl group, a benzopyrazolyl group, a benzimidazolyl group, a benzoxazolyl group, a benzothiazolyl group, a benzoxadiazolyl group, a benzothiadiazolyl group, an imidazopyridinyl group, an imidazopyrimidinyl group, an imidazotriazinyl group, an imidazopyrazinyl group, an imidazopyridazinyl group, an indeno carbazolyl group, an indolocarbazolyl group, a benzofurocarbazolyl group, a benzothienocarbazolyl group, a benzosilolocarbazolyl group, a benzoindolocarbazolyl group, a benzocarbazolyl group, a benzonaphthofuranyl group, a benzonaphthothiophenyl group, a benzonaphthosilolyl group, a benzofurodibenzofuranyl group, a benzofurodibenzothiophenyl group, and a benzothienodibenzothiophenyl group. The term “divalent non-aromatic condensed heteropolycyclic group” as used herein refers to a divalent group having the same structure as the monovalent non-aromatic condensed heteropolycyclic group.

The term “C₆-C₆₀ aryloxy group” as used herein indicates —OA₁₀₂ (wherein A₁₀₂ is the C₆-C₆₀ aryl group), and the term “C₆-C₆₀ arylthio group” as used herein indicates —SA₁₀₃ (wherein A₁₀₃ is the C₆-C₆₀ aryl group).

The term “C₇-C₆₀ arylalkyl group” as used herein refers to —A₁₀₄A₁₀₅ (wherein A₁₀₄ is a C₁-C₅₄ alkylene group, and A₁₀₅ is a C₆-C₅₉ aryl group), and the term “C₂-C₆₀ heteroarylalkyl group” as used herein refers to —A₁₀₆A₁₀₇ (wherein A₁₀₆ is a C₁-C₅₉ alkylene group, and A₁₀₇ is a C₁-C₅₉ heteroaryl group).

The term “R₁₀ₐ” as used herein may be: deuterium, —F, —Cl, —Br, —I, a hydroxyl group, a cyano group, or a nitro group; a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), and/or a (e.g., any suitable) combination thereof; a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, or a C₂-C₆₀ heteroaryl alkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₁-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, a C₂-C₆₀ heteroaryl alkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), and/or a (e.g., any suitable) combination thereof; or —Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂).

In the specification, Q₁ to Q₃, Q₁₁ to Q₁₃, Q₂₁ to Q₂₃, and Q₃₁ to Q₃₃ may each independently be: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; a C₃-C₆₀ carbocyclic group or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, and/or a (e.g., any suitable) combination thereof; a C₇-C₆₀ arylalkyl group; or a C₂-C₆₀ heteroarylalkyl group.

The term “heteroatom” as used herein refers to any atom other than a carbon atom. Examples of the heteroatom may include O, S, N, P, Si, B, Ge, Se, and/or a (e.g., any suitable) combination thereof.

The term “third-row transition metal” as used herein includes Hf, Ta, W, Re, O₃, Ir, Pt, Au, and/or the like.

In the specification, “Ph” refers to a phenyl group, “Me” refers to a methyl group, “Et” refers to an ethyl group, “tert-Bu” or “Bu^{t}” refers to a tert-butyl group, and “OMe” refers to a methoxy group.

The term “biphenyl group” as used herein refers to “a phenyl group substituted with a phenyl group.” For example, the “biphenyl group” may be a substituted phenyl group having a C₆-C₆₀ aryl group as a substituent.

The term “terphenyl group” as used herein refers to “a phenyl group substituted with a biphenyl group.” For example, the “terphenyl group” may be a substituted phenyl group having, as a substituent, a C₆-C₆₀ aryl group substituted with a C₆-C₆₀ aryl group.

The term * and *′ as used herein, unless defined otherwise, each refer to a binding site to a neighboring atom in a corresponding formula or moiety.

In the specification, the x-axis, y-axis, and z-axis are not limited to three axes in an orthogonal coordinate system, and may be interpreted in a broad sense including these axes. For example, the x-axis, y-axis, and z-axis may refer to those orthogonal to each other, or may refer to those in different directions that are not orthogonal to each other.

Hereinafter, compounds according to one or more embodiments and light-emitting devices according to one or more embodiments will be described in more detail with reference to the following synthesis examples and examples. The wording “B was used instead of A” used in describing Synthesis Examples means that a substantially identical molar equivalent of B was used in place of A.

### Synthesis Examples

### Synthesis Example 1 (Synthesis of Quantum Dot 1

### Synthesis of the Core

Zinc acetate (5 mmol), oleic acid (15 mmol), and trioctylamine (20 mL) were added to a 100 mL 3-neck flask, and the mixed solution was in a vacuum state at 120° C. for 1 hour. After converting the atmosphere inside the reactor to N₂, 0.8 mL of 1 M trioctylphosphine-selenide was added thereto together with 0.3 mL of DPP(diphenylphosphine) at 340° C. After lowering the reaction temperature to 300° C., 0.8 mL of 2 M cadmium oleate was added thereto to allow a reaction therein for 1 hour. After cooling the reaction solution to room temperature, the resulting reaction solution was washed twice with ethanol, so as to obtain a core.

### Synthesis of the Shell

The synthesized core, zinc acetate (20 mmol), oleic acid (60 mmol), and trioctylamine (50 mL) were added to a three-neck flask, and the mixed solution was in a vacuum state at 120° C. for 1 hour. After converting the atmosphere inside the reactor to N₂, 20 mL of a solution in which 1 M trioctylphosphine-selenide and trioctylphosphine-sulfide were mixed at a volume ratio of 3:7 was added thereto at 300° C. After allowing a reaction for 1 hour, the reaction solution was cooled to room temperature. The resulting reaction solution was washed twice with ethanol, so as to obtain final quantum dots.

### Synthesis Example 2 (Synthesis of Quantum Dot 2

All processes to synthesize (e.g., cores of) quantum dots were (e.g., each) performed in substantially the same manner as in the Synthesis of the Core according to Synthesis Example 1, except that 6 mmol of zinc acetate and 18 mmol of oleic acid were used. Also, all processes to synthesize (e.g., shells of) quantum dots were (e.g., each) performed in substantially the same manner as in the Synthesis of the Shell according to Synthesis Example 1, except the time allowed for the reaction was changed from 1 hour to 50 minutes.

### Synthesis Example 3 (Synthesis of Quantum Dot 3

All processes to synthesize quantum dots were performed in substantially the same manner as in the Synthesis of the Core according to Synthesis Example 1, except that 6.5 mmol of zinc acetate and 19.5 mmol of oleic acid were used. Also, all processes to synthesize quantum dots were performed in substantially the same manner as in the Synthesis of the Shell according to Synthesis Example 1, except the time allowed for the reaction was changed from 1 hour to 45 minutes.

### Synthesis Example 4 (Synthesis of Quantum Dot 4

All processes to synthesize quantum dots were performed in substantially the same manner as in the Synthesis of the Core according to Synthesis Example 1, except that 7.0 mmol of zinc acetate and 21 mmol of oleic acid were used. Also, all processes to synthesize quantum dots were performed in substantially the same manner as in the Synthesis of the Shell according to Synthesis Example 1, except the time allowed for the reaction was changed from 1 hour to 45 minutes.

### Synthesis Example 5 (Synthesis of Quantum Dot 5

All processes to synthesize quantum dots were performed in substantially the same manner as in the Synthesis of the Core according to Synthesis Example 1, except that 7.5 mmol of zinc acetate and 22.5 mmol of oleic acid were used. Also, all processes to synthesize quantum dots were performed in substantially the same manner as in the Synthesis of the Shell according to Synthesis Example 1, except the time allowed for the reaction was changed from 1 hour to 40 minutes.

### Synthesis Example 6 (Synthesis of Quantum Dot 6

All processes to synthesize quantum dots were performed in substantially the same manner as in the Synthesis of the Core according to Synthesis Example 1, except that 8 mmol of zinc acetate and 24 mmol of oleic acid were used. Also, all processes to synthesize quantum dots were performed in substantially the same manner as in the Synthesis of the Shell according to Synthesis Example 1, except the time allowed for the reaction was changed from 1 hour to 30 minutes.

### Synthesis Comparative Example 1 (Comparative Quantum Dot 1

### Synthesis of the Core

Zinc acetate (3 mmol), oleic acid (9 mmol), and trioctylamine (20 mL) were added to a 100 mL 3-neck flask, and the mixed solution was in a vacuum state at 120° C. for 1 hour. After converting the atmosphere inside the reactor to N₂, 0.8 mL of 1 M trioctylphosphine-selenide was added thereto together with 0.2 mL of DPP(diphenylphosphine) at 340° C. After lowering the reaction temperature to 300° C., 0.4 mL of 2 M cadmium oleate was added thereto to allow a reaction therein for 1 hour. After cooling the reaction solution to room temperature, the resulting reaction solution was washed twice with ethanol, so as to obtain a core.

### Synthesis of the Shell

The synthesized core, zinc acetate (2 mmol), oleic acid (6 mmol), and trioctylamine (5 mL) were added to a three-neck flask, and the mixed solution was in a vacuum state at 120° C. for 1 hour. After converting the atmosphere inside the reactor to N₂, 2 mL of a solution in which 1 M trioctylphosphine-selenide and trioctylphosphine-sulfide were mixed at a volume ratio of 3:7 was added thereto at 300° C. After allowing a reaction for 1 hour, the reaction solution was cooled to room temperature. The resulting reaction solution was washed twice with ethanol, so as to obtain final quantum dots.

### Synthesis Comparative Example 2 (Comparative Quantum Dot 2

All processes to synthesize quantum dots were performed in substantially the same manner as in the Synthesis of the Core according to Synthesis comparative Example 1, except that 0.2 mL of 2 M cadmium oleate was used. Also, all processes to synthesize quantum dots were performed in substantially the same manner as in the Synthesis of the Shell according to Synthesis comparative Example 1.

### Synthesis Comparative Example 3 (Comparative Quantum Dot 3

All processes to synthesize quantum dots were performed in substantially the same manner as in the Synthesis of the Core according to Synthesis Example 3, except that 1.6 mL of 2 M cadmium oleate was used. Also, all processes to synthesize quantum dots were performed in substantially the same manner as in the Synthesis of the Shell according to Synthesis comparative Example 1, except that zinc acetate (5 mmol), oleic acid (15 mmol) were used.

### Synthesis Comparative Example 4 (Comparative Quantum Dot 4

All processes to synthesize quantum dots were performed in substantially the same manner as in the Synthesis of the Core according to Synthesis Example 3. Also, all processes to synthesize quantum dots were performed in substantially the same manner as in the Synthesis of the Shell according to Synthesis Example 3, except that cadmium acetate (3 mmol) and oleic acid (9 mmol) were additionally used with 6.5 mmol of zinc acetate and 19.5 mmol of oleic acid, and only 20 mL of 1 M trioctylphosphine-sulfide solution was used without mixing trioctylphosphine-selenide solution.

### Synthesis Comparative Example 5 (Comparative Quantum Dot 5

All processes to synthesize quantum dots were performed in substantially the same manner as in the Synthesis of the Core according to Synthesis Example 3. Also, all processes to synthesize quantum dots were performed in substantially the same manner as in the Synthesis of the Shell according to Synthesis Example 3, except that only 20 mL of 1 M trioctylphosphine-sulfide solution was used without mixing trioctylphosphine-selenide solution.

### Synthesis Comparative Example 6 (Comparative Quantum Dot 6

All processes to synthesize quantum dots were performed in substantially the same manner as in the Synthesis of the Core according to Synthesis comparative Example 1, Also, all processes to synthesize quantum dots were performed in substantially the same manner as in the Synthesis of the Shell according to Synthesis comparative Example 1.

### EXAMPLES

### Example 1

As an anode, an ITO substrate was cut to a size of 50 mm×50 mm×0.5 mm, sonicated with acetone, isopropyl alcohol, and pure water each for 15 minutes, and then cleaned by exposure to ultraviolet rays and ozone for 30 minutes. Then, the ITO substrate was provided to a vacuum deposition apparatus.

Poly(3,4-ethylenedioxythiophene)/poly(4-styrenesulfonate) (PEDOT/PSS) were deposited/applied (by spin coating) on the ITO substrate to form a hole injection layer having a thickness of 600 Å, and poly[(9,9-dioctylfluorenyl-2,7-diyl)-co-(4,4′-(N-(4-sec-butylphenyl)diphenylamine)](TFB) was vacuum-deposited/applied (by spin coating) on the hole injection layer to form a hole transport layer having a thickness of 400 Å.

A composition in which Quantum Dot 1 of Synthesis Example 1 was mixed with octane was applied (by spin coating) to the hole transport layer to form a thin film, and a vapor compression distillation (VCD) process at 10⁻³ torr and a bake process at 140° C. for 10 minutes were sequentially performed on the thin film to form an emission layer. The emission layer was then spin coated with ZnMgO to form an electron transport layer having a thickness of 280 Å. Aluminum (Al) was deposited on the electron transport layer to form a cathode having a thickness of 1,000 Å, thereby completing the manufacture of a light-emitting device.

### Examples 2 to 6 and Comparative Examples 1 to 6

Light-emitting devices were each manufactured in substantially the same manner as in Example 1, except that quantum dots listed in Table 1 were each used instead of Quantum dot 1 and solvents listed in Table 1 were used instead of octane.

TABLE 1

| | | | | Radius | Thickness | |
|---|---|---|---|---|---|---|
| | Quantum dot | | | of | of | |
| | Quantum | | | core | shell | |
| | dot | Core | Shell | (nm) | (nm) | Solvent |
| Example | Quantum | Cd_{0.11}Zn_{0.89}Se | ZnSe_{0.5}S_{0.5} | 5 | 3.5 | Octane |
| 1 | Dot 1 | | | | | |
| Example | Quantum | Cd_{0.10}Zn_{0.90}Se | ZnSe_{0.5}S_{0.5} | 5.5 | 3 | Octane |
| 2 | Dot 2 | | | | | |
| Example | Quantum | Cd_{0.09}Zn_{0.91}Se | ZnSe_{0.5}S_{0.5} | 6 | 2.5 | Octane |
| 3 | Dot 3 | | | | | |
| Example | Quantum | Cd_{0.08}Zn_{0.92}Se | ZnSe_{0.5}S_{0.5} | 6.5 | 2.0 | Octane |
| 4 | Dot 4 | | | | | |
| Example | Quantum | Cd_{0.07}Zn_{0.93}Se | ZnSe_{0.5}S_{0.5} | 7.5 | 1.0 | Octane |
| 5 | Dot 5 | | | | | |
| Example | Quantum | Cd_{0.09}Zn_{0.91}Se | ZnSe_{0.5}S_{0.5} | 6 | 2.5 | Cyclohexyl |
| 6 | Dot 6 | | | | | bezene:hexadecane:octyl |
| | | | | | | benzene |
| | | | | | | (6:3:1) |
| Comparative | Comparative | Cd_{0.17}Zn_{0.83}Se | ZnSe_{0.5}S_{0.5} | 3.5 | 1.0 | Octane |
| Example | Quantum | | | | | |
| 1 | Dot 1 | | | | | |
| Comparative | Comparative | Cd_{0.09}Zn_{0.91}Se | ZnSe_{0.5}S_{0.5} | 3.5 | 1.0 | Octane |
| Example | Quantum | | | | | |
| 2 | Dot 2 | | | | | |
| Comparative | Comparative | Cd_{0.17}Zn_{0.83}Se | ZnSe_{0.5}S_{0.5} | 6 | 1.0 | Octane |
| Example | Quantum | | | | | |
| 3 | Dot 3 | | | | | |
| Comparative | Comparative | Cd_{0.09}Zn_{0.91}Se | CdZnS | 6 | 2.5 | Octane |
| Example | Quantum | | | | | |
| 4 | Dot 4 | | | | | |
| Comparative | Comparative | Cd_{0.09}Zn_{0.91}Se | ZnS | 6 | 2.5 | Octane |
| Example | Quantum | | | | | |
| 5 | Dot 5 | | | | | |
| Comparative | Comparative | Cd_{0.17}Zn_{0.83}Se | ZnSe_{0.5}S_{0.5} | 3.5 | 1.0 | Cyclohexyl |
| Example | Quantum | | | | | benzene:hexadecane:octyl |
| 6 | Dot 6 | | | | | benzene |
| | | | | | | (6:3:1) |

### Evaluation Example 1

For the light-emitting devices of Examples 1 to 6 and Comparative Examples to 6, the photoluminescence quantum yield (PLOY), external quantum efficiency (E.Q.E), and luminance-dependent lifespan were measured by using measuring meters, such as Keithley SMU 236 and luminance meter PR650, and the results are shown in Table 2. The luminance-dependent lifespan was measured as Tso, wherein T₉₀ represents the time required for the luminance to reach 90% of the initial luminance.

TABLE 2

| | | | | | Emission |
|---|---|---|---|---|---|
| | PLQY | FWHM | E.Q.E | Lifespan | color |
| | (%) | (nm) | (%) | (T₉₀, h) | (wavelength) |
| Example 1 | 80 | 22 | 8.5 | 500 | Blue (460 nm) |
| Example 2 | 77 | 23 | 9.1 | 800 | Blue (460 nm) |
| Example 3 | 70 | 21 | 9.8 | 1500 | Blue (460 nm) |
| Example 4 | 65 | 22 | 7.5 | 1100 | Blue (460 nm) |
| Example 5 | 62 | 23 | 6.2 | 1300 | Blue (460 nm) |
| Example 6 | 71 | 21 | 10.7 | 2130 | Blue (460 nm) |
| Comparative | — | — | — | 300 | Blue (460 nm) |
| Example 1 | | | | | |
| Comparative | 43 | — | 5.5 | 1 | Purple (445 nm) |
| Example 2 | | | | | |
| Comparative | 48 | 28 | 5.7 | 100 | Light blue |
| Example 3 | | | | | (486 nm) |
| Comparative | — | — | — | 600 | Blue (460 nm) |
| Example 4 | | | | | |
| Comparative | — | — | — | 100 | Blue (460 nm) |
| Example 5 | | | | | |
| Comparative | 45 | — | 5.1 | 85 | Blue (460 nm) |
| Example 6 | | | | | |

Referring to Table 2, it was confirmed that the light-emitting devices of Examples 1 to 6 had excellent or suitable PLQY, E.Q.E, and lifespan compared to the light-emitting devices of Comparative Examples 1 to 3.

For example, when comparing the light-emitting device of Example 3 and the light-emitting devices of Comparative Examples 4 and 5 that included the same core particles, it was confirmed that the light-emitting device of Example 3 having the shell structure of embodiments of the present disclosure had excellent or suitable lifespan characteristics compared to the light-emitting devices of Comparative Examples 4 and 5.

Also, when comparing the light-emitting device of Example 3 and the light-emitting device of Comparative Example 2 that have the same core and shell particle, it was confirmed that the light-emitting device of Example 3 satisfying the radius range of the core of embodiments of the present disclosure achieved excellent or suitable characteristics in terms of PLQY, E.Q.E, and lifespan, a narrow FWHM, and excellent or suitable blue light emission.

Also, when comparing the light-emitting device of Example 3 and the light-emitting device of Comparative Example 3 that satisfied the same the radius range of the core of embodiments of the present disclosure, it was confirmed that the light-emitting device of Example 3 satisfying the Cd amount of embodiments of the present disclosure achieved excellent or suitable characteristics in terms of PLQY, E.Q.E, and lifespan, a narrow FWHM, and excellent or suitable blue light emission.

Also, when comparing the light-emitting device of Example 6 and the light-emitting device of Comparative Example 6 that were manufactured by using a composition including solvents with a high boiling point and quantum dots, it was confirmed that the light-emitting device of Example 6 satisfying the core particles and the core size of embodiments of the present disclosure achieved excellent or suitable characteristics in terms of PLQY, E.Q.E, and lifespan compared to the light-emitting device of Comparative Example 6. For example, as the exchange of Cd cations caused by Cu impurities in the solvent having a high boiling point was suppressed or reduced in the quantum dots of embodiments of the present disclosure, the light-emitting device of embodiments of the present disclosure were confirmed to maintain excellent or suitable characteristics without deteriorating the efficiency and lifespan characteristics.

According to the one or more embodiments, quantum dots have excellent or suitable luminescence efficiency and long lifespan characteristics, and thus use of such quantum dots may provide high-quality optical members, electronic apparatuses, and electronic devices.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

Further, the use of “may” when describing embodiments of the present disclosure refers to “one or more embodiments of the present disclosure.”

As used herein, the term “substantially,” “about,” and similar terms are used as terms of approximation and not as terms of degree, and are intended to account for the inherent deviations in measured or calculated values that would be recognized by those of ordinary skill in the art. “Substantially” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “substantially” may mean within one or more standard deviations, or within ±30%, 20%, 10%, 5% of the stated value.

Also, any numerical range recited herein is intended to include all subranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The light emitting device, electronic apparatus or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

It should be understood that embodiments described herein should be considered in a descriptive sense only and not for purposes of limitation. Descriptions of features or aspects within each embodiment should typically be considered as available for other similar features or aspects in one or more embodiments. Although the embodiments of the present disclosure have been described, it is understood that the present disclosure should not be limited to these embodiments, but one or more suitable changes and modifications can be made by one ordinary skilled in the art within the spirit and scope of the present disclosure as defined by the following claims and equivalents thereof.

What is claimed is:

1. A quantum dot comprising:
a core comprising a first semiconductor compound represented by Formula 1; and
a first shell around the core and comprising A¹,
wherein a radius of the core of the quantum dot is 5 nm or more:
CdₓA₁₋ₓ¹B¹ Formula 1
wherein, in Formula 1,
A¹ comprises a Group II element other than cadmium (Cd),
B¹ comprises a Group VI element, and
x is greater than 0 and less than or equal to about 0.12.

2. The quantum dot of claim 1, wherein x is in a range of about 0.07 to about 0.11.

3. The quantum dot of claim 1, wherein A¹ comprises Zn, Mg, Ca, Hg, or a combination thereof.

4. The quantum dot of claim 1, wherein
the first shell further comprises B² and B³, and
B² and B³ each independently comprise a Group VI element.

5. The quantum dot of claim 4, wherein B¹, B², and B³ each independently comprise O, S, Se, Te, or a combination thereof.

6. The quantum dot of claim 4, wherein B¹ and B² are substantially identical to each other.

7. The quantum dot of claim 1, wherein the core and the first shell each comprise a Group II-VI semiconductor compound.

8. The quantum dot of claim 7, wherein the Group II-VI semiconductor compound comprises CdS, CdSe, CdTe, ZnS, ZnSe, ZnTe, ZnO, HgS, HgSe, HgTe, MgSe, MgS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, CdZnSeS, CdZnSeTe, CdZnSTe, CdHgSeS, CdHgSeTe, CdHgSTe, HgZnSeS, HgZnSeTe, HgZnSTe, or a combination thereof.

9. The quantum dot of claim 1, wherein the first shell comprises a second semiconductor compound represented by Formula 2:
A¹B_{y}²B_{1-y}³ Formula 2
wherein, in Formula 2,
A¹ is a Group II element,
B² and B³ are each independently a Group VI element, and
y is greater than 0 but less than 1.

10. The quantum dot of claim 1, wherein a thickness of the first shell is in a range of about 1 nm to about 5 nm.

11. The quantum dot of claim 1, wherein a maximum emission wavelength of the quantum dot is in a range of about 410 nm to about 480 nm.

12. An ink composition comprising the quantum dot of claim 1 and a solvent.

13. The ink composition of claim 12, wherein a boiling point of the solvent is 120° C. or more.

14. The ink composition of claim 12, wherein the solvent is a single solvent or a mixed solvent of at least two types of solvent.

15. An optical member comprising the quantum dot of claim 1.

16. An electronic apparatus comprising the quantum dot of claim 1.

17. The electronic apparatus of claim 16, further comprising:
a light source; and
a color conversion member located on a pathway of light emitted from the light source,
wherein the color conversion member comprises the quantum dot.

18. The electronic apparatus of claim 16, further comprising
a light-emitting device comprising: a first electrode; a second electrode facing the first electrode; and an interlayer arranged between the first electrode and the second electrode and comprising an emission layer,
wherein the light-emitting device comprises the quantum dot.

19. An electronic device comprising the quantum dot of claim 1.

20. The electronic device of claim 19, wherein the electronic device is at least one of a flat panel display, a curved display, a computer monitor, a medical monitor, a television, a billboard, an indoor or outdoor light and/or light for signal, a head-up display, a fully or partially transparent display, a flexible display, a rollable display, a foldable display, a stretchable display, a laser printer, a telephone, a portable phone, a tablet personal computer, a phablet, a personal digital assistant (PDA), a wearable device, a laptop computer, a digital camera, a camcorder, a viewfinder, a micro display, a three-dimensional (3D) display, a virtual reality or augmented reality display, a vehicle, a video wall with multiple displays tiled together, a theater or stadium screen, a phototherapy device, or a signboard.
